(19) United States
(12) Patent Application Publication
(10) Pub. No.: US 2025/0317118 A1
(43) Pub. Date: Oct. 9, 2025

(54) ACOUSTIC WAVE DEVICE AND FILTER DEVICE

(71) Applicant: Murata Manufacturing Co., Ltd., Nagaokakyo-shi (JP)

(72) Inventors: Kentaro NAKAMURA, Nagaokakyo-shi (JP); Takuya YABU, Nagaokakyo-shi (JP); Ryo NAKAGAWA, Nagaokakyo-shi (JP)

(21) Appl. No.: 19/241,733

(22) Filed: Jun. 18, 2025

Related U.S. Application Data
(63) Continuation of application No. PCT/JP2023/042659, filed on Nov. 29, 2023.

(30) Foreign Application Priority Data
Dec. 19, 2022 (JP) 2022-201749

(51) Int. Cl. H03H 9/02; H03H 9/64

(52) U.S. Cl. CPC H03H 9/02818; H03H 9/02992; H03H 9/64

(57) ABSTRACT

An acoustic wave device includes a piezoelectric substrate including a piezoelectric layer, and an IDT electrode on the piezoelectric layer and including first and second busbars and first and second electrode fingers. Virtual lines connecting tips of distal end portions of the first and second fingers are respectively referred to as first and second envelopes. An overlap region is between the first and second envelopes and includes at least one curved-line region, in which the first and second electrode fingers have a curved plan-view shape. In the curved-line region, each of the first and second electrode fingers has a non-constant curvature.

### CROSS REFERENCE TO RELATED APPLICATIONS

This application claims the benefit of priority to Japanese Patent Application No. 2022-201749 filed on Dec. 19, 2022 and is a Continuation Application of PCT Application No. PCT/JP2023/042659 filed on Nov. 29, 2023. The entire contents of each application are hereby incorporated herein by reference.

### BACKGROUND OF THE INVENTION

### 1. Field of the Invention

The present invention relates to acoustic wave devices and filter devices.

### 2. Description of the Related Art

Acoustic wave devices have been widely used in filters of mobile phones and other devices. International Publication No. 2011/108229 discloses an example of acoustic wave devices. This acoustic wave device includes an interdigital transducer (IDT) electrode on a piezoelectric substrate. Multiple electrode fingers of the IDT electrode have a curved shape. More specifically, each electrode finger extends along a curved line from the center of the overlap region of the IDT electrode to common electrodes.

In the IDT electrode of the acoustic wave device described in International Publication No. 2011/108229, the electrode finger pitch is smaller in a central portion in the direction in which the plurality of electrode fingers extend than in end portions in the same direction. However, in this acoustic wave device, spurious responses cannot be reduced or prevented sufficiently.

### SUMMARY OF THE INVENTION

Example embodiments of the present invention provide acoustic wave devices and filter devices in each of which spurious waves can be effectively reduced or prevented.

An example embodiment of the present invention provides an acoustic wave device that includes a piezoelectric substrate including a piezoelectric layer, and an IDT electrode on the piezoelectric layer and including a pair of busbars and a plurality of electrode fingers. The pair of busbars include a first busbar and a second busbar that face each other. The plurality of electrode fingers include a plurality of first electrode fingers and a plurality of second electrode fingers. One end of each of the plurality of first electrode fingers is connected to the first busbar. One end of each of the plurality of second electrode fingers is connected to the second busbar. The plurality of first electrode fingers and the plurality of second electrode fingers are interdigitated with each other. A region between a first envelope and a second envelope in the IDT electrode is defined as an overlap region where the first envelope is a virtual line connecting tips of distal end portions of the plurality of second electrode fingers and the second envelope is a virtual line connecting tips of distal end portions of the plurality of first electrode fingers. A portion including a portion of each of the plurality of first electrode fingers located on the first envelope and adjacent to a distal end portion of any one of the plurality of second electrode fingers is referred to as an adjacent portion of the first electrode finger. A portion including a portion of each of the plurality of second electrode fingers located on the second envelope and adjacent to the distal end portion of any one of the plurality of first electrode fingers is referred to as an adjacent portion of the second electrode finger. The overlap region includes at least one curved-line region, in which the plurality of first electrode fingers and the plurality of second electrode fingers each have a curved plan-view shape. The at least one curved-line region includes a curved-line region one edge of which corresponds to the first envelope. In the curved-line region, each of the plurality of first electrode fingers and the plurality of second electrode fingers has a non-constant curvature. On the first envelope side in at least one pair of electrode fingers among the plurality of first electrode fingers and the plurality of second electrode fingers, the distal end portions, the adjacent portions, or the distal end portion and the adjacent portions have different curvatures from each other.

Another example embodiment of the present invention provides an acoustic wave device that includes a piezoelectric substrate including a piezoelectric layer, and an IDT electrode on the piezoelectric layer and including a pair of busbars and a plurality of electrode fingers. The pair of busbars include a first busbar and a second busbar that face each other. The plurality of electrode fingers include a plurality of first electrode fingers and a plurality of second electrode fingers. One end of each of the plurality of first electrode fingers is connected to the first busbar. One end of each of the plurality of second electrode fingers is connected to the second busbar. The plurality of first electrode fingers and the plurality of second electrode fingers are interdigitated with each other. A region between a first envelope and a second envelope in the IDT electrode is defined as an overlap region where the first envelope is a virtual line connecting distal end portions of the plurality of second electrode fingers and the second envelope is a virtual line connecting distal end portions of the plurality of first electrode fingers. A portion including a portion of each of the plurality of first electrode fingers located on the first envelope and adjacent to the distal end portion of any one of the plurality of second electrode fingers is referred to as an adjacent portion of the first electrode finger. A portion including a portion of each of the plurality of second electrode fingers located on the second envelope and adjacent to the distal end portion of any one of the plurality of first electrode fingers is referred to as an adjacent portion of the second electrode finger. The overlap region includes at least one curved-line region, in which the plurality of first electrode fingers and the plurality of second electrode fingers each have a curved plan-view shape. The at least one curved-line region includes the curved-line region one edge of which corresponds to the first envelope. In the curved-line region, each of the plurality of first electrode fingers and the plurality of second electrode fingers has a curved plan-view shape that is not a circular or elliptical arc and to be approximated by a circular or elliptical arc. In the curved-line region, when the plan-view shapes of at least one pair of electrode fingers among the plurality of first electrode fingers and the plurality of second electrode fingers are approximated by circular or elliptical arcs, centers of the circles including the respective circular arcs or the centroids of the foci of the ellipses including the respective elliptical arcs are located at different positions.

A filter device according to an example embodiment of the present invention includes a plurality of acoustic wave resonators, at least one of the plurality of acoustic wave resonators being an acoustic wave device according to an example embodiment of the present invention.

With the acoustic wave devices and filter devices according to example embodiments of the present invention, it is possible to effectively reduce or prevent spurious waves.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a simplified plan view of an acoustic wave device according to a first example embodiment of the present invention.

FIG. 2 is a schematic sectional view along a line I-I in FIG. 1.

FIG. 3 is a schematic enlarged plan view of a part of the acoustic wave device according to the first example embodiment of the present invention.

FIG. 4 is a diagram illustrating slowness curves of acoustic waves propagating in a first piezoelectric substrate and a second piezoelectric substrate.

FIG. 5 is a diagram illustrating slowness curves of a longitudinal wave, a fast transversal wave, and a slow transversal wave in the first piezoelectric substrate.

FIG. 6 is a diagram illustrating the relationship between the absolute value |θ_{c_prop}| of the excitation angle and change rate Δpitch of the electrode finger pitch in the IDT electrode according to the first example embodiment of the present invention.

FIG. 7 is a simplified plan view of the IDT electrode according to the first example embodiment of the present invention, illustrating circles that include circular arcs approximating the plan-view shapes of electrode fingers.

FIG. 8 is a simplified plan view of an IDT electrode according to a first modification of the first example embodiment of the present invention, illustrating circles that include circular arcs approximating the plan-view shapes of electrode fingers.

FIG. 9 is a diagram illustrating the relationship between the absolute value |θ_{c_prop}| of the excitation angle and the duty ratio in an IDT electrode according to a second modification of the first example embodiment of the present invention.

FIG. 10 is a diagram illustrating the relationship between the absolute value |θ_{c_prop}| of the excitation angle and electrode finger thickness in an IDT electrode according to a third modification of the first example embodiment of the present invention.

FIG. 11 is a schematic front sectional view of an acoustic wave device according to a fourth modification of the first example embodiment of the present invention.

FIG. 12 is a diagram illustrating the relationship between the absolute value |θ_{c_prop}| of the excitation angle and the thickness of a portion of dielectric film that covers a curved-line region, in the fourth modification of the first example embodiment of the present invention.

FIG. 13 is a diagram illustrating the relationship between the absolute value |θ_{c_prop}| of the excitation angle and the thickness of a portion of dielectric film that covers a curved-line region, in a fifth modification of the first example embodiment of the present invention.

FIG. 14 is a schematic enlarged plan view of the vicinity of first offset electrodes in a sixth modification of the first example embodiment of the present invention.

FIG. 15 is a schematic plan view of an acoustic wave device according to a second example embodiment of the present invention.

FIG. 16 is a simplified plan view of an acoustic wave device according to a modification of the second example embodiment of the present invention.

FIG. 17 is a schematic plan view of an acoustic wave device of a first reference example.

FIG. 18 is a schematic plan view of an acoustic wave device of a comparative example.

FIG. 19 is a diagram illustrating impedance-frequency characteristics in the second example embodiment, the first reference example, and the comparative example of the present invention.

FIG. 20 is a diagram illustrating return loss in the second example embodiment and the first reference example of the present invention.

FIG. 21 is a diagram illustrating phase characteristics at lower frequencies than the resonant frequency in the second example embodiment, the first reference example, and the comparative example of the present invention.

FIG. 22 is a schematic plan view for explaining an acoustic wave device of a second reference example.

FIG. 23 is a schematic plan view of an acoustic wave device according to a third example embodiment of the present invention.

FIG. 24 is a simplified plan view of an acoustic wave device according to a modification of the third example embodiment of the present invention.

FIG. 25 is a schematic plan view of an acoustic wave device according to a fourth example embodiment of the present invention.

FIG. 26 is a schematic plan view of an acoustic wave device according to a fifth example embodiment of the present invention.

FIG. 27 is a schematic enlarged plan view of the vicinity of a first edge region and the vicinity of a second edge region in the fifth example embodiment of the present invention.

FIG. 28 is a schematic plan view of an acoustic wave device according to a modification of the fifth example embodiment of the present invention.

FIG. 29 is a schematic plan view of an acoustic wave device according to a sixth example embodiment of the present invention.

FIG. 30 is a schematic plan view of an acoustic wave device according to a modification of the sixth example embodiment of the present invention.

FIG. 31 is a simplified plan view of an acoustic wave device according to a seventh example embodiment of the present invention.

FIG. 32 is a schematic enlarged plan view of a part of an IDT electrode in the seventh example embodiment of the present invention.

FIG. 33 is a schematic plan view of an acoustic wave device according to an eighth example embodiment of the present invention.

FIG. 34 is a schematic plan view of an acoustic wave device according to a modification of the eighth example embodiment of the present invention.

FIG. 35 is a schematic front sectional view of an acoustic wave device according to a ninth example embodiment of the present invention.

FIG. 36 is a schematic front sectional view of an acoustic wave device according to a first modification of the ninth example embodiment of the present invention.

FIG. 37 is a schematic front sectional view of an acoustic wave device according to a second modification of the ninth example embodiment of the present invention.

FIG. 38 is a schematic front sectional view of an acoustic wave device according to a tenth example embodiment of the present invention.

FIG. 39 is a schematic front sectional view of an acoustic wave device according to an eleventh example embodiment of the present invention.

FIG. 40 is a schematic front sectional view of an acoustic wave device according to a first modification of the eleventh example embodiment of the present invention.

FIG. 41 is a schematic front sectional view of an acoustic wave device according to a second modification of the eleventh example embodiment of the present invention.

FIG. 42 is a schematic front sectional view of an acoustic wave device according to a third modification of the eleventh example embodiment of the present invention.

FIG. 43 is a circuit diagram of a filter device according to a twelfth example embodiment of the present invention.

FIG. 44 is a simplified plan view of the IDT electrode in a seventh modification of the first example embodiment of the present invention, illustrating parabolas that approximate the plan-view shapes of the electrode fingers.

FIG. 45 is a simplified plan view of the IDT electrode in an eighth modification of the first example embodiment of the present invention, illustrating one branch of each hyperbola that approximates the plan-view shapes of the electrode fingers.

FIG. 46 is a simplified plan view of an acoustic wave device according to a thirteenth example embodiment of the present invention.

FIG. 47 is a schematic enlarged plan view of areas bounded by dash double-dotted lines Q1 and Q2 in FIG. 46.

FIG. 48 is a simplified plan view of an acoustic wave device according to a fourteenth example embodiment of the present invention.

FIG. 49 is a schematic enlarged plan view of areas bounded by dash double-dotted lines Q3 and Q4 in FIG. 48.

FIG. 50 is a schematic enlarged plan view of areas near the first bus bar and second bus bar of an IDT electrode according to the fifteenth example embodiment of the present invention.

### DETAILED DESCRIPTION OF THE EXAMPLE EMBODIMENTS

Hereinafter, the present invention will be disclosed by describing specific example embodiments of the present invention with reference to the drawings.

Each example embodiment described in this specification is illustrative and partial substitutions or combinations of configurations are possible across different example embodiments.

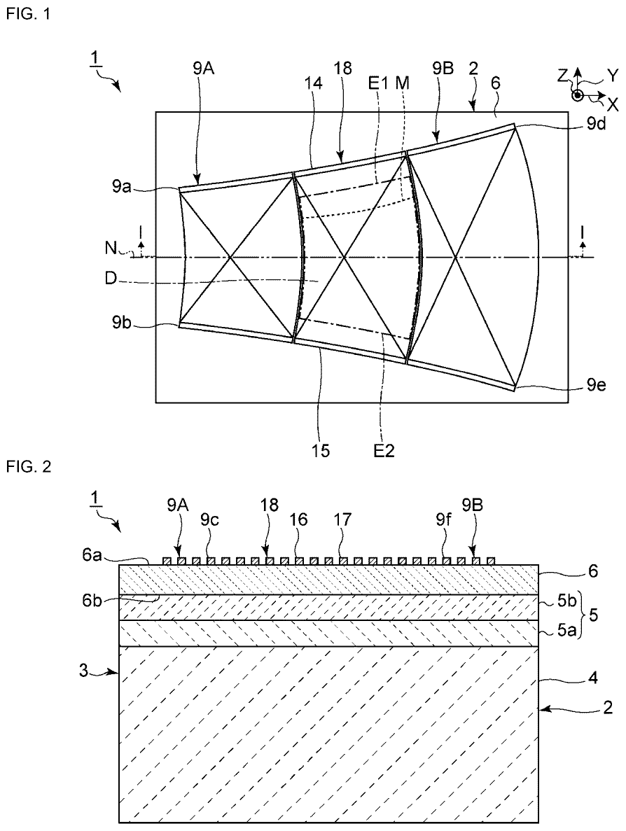

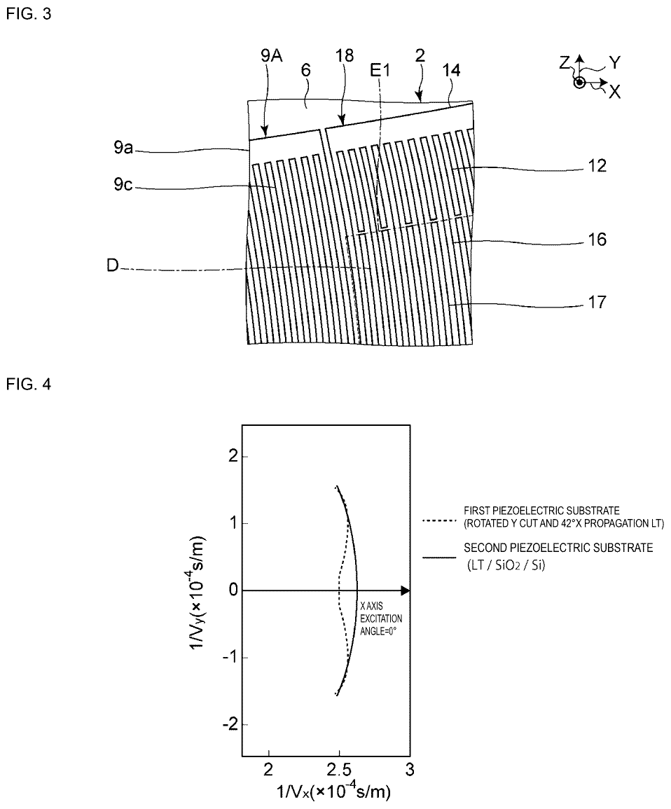

FIG. 1 is a simplified plan view of an acoustic wave device according to a first example embodiment of the present invention. FIG. 2 is a schematic sectional view along a line I-I in FIG. 1. FIG. 3 is a schematic enlarged plan view of a part of the acoustic wave device according to the first example embodiment. In FIG. 1, the electrode configurations other than later-described busbars and reflector busbars are simplified by figures each including two diagonals. The same applies to simplified plan views, other than FIG. 1.

As illustrated in FIGS. 1 and 2, an acoustic wave device 1 includes a piezoelectric substrate 2. As illustrated in FIG. 2, the piezoelectric substrate 2 includes a support 3 and a piezoelectric layer 6. That is, the piezoelectric substrate is a substrate with piezoelectric properties. More specifically, the support 3 includes a support substrate 4 and an intermediate layer 5. The intermediate layer 5 includes a first layer 5a and a second layer 5b. The first layer 5a is provided on the support substrate 4. The second layer 5b is provided on the first layer 5a. The piezoelectric layer 6 is provided on the second layer 5b. The layer structure of the piezoelectric substrate 2 is not limited to that described above. For example, the intermediate layer 5 may be a single dielectric film layer. Alternatively, the piezoelectric substrate 2 may be a substrate including only the piezoelectric layer 6.

The piezoelectric layer 6 of the acoustic wave device 1 is made of a piezoelectric single crystal. In the piezoelectric layer 6, the propagation axis extends in the X-propagation direction. The propagation axis extends parallel or substantially parallel to a dash double-dotted line N illustrated in FIG. 1.

The piezoelectric layer 6 includes a first major surface 6a and a second major surface 6b. The first major surface 6a and the second major surface 6b face each other. Of the first major surface 6a and the second major surface 6b, the second major surface 6b is located on the support substrate 4 side. On the first major surface 6a of the piezoelectric layer 6, an IDT electrode 18 is provided.

As illustrated in FIG. 1, the IDT electrode 18 includes a pair of busbars and a plurality of electrode fingers. Specifically, the pair of busbars include a first busbar 14 and a second busbar 15. The first busbar 14 and the second busbar 15 face each other. As illustrated in FIG. 2, specifically, the plurality of electrode fingers include a plurality of first electrode fingers 16 and a plurality of second electrode fingers 17. One end of each of the plurality of first electrode fingers 16 is connected to the first busbar 14. One end of each of the plurality of second electrode fingers 17 is connected to the second busbar 15. The plurality of first electrode fingers 16 and the plurality of second electrode fingers 17 each include a proximal end portion and a distal end portion. The proximal end portions of the first electrode fingers 16 are portions connected to the first busbar 14. The proximal end portions of the second electrode fingers 17 are portions connected to the second busbar 15. As illustrated in FIG. 3, the plurality of first electrode fingers 16 and the plurality of second electrode fingers 17 are interdigitated with each other. Hereinafter, the first electrode fingers 16 and the second electrode fingers 17 may simply be referred to as electrode fingers. The first busbar 14 and the second busbar 15 may simply be referred to as a busbar.

The distal end portions of the plurality of first electrode fingers 16 and the plurality of second electrode fingers 17 each include a tip. As illustrated in FIG. 3, the virtual line connecting the tips of the plurality of second electrode fingers 17 is referred to as a first envelope E1. Similarly, the virtual line connecting the tips of the plurality of first electrode fingers 16 is referred to as a second envelope E2, which is illustrated in FIG. 1. The region between the first envelope E1 and the second envelope E2 is referred to as an overlap region D.

More specifically, the overlap region D is the region bounded by the first envelope E1 and the second envelope E2, as well as by, among the plurality of electrode fingers, the electrode finger at one end and the electrode finger at the other end in the arrangement direction of the plurality of electrode fingers. The first envelope E1 corresponds to the edge of the overlap region D on the first busbar 14 side. The second envelope E2 corresponds to the edge of the overlap region D on the second busbar 15 side.

In the overlap region D, adjacent electrode fingers overlap each other when viewed in the direction in which the first envelope E1 or the second envelope E2 extends. The portion that includes a portion of each first electrode finger 16 located on the first envelope E1 and is adjacent to the distal end portion of any one of the second electrode fingers 17 is referred to as an adjacent portion of the first electrode finger 16. The portion that includes a portion of each second electrode finger 17 located on the second envelope E2 and is adjacent to the distal end portion of any one of the first electrode fingers 16 is referred to as an adjacent portion of the second electrode finger 17.

The distal end portion of each electrode finger is defined as a portion about 1λ from the tip of the electrode finger in the direction in which the electrode finger extends. Herein, λ is the wavelength determined by the electrode finger pitch of the IDT electrode 18. The range of each adjacent portion is also about 1λ in the direction in which the electrode finger extends. The electrode finger pitch refers to the distance between the centers of each first electrode finger 16 and the second electrode finger 17 adjacent thereto. λ=2p where p is the electrode finger pitch. The electrode finger pitch defining and functioning as the reference for the ranges of the distal end portions and the adjacent portions may be, for example, the smallest electrode finger pitch in the portion where the later-described excitation angle is about 0°.

The overlap region D in the first example embodiment includes a single curved-line region. The curved-line region refers to a region in which the plurality of first electrode fingers 16 and the plurality of second electrode fingers 17 each have a curved plan-view shape. One edge of the curved-line region of the overlap region D is the first envelope E1. The other edge is the second envelope E2. However, it is sufficient that the overlap region D needs to include at least one curved-line region. When the overlap region D includes two or more curved-line regions, one edge of any one of the curved-line regions needs to be the first envelope E1.

In this specification, the term “plan view” refers to a view from a direction corresponding to the upper side in FIG. 2. In FIG. 2, of the support substrate 4 side and the piezoelectric layer 6 side, the piezoelectric layer 6 side is positioned on the upper side.

In the acoustic wave device 1, each of the plurality of first electrode fingers 16 and the plurality of second electrode fingers 17 has a plan-view shape with a gradually varying curvature. Specifically, the plurality of first electrode fingers 16 and the plurality of second electrode fingers 17 have plan-view shapes that can be approximated by circular arcs. However, the plurality of first electrode fingers 16 and the plurality of second electrode fingers 17 may have plan-view shapes that can be approximated by elliptical arcs, for example. The plan-view shape of each electrode finger does not need to be a shape that can be approximated by a circular or elliptical arc. For example, the plan-view shape of each electrode finger may be a parabolic shape, which cannot be approximated by a circular or elliptical arc. Similarly, the plan-view shapes of the plurality of first electrode fingers 16 and the plurality of second electrode fingers 17 are curved shapes other than circular arcs and elliptical arcs.

The first example embodiment has the following configurations: 1) in the curved-line region, each first electrode finger 16 and each second electrode finger 17 had a non-constant curvature, and 2) on the first envelope E1 side in at least one pair of electrode fingers among the plurality of first electrode fingers 16 and the plurality of second electrode fingers 17, the distal end portions, the adjacent portions, or the distal end portions and the adjacent portions have different curvatures from each other. This enables effective reduction or prevention of spurious waves. Hereinafter, the details of the advantageous effects will be described together with the details of the configuration of the IDT electrode 18.

The overlap region D of the IDT electrode 18 in the acoustic wave device 1 illustrated in FIG. 3 is the curved-line region. In the curved-line region, each electrode finger has a curved plan-view shape. Therefore, the excitation direction of acoustic waves is not uniform in the curved-line region of the IDT electrode 18.

Specifically, the excitation direction of an acoustic wave at any given portion of any given electrode finger among the plurality of first electrode fingers 16 and the plurality of second electrode fingers 17 in the curved-line region is any one of first to third directions described below. The first direction is perpendicular or substantially perpendicular to the direction in which the electrode finger extends. The second direction is the direction of the shortest line connecting the electrode finger to the first or second electrode finger 16 or 17 adjacent thereto. The third direction is the direction of an electric field vector generated between the electrode finger and the first or second electrode finger 16 or 17 adjacent thereto.

Because each electrode finger has a curved shape in the curved-line region, the direction in which one electrode finger extends varies from one position to another. In this specification, the direction in which the electrode finger extends is as follows, unless otherwise described.

First of all, it is assumed that each electrode finger includes a pair of edge portions connecting the proximal end portion and the distal end portion in plan view. Both edge portions are curved. When a virtual line segment parallel or substantially parallel to the direction in which the propagation axis extends is drawn at any given portion of the electrode finger so as to connect the both edge portions, the center of gravity of the portion located on the virtual line segment is defined as the representative point of the virtual line segment. On the electrode finger, an infinite number of the virtual line segments can be drawn, and an infinite number of the representative points are also present. The direction in which each electrode finger extends is defined as the direction of the tangent to the curve connecting these representative points.

The angle between the excitation direction of an acoustic wave and the direction in which the propagation axis of the piezoelectric layer 6 extends is referred to as an excitation angle θ_{c_Prop}. The dash double-dotted line N in FIG. 1 indicates portions where the excitation angle θ_{c_prop} is about 0°. The portions where the excitation angle θ_{c_prop} is about 0° are aligned in a straight line. As indicated by a curved line M in FIG. 1, connecting the portions where the excitation angle θ_{c_prop} is uniform and not 0° results in curved lines in the first example embodiment. The curved line M in FIG. 1 is an example of the curved lines where the excitation angle θ_{c_prop} is uniform and not 0°. In the curved-line region, there are an infinite number of curved lines the same as or similar to the curved line M. Thus, in the plan-view shape of the plurality of first electrode fingers 16 and the plurality of second electrode fingers 17, portions where the excitation angle θ_{c_prop} is equal and not 0° are arranged in a curved line.

In this specification, the positive direction of the excitation angle θ_{c_prop} is defined as the counterclockwise direction in plan view. More specifically, the positive direction is the direction from the second busbar 15 toward the first busbar 14.

In the acoustic wave device 1, the direction in which the propagation axis extends is the X-propagation direction. The direction in which the propagation axis extends is not limited thereto and may be, for example, the 90° X-propagation direction. Alternatively, the direction in which the propagation axis extends may be the direction perpendicular or substantially perpendicular to any one of the directions in which the electrode fingers of the IDT electrode 18 extend.

In the curved-line region of the first example embodiment, an infinite number of curved areas where the excitation angle θ_{c_prop} is uniform and not 0° are arranged in the direction in which the first busbar 14 and the second busbar 15 face each other. These curved areas differ in the excitation angle θ_{c_prop}. The areas that differ in the excitation angle θ_{c_prop} have different propagation characteristics for spurious waves. Therefore, spurious waves can be dispersed and effectively reduced or prevented.

In the first example embodiment, resonant frequencies or anti-resonant frequencies are the same or substantially the same throughout the entirety or substantially the entirety of the overlap region D. This enables a more reliable improvement in the resonance characteristics of the acoustic wave device 1. In this specification, “one frequency is substantially the same as another frequency” means that the absolute value of the difference between the both frequencies is, for example, about 10% or less relative to a reference frequency. The reference frequency refers to the frequency when the excitation angle θ_{c_prop} is about 0°. In the overlap region D, the absolute value of the difference between the highest and lowest resonant frequencies of the primary mode is, for example, preferably about 2% or less relative to the reference frequency and more preferably about 1% or less. Alternatively, in the overlap region D, the absolute value of the difference between the highest and lowest anti-resonant frequencies of the primary mode is, for example, preferably about 2% or less relative to the reference frequency and more preferably about 1% or less. This enables a still more reliable improvement in the resonance characteristics.

When the resonant frequencies or anti-resonant frequencies are the same or substantially the same throughout the entirety or substantially the entirety of the overlap region D, spurious waves can be further reduced or prevented. The details thereof will be described below.

The phase velocity of an acoustic wave depends on the excitation angle θ_{c_prop} in the curved-line region and has specific characteristics depending on the substrate structure. The reciprocal of the phase velocity corresponds to a slowness curve. The relationship between the excitation angle θ_{c_prop} and the phase velocity is equal or approximately equal to the slowness curve of the piezoelectric substrate. Examples of the slowness curve of piezoelectric substrates with different layer structures will be illustrated. One of the piezoelectric substrates is, for example, a substrate made of only 42° rotated Y-cut and X-propagation LiTaO₃ (LT). This substrate is referred to a first piezoelectric substrate. The other piezoelectric substrate is a piezoelectric layer/support substrate bonded substrate. This substrate is referred to a second piezoelectric substrate. More specifically, in the second piezoelectric substrate, for example, a silicon substrate of (100) orientation, a silicon oxide film, and a lithium tantalate layer are laminated in this order. Even if the silicon substrate has a different plane orientation, such as (110) or (111) the concave or convex shape of the slowness curve does not change.

FIG. 4 is a diagram illustrating slowness curves of acoustic waves propagating in the first piezoelectric substrate and the second piezoelectric substrate.

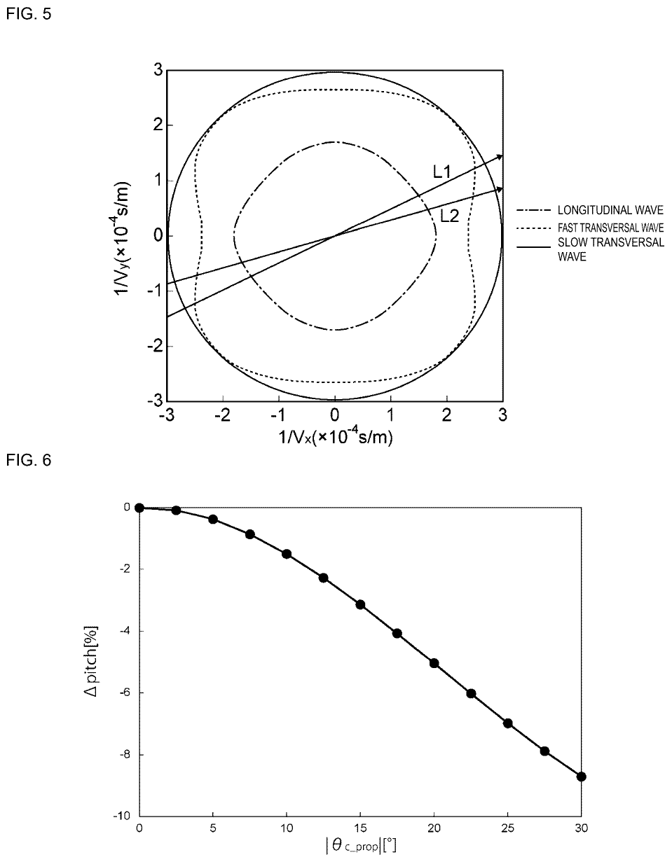

The x-axis illustrated in FIG. 4 corresponds to the results when the excitation direction is parallel or substantially parallel to the propagation axis, that is, when the excitation angle θ_{c_prop} is about 0°. The slowness curves in the first and second piezoelectric substrates are both symmetric with respect to the X-axis as the axis of symmetry. The slowness curve in the first piezoelectric substrate is concave while the slowness curve in the second piezoelectric substrate is convex. The dependence of an acoustic wave propagating in a substrate on the excitation angle θ_{c_prop} varies depending on the substrate structure in such a manner. Furthermore, the dependence of an acoustic wave propagating in the same substrate on the excitation angle θ_{c_prop} varies depending on the mode of the acoustic wave. This will be described with FIG. 5.

FIG. 5 is a diagram illustrating slowness curves of a longitudinal wave, a fast transversal wave, and a slow transversal wave in the first piezoelectric substrate.

As illustrated in FIG. 5, the slowness curves of a longitudinal wave, a fast transversal wave, and a slow transversal wave, which are three types of acoustic wave modes, are different from each other. Regions passing through arrows L1 and L2 in FIG. 5 correspond to result examples when the excitation angle θ_{c_prop} is not 0°. The spacing between the slowness curves of the slow transversal wave and the fast transversal wave in the region passing through the arrow L1 is different from that in the region passing through the arrow L2. In the same or similar manner, the spacing between the slowness curves of the fast transversal wave and the longitudinal wave in the region passing through the arrow L1 is different from that in the region passing through the arrow L2. That is, in the curved-line region, the spacing between slowness curves of different modes varies between portions that differ in the excitation angle θ_{c_prop}. The same applies to the relationship between the primary mode used in the acoustic wave device and spurious waves.

In this case, resonant frequencies or anti-resonant frequencies of the primary mode are the same or substantially the same throughout the entirety or substantially the entirety of the overlap region D in the acoustic wave device 1 of the first example embodiment. Therefore, spurious waves have different frequencies in portions that differ in the excitation angle θ_{c_prop} from each other. Spurious waves outside the pass band are thus dispersed. This allows spurious waves outside the pass band to be further reduced or prevented. In this specification, the term “outside the pass band” in an acoustic wave device refers to frequencies lower than the resonant frequency and frequencies higher than the anti-resonant frequency. In the following description, the term “outside the pass band” in an acoustic wave device may simply be referred to as “outside the band”.

In the first example embodiment, since resonant frequencies or anti-resonant frequencies are the same or substantially the same in the curved-line region, the primary mode is suitably excited. This enables a more reliable improvement in the resonance characteristics.

The phase velocity corresponds to the reciprocal of the slowness curve as described above. The relationship between the excitation angle θ_{c_prop} and the phase velocity is equal or approximately equal to the slowness curve in the X-Y plane of the piezoelectric substrate, as illustrated in FIG. 5. This means that the function representing the curved shape of the electrode fingers is determined based on the shape of the slowness curve in the X-Y plane of the piezoelectric substrate. The phase velocity of acoustic waves depends on the excitation angle θ_{c_prop}.

In the first example embodiment, frequencies of acoustic waves excited in portions that differ in the excitation angle θ_{c_prop} are the same or substantially the same by varying the electrode finger pitch, which affects the frequencies, according to the excitation angle θ_{c_prop}. In portions where the excitation angle θ_{c_prop} is uniform, the electrode finger pitch is constant. The relationship between the excitation angle θ_{c_prop} and the electrode finger pitch is illustrated in FIG. 6.

Herein, the change rate Δpitch [%] of the electrode finger pitch is defined as ((p1−p0)/p0)×100 [%] where p0 is the electrode finger pitch in the portion where the excitation angle θ_{c_prop} is about 0° and p1 is the electrode finger pitch in any portion.

FIG. 6 is a diagram illustrating the relationship between the absolute value |θ_{c_prop}| of the excitation angle and the change rate Δpitch of the electrode finger pitch in the IDT electrode of the first example embodiment.

As illustrated in FIG. 6, in the first example embodiment, Δpitch is about 0% in the portions of the IDT electrode where the excitation angle θ_{c_prop} is about 0°. As the absolute value |θ_{c_prop}| of the excitation angle increases, Δpitch increases in the negative direction. That is, the greater the absolute value |θ_{c_prop}| of the excitation angle, the smaller the electrode finger pitch. This allows resonant frequencies or anti-resonant frequencies to be the same or substantially the same throughout the entirety or substantially the entirety of the overlap region D.

The relationship between the electrode finger pitch and the frequency of each mode depends on the slowness curve of the piezoelectric substrate. In a certain configuration of the piezoelectric substrate, or a certain configuration on the piezoelectric substrate, resonant frequencies or anti-resonant frequencies may be the same or substantially the same throughout the entirety or substantially the entirety of the curved-line region when the electrode finger pitch increases as the absolute value |θ_{c_prop}| of the excitation angle increases. Examples thereof include an acoustic wave device in which an IDT electrode provided on a substrate including only −4° rotated Y-cut and X propagation LiNbO₃ is embedded in a thick SiO₂ film. Alternatively, the electrode finger pitch is not necessarily the largest or smallest in the portion where the excitation angle θ_{c_prop} is about 0°.

In example embodiments of the present invention, resonant frequencies or anti-resonant frequencies do not need to be the same or substantially the same throughout the entirety or substantially the entirety of the overlap region, or the entirety or substantially the entirety of the curved-line region. However, it is preferable that the resonant frequencies or anti-resonant frequencies is the same or substantially the same in at least a part of the curved-line region. In this case, it is sufficient that the electrode finger pitch is made constant in portions where the excitation angle θ_{c_prop} is uniform. Furthermore, it is sufficient that among the portions where the excitation angle θ_{c_prop} is uniform, as the absolute value |θ_{c_prop}| of the excitation angle increases, the electrode finger pitch increases or decreases such that the resonant frequencies or anti-resonant frequencies are the same or substantially the same in at least a portion of the curved-line region.

It is more preferable that resonant frequencies or anti-resonant frequencies are the same or substantially the same throughout the entirety or substantially the entirety of the curved-line region as in the first example embodiment. In this case, for example, it is sufficient that among the portions where the excitation angle θ_{c_prop} is uniform, as the absolute value |θ_{c_prop}| of the excitation angle increases, the electrode finger pitch increases or decreases such that resonant frequencies or anti-resonant frequencies are substantially the same throughout the entirety of the curved-line region. The example thereof is as illustrated in FIG. 6.

Hereinafter, the configuration of the first example embodiment will be described in more detail.

As illustrated in FIG. 3, the IDT electrode 18 includes a plurality of first offset electrodes 12. One end of each of the plurality of first offset electrodes 12 is connected to the first busbar 14. The first electrode fingers 16 and the first offset electrodes 12 are alternately arranged. The plurality of first offset electrodes 12 each include a proximal end portion and a distal end portion. The proximal end portions of the first offset electrodes 12 are portions connected to the first busbar 14. The distal end portions of the first offset electrodes 12 face the respective distal end portions of the second electrode fingers 17 across gaps.

The IDT electrode 18 includes a plurality of second offset electrodes, not illustrated. One end of each of the plurality of second offset electrodes is connected to the second busbar 15, which is illustrated in FIG. 1. The second electrode fingers 17, which are illustrated in FIG. 3, and the second offset electrodes are alternately arranged. The plurality of second offset electrodes each include a proximal end portion and a distal end portion. The proximal end portions of the second offset electrodes are portions connected to the second busbar 15. The distal end portions of the second offset electrodes face the respective distal end portions of the first electrode fingers 16 across gaps.

The plurality of first offset electrodes 12 and the plurality of second offset electrodes do not need to be provided. Hereinafter, the first offset electrodes 12 and the second offset electrodes may be simply referred to as offset electrodes.

As illustrated in FIG. 1, a pair of reflectors 9A and 9B are provided on the piezoelectric layer 6. The reflectors 9A and 9B face each other across the IDT electrode 18 in the direction in which the plurality of electrode fingers of the IDT electrode 18 are arranged. The reflector 9A includes a pair of a reflector busbar 9a and a reflector busbar 9b. The reflector busbar 9a and the reflector busbar 9b face each other. As illustrated in FIG. 2, the reflector 9A includes a plurality of reflector electrode fingers 9c. One end of each of the plurality of reflector electrode fingers 9c is connected to the reflector busbar 9a. The other end of each of the plurality of reflector electrode fingers 9c is connected to the reflector busbar 9b. As illustrated in FIG. 3, the plan-view shape of the plurality of reflector electrode fingers 9c of the reflector 9A includes a curved shape.

In the same or similar manner, as illustrated in FIG. 1, the reflector 9B includes a pair of a reflector busbar 9d and a reflector busbar 9e. As illustrated in FIG. 2, the reflector 9B includes a plurality of reflector electrode fingers 9f.

Hereinafter, examples of the material of each member of the acoustic wave device 1 will be described.

Examples of the material of the support substrate 4, illustrated in FIG. 2, are piezoelectric materials such as aluminum nitride, lithium tantalate, lithium niobate, and quartz, ceramics such as alumina, sapphire, magnesia, silicon nitride, silicon carbide, zirconia, cordierite, mullite, steatite, forsterite, spinel, or sialon, dielectrics such as aluminum oxide, silicon oxynitride, diamond-like carbon (DLC), or diamond, and semiconductors such as silicon, or materials including the above-described materials as the main component. The spinel described above includes an aluminum compound including oxygen and one or more elements selected from Mg, Fe, Zn, Mn, or other elements. Examples of such spinel are MgAl₂O₄, FeAl₂O₄, ZnAl₂O₄, or MnAl₂O₄. The material of the support substrate 4 is, for example, preferably a high-resistance silicon. Preferably, the material of the support substrate 4 has a volume resistivity of, for example, about 1000 Ω·cm or more. In the first example embodiment, the support substrate 4 is made of a high-resistance silicon, for example.

The first layer 5a of the intermediate layer 5 is a high-velocity film. The high-velocity film is a film with a relatively high acoustic velocity. More specifically, the acoustic velocity of bulk waves propagating in the high-velocity film is higher than that of acoustic waves propagating in the piezoelectric layer 6. Examples of the material of the first layer 5a, which is the high-velocity film, include piezoelectric materials such as aluminum nitride, lithium tantalate, lithium niobate or quartz, ceramics such as alumina, sapphire, magnesia, silicon nitride, silicon carbide, zirconia, cordierite, mullite, steatite, forsterite, spinel, or sialon, dielectrics such as aluminum oxide, silicon oxynitride, diamond-like carbon (DLC), or diamond, and semiconductors such as silicon, and materials including the above-described materials as the main component. The spinel described above includes an aluminum compound including, for example, oxygen and one or more elements selected from Mg, Fe, Zn, Mn, or other elements. Examples of such spinel are MgAl₂O₄, FeAl₂O₄, ZnAl₂O₄, or MnAl₂O₄. In the first example embodiment, the first layer 5a is made of silicon nitride, for example.

The second layer 5b of the intermediate layer 5 is a low-velocity film. The low-velocity film is a film with a relatively low acoustic velocity. More specifically, the acoustic velocity of bulk waves propagating in the low-velocity film is lower than that of bulk waves propagating in the piezoelectric layer 6. Examples of the material of the second layer 5b, which is the low-velocity film, include dielectrics, such as, for example, glass, silicon oxide, silicon oxynitride, lithium oxide, tantalate peroxide, or compounds of silicon oxide added with fluorine, carbon, or boron, and materials including the above-described materials as the main component. In the first example embodiment, the second layer 5b is made of silicon oxide, for example.

Examples of the material of the piezoelectric layer 6, which is illustrated in FIG. 2, include lithium tantalate, lithium niobate, zinc oxide, aluminum nitride, quartz, or lead zirconate titanate (PZT). Preferably, the material of the piezoelectric layer 6 is, for example, lithium tantalate or lithium niobate. In the first example embodiment, the piezoelectric layer 6 is made of lithium tantalate, for example.

In the first example embodiment, the first layer 5a as the high-velocity film, the second layer 5b as the low-velocity film, and the piezoelectric layer 6 are laminated on top of each other in this order in the piezoelectric substrate 2. This allows acoustic wave energy to be effectively confined to the piezoelectric layer 6 side.

The IDT electrode 18 and the reflectors 9A and 9B may be made of, for example, one or more types of metal selected from Ti, Mo, Ru, W, Al, Pt, Ir, Cu, Cr, or Sc. The IDT electrode 18 and each reflector may include a single-layer metal film or a multilayer metal film. In the first example embodiment, the IDT electrode 18 and the reflectors 9A and 9B are made of Al, for example.

In this specification, the main component refers to a component that includes more than 50 wt %. The material of the main component may exist in a single-crystal, polycrystalline, or amorphous form, or a mixed form thereof, for example.

An example of the design parameters for the acoustic wave device 1 will be described below. Herein, the dimension of each offset electrode in the direction from its proximal end portion to its distal end portion is referred to as a length of the offset electrode. The dimension of the gap between the distal end portion of each electrode finger and the distal end portion of the corresponding offset electrode, in the direction in which the electrode finger and the offset electrode face each other is referred to as a gap length. In the first example embodiment, the gap between the distal end portion of each second electrode finger 17 and the distal end portion of the corresponding first offset electrode 12 has the same or substantially the same gap length as the gap between the distal end portion of each first electrode finger 16 and the distal end portion of the corresponding second offset electrode.
Support substrate 4: material, Si; plane orientation, (111); φ in Euler angles (φ, θ, ψ), about 73°
Intermediate layer 5: material, SiO₂; thickness, about 0.15λ
Piezoelectric layer 6: material, 55° rotated Y-cut and X-propagation LiTaO₃; thickness, about 0.2λ
IDT electrode 18: material, Al; thickness, about 0.05λ
Wavelength λ: about 2 μm in portions where the excitation angle θ_{c_prop} is about 0°
Number of pairs of electrode fingers of the IDT electrode 18: 100 pairs
Duty ratio: about 0.5
Gap length: about 0.135λ
Reflectors 9A and 9B: number of pairs of electrode fingers of reflectors, 20 pairs

Hereinafter, preferable configurations of example embodiments of the present invention will be described.

Preferably, all of the electrode fingers in the IDT electrode 18 have curved plan-view shapes different from each other. Three specific examples thereof will be illustrated. As the first example, it is preferable that on the first envelope E1 side in all of the first electrode fingers 16 and all of the second electrode fingers 17, the distal end portions, the adjacent portions, or the distal end portions and the adjacent portions have different curvatures from each other. More specifically, the distal end portions of all of the second electrode fingers 17 have different curvatures, the adjacent portions of all of the first electrode fingers 16 have different curvatures, and the distal end portions of all of the second electrode fingers 17 have different curvatures from the adjacent portions of all of the first electrode fingers 16.

As the second example, it is preferable that, on the second envelope E2 side in all of the first electrode fingers 16 and all of the second electrode fingers 17, the distal end portions, the adjacent portions, or the distal end portions and the adjacent portions have different curvatures from each other. More specifically, the distal end portions of all of the first electrode fingers 16 have different curvatures, the adjacent portions of all of the second electrode fingers 17 have different curvatures, and the distal end portions of all of the first electrode fingers 16 have different curvatures from the adjacent portions of all the second electrode fingers 17.

As the third example, it is preferable that in all of the first electrode fingers 16 and all of the second electrode fingers 17, the portions that are located in the area where the excitation angle θ_{c_prop} is about 0° have different curvatures from each other. All of the electrode fingers in the IDT electrode 18 having curved plan-view shapes different from each other like those examples allows spurious waves to be reduced or prevented more reliably and effectively.

The first example embodiment satisfies all of the above-described three examples. However, it is sufficient that on the first envelope E1 side in at least one pair of electrode fingers among the plurality of first electrode fingers 16 and the plurality of second electrode fingers 17, the distal end portions, the adjacent portions, or the distal end portion and the adjacent portion have different curvatures from each other.

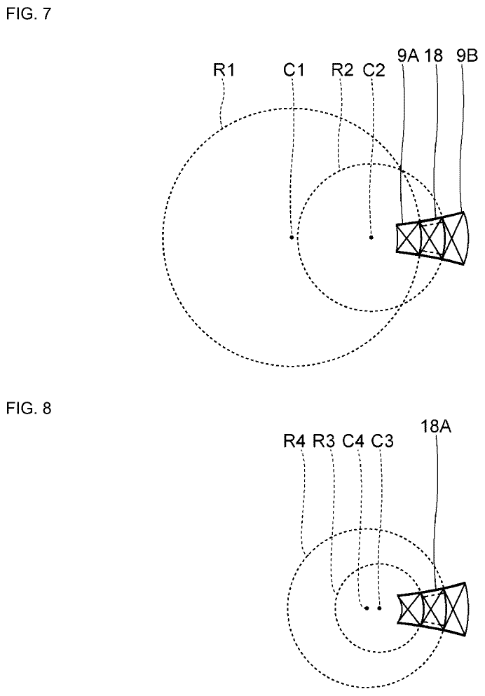

In the first example embodiment, in the curved-line region, the plan-view shapes of the plurality of first electrode fingers 16 and the plurality of second electrode fingers 17 are each any curve that is not a circular or elliptical arc but can be approximated by a circular arc, that is, which appears to be roughly approximated by a circular arc in plan view, and the plan-view shapes of the plurality of first electrode fingers 16 and the plurality of second electrode fingers 17 are curved shapes different from each other. Therefore, the relationship illustrated in FIG. 7 is provided.

FIG. 7 is a simplified plan view of the IDT electrode according to the first example embodiment, illustrating circles that include circular arcs approximating the plan-view shapes of electrode fingers.

In FIG. 7, dashed lines indicate two circles R1 and R2. The circles R1 and R2 include circular arcs approximating the plan-view shapes of two different electrode fingers. The position of a center C1 of the circle R1 is different from the position of a center C2 of the circle R2.

In the curved-line region, it is preferable that when the plan-view shapes of all of the first electrode fingers 16 and all of the second electrode fingers 17 are approximated by circular arcs, the center positions of the circles that include those circular arcs are different from each other. In this case, all of the electrode fingers in the IDT electrode 18 have curved plan-view shapes different from each other. This enables more reliable and effective reduction or prevention of spurious waves. However, it is sufficient that in the curved-line region, when the plan-view shapes of at least one pair of electrode fingers among the plurality of first electrode fingers 16 and the plurality of second electrode fingers 17 are approximated by circular arcs, the center positions of circles that include those circular arcs are different from each other.

In the curved-line region, the plan-view shapes of the plurality of first electrode fingers 16 and the plurality of second electrode fingers 17 can be approximated by elliptical arcs. In this case, it is preferable that when the plan-view shapes of all of the first electrode fingers 16 and all of the second electrode fingers 17 are approximated by elliptical arcs, the centroid positions of the foci of ellipses that include those elliptical arcs be different from each other. However, it is sufficient that, in the curved-line region, when the plan-view shapes of at least one pair of electrode fingers among the plurality of first electrode fingers 16 and the plurality of second electrode fingers 17 are approximated by elliptical arcs, the centroid positions of the foci of ellipses that include those elliptical arcs are different from each other.

As illustrated in FIG. 7, when the side closer to the center C1 of the circle R1 is defined as the inner side of the IDT electrode 18 and the farther side is defined as the outer side, the circle R1 is a circle that includes a circular arc approximating the plan-view shape of the electrode finger located closest to the inner side in the IDT electrode 18. The circle R2 is a circle that includes a circular arc approximating the plan-view shape of the electrode finger located closest to the outer side in the IDT electrode 18. The curvature of the circular arc of the circle R2 is greater than that of the circular arc of the circle R1. Furthermore, when the plan-view shapes of electrode fingers are approximated by a circular arc, the curvature of the circular arcs increases from the inner side to the outer side of the IDT electrode 18 of the acoustic wave device 1. Therefore, the curvature of a circular arc that approximates the plan-view shape of any electrode finger on the outer side can be suitably increased. This enables further reduction or prevention of spurious waves.

In the above description, the inner side and the outer side of the IDT electrode 18 are defined based on the center C1 of the circle R1. However, the center of the circle that includes a circular arc approximating the plan-view shape of any electrode finger is located in the left side of the IDT electrode 18 in FIG. 7. In the first example embodiment, the directions of the inner side and the outer side remain unchanged even when the center of a circle based on the shape of any electrode finger is used as the reference.

The relationship in curvature among the portions of the electrode fingers in the IDT electrode 18, which are illustrated in the above-described three examples, is the same or substantially the same as that between the above-described circular arcs. Specifically, as the first and second examples, the curvature of the distal end portion or the adjacent portion of any first electrode finger 16 or any second electrode finger 17 that is located on the outer side is greater than that of the distal end portion or the adjacent portion of any first electrode finger 16 or any second electrode finger 17 located on the inner side. More specifically, as the first example, the curvature of the distal end portion of any second electrode finger 17 located on the outer side or the adjacent portion of any first electrode finger 16 located on the outer side is greater than that of the distal end portion of any second electrode finger 17 located on the inner side or the adjacent portion of any first electrode finger 16 located on the inner side. As the second example, the curvature of the distal end portion of any first electrode finger 16 located on the outer side or the adjacent portion of any second electrode finger 17 located on the outer side is greater than that of the distal end portion of any first electrode finger 16 located on the inner side or the adjacent portion of any second electrode finger 17 located on the inner side.

As the third example, among the portions of all of the first electrode fingers 16 and all of the second electrode fingers 17 that are located in the area where the excitation angle θ_{c_prop} is about 0°, the curvature of any portion located on the outer side is greater than that of any portion located on the inner side. Satisfying at least one of the magnitude relationships in curvature in the three examples enables further reduction or prevention of spurious waves. The first example embodiment satisfies all of the magnitude relationships in curvature in the three type examples.

When the plan-view shapes of the plurality of electrode fingers can be approximated by elliptical arcs in the curved-line region, the side closer to the centroid of the foci of the ellipse that includes an elliptical arc approximating the plan-view shape of any given electrode finger may be defined as the inner side of the IDT electrode 18, while the farther side may be defined as the outer side. In this case as well, it is preferable that at least one of the magnitude relationships in curvature in the three examples is satisfied. This enables further reduction or prevention of spurious waves.

The magnitude relationships in curvature among the electrode fingers of the IDT electrode 18 are not limited to those described above. In a first modification of the first example embodiment illustrated in FIG. 8, a circle R3 is a circle that includes a circular arc approximating the plan-view shape of the electrode finger located closest to the inner side of an IDT electrode 18A. A circle R4 is a circle that includes a circular arc approximating the plan-view shape of the electrode finger located closest to the outer side of the IDT electrode 18A. The curvature of the circular arc of the circle R4 is smaller than that of the circular arc of the circle R3. Furthermore, in the IDT electrode 18A, the curvature of the circular arcs that approximate the plan-view shapes of the electrode fingers decreases from the inner side to the outer side. This can reduce or prevent deterioration in major electrical characteristics, including fractional bandwidth, fractional stop band width, and Q factor.

The fractional bandwidth is expressed by (|fa−fr|/fr)×100 [%] where fr is the resonant frequency and fa is the anti-resonant frequency. A stop band is a region where acoustic waves are confined to a metal grating having a periodic structure and thereby have constant wavelength. The fractional stop band width is the bandwidth of the stop band divided by the resonant frequency fr. The upper end of the stop band is the end of the stop band on the high-frequency side. The bandwidth of the stop band is the difference between the frequency at the upper end of the stop band and the resonant frequency fr.

The relationships in curvature among the portions of the electrode fingers in the first modification that correspond to the portions of the electrode fingers illustrated in the three examples are the same or substantially the same as the above-described relationships in curvature between the circular arcs. Specifically, as the first and second examples, the curvature of the distal end portion or the adjacent portion of any first electrode finger or any second electrode finger that is located on the outer side is smaller than that of the distal end portion or the adjacent portion of any first electrode finger or any second electrode finger located on the inner side. More specifically, as the first example, the curvature of the distal end portion of any second electrode finger located on the outer side or the adjacent portion of any first electrode finger located on the outer side is smaller than that of the distal end portion of any second electrode finger located on the inner side or the adjacent portion of any first electrode finger located on the inner side. As the second example, the curvature of the distal end portion of any first electrode finger located on the outer side or the adjacent portion of any second electrode finger located on the outer side is smaller than that of the distal end portion of any first electrode finger located on the inner side or the adjacent portion of any second electrode finger located on the inner side.

As the third example, among the portions of all of the first electrode fingers and all of the second electrode fingers that are located in the area where the excitation angle θ_{c_prop} is about 0°, the curvature of any portion located on the outer side is smaller than that of any portion located on the inner side. Satisfying at least one of the magnitude relationships in curvature in the three type examples enables reduction or prevention of deterioration in major electrical characteristics, including fractional bandwidth, fractional stopband width, and Q factor.

Back to FIG. 1, it is preferable that the entirety or substantially the entirety of the overlap region D includes at least one curved-line region. This enables further dispersion of spurious waves outside the pass band and further reduction or prevention of spurious waves outside the pass band. In the first example embodiment, the entirety or substantially the entirety of the overlap region D includes a single curved-line region.

In each of the plurality of first electrode fingers 16 and the plurality of second electrode fingers 17, which are illustrated in FIG. 3, it is preferable that the maximum absolute value of the excitation angle θ_{c_prop} is about 5° or more, for example. This enables further effective reduction or prevention of spurious waves outside the pass band.

In the first example embodiment, the duty ratio in the direction parallel or substantially parallel to the direction in which the propagation axis extends is constant in the curved-line region. This makes it less likely that the width of electrode fingers becomes narrow in the vicinity of the first envelope E1 or the second envelope E2, for example. The width of an electrode finger refers to the dimension of the electrode finger in the direction perpendicular or substantially perpendicular to the direction in which the electrode finger extends. The above configuration of the IDT electrode 18 reduces the likelihood of the electric resistance of each electrode finger becoming high. In addition, the bandwidth of the stop band is less likely to become narrow, leading to good characteristics of the primary mode.

In the first example embodiment, the electrode finger pitch varies according to the excitation angle θ_{c_prop}. This allows resonant frequencies or anti-resonant frequencies to be the same or substantially the same throughout the entirety or substantially the entirety of the curved-line region. The parameters other than the electrode finger pitch may be varied according to the excitation angle θ_{c_prop} such that resonant frequencies or anti-resonant frequencies are the same or substantially the same in at least a portion of the curved-line region.

Specifically, it is preferable that at least one of the duty ratio, the electrode finger pitch, and the thickness of the plurality of first electrode fingers 16 and the plurality of second electrode fingers 17 vary according to the excitation angle θ_{c_prop}. Of these parameters, the parameter that varies according to the excitation angle θ_{c_prop} is constant in the portions where the excitation angle θ_{c_prop} is uniform. Preferably, at least one of these parameters varies according to the excitation angle θ_{c_prop} such that resonant frequencies or anti-resonant frequencies are the same or substantially the same in at least a portion of the curved-line region. More preferably, at least one of these parameters varies according to the excitation angle θ_{c_prop} such that resonant frequencies or anti-resonant frequencies are the same or substantially the same throughout the entirety of the curved-line region. This enables a more reliable improvement in the resonance characteristics.

Alternatively, when another parameter, such as the thickness of the intermediate layer 5 in the piezoelectric substrate 2, affects frequencies, the parameter may be varied according to the excitation angle θ_{c_prop} in the curved-line region. When a dielectric film is provided on the piezoelectric substrate 2 so as to cover the IDT electrode 18, the thickness of the dielectric film may be varied according to the excitation angle θ_{c_prop} in the curved-line region. Among the above-described parameters of the IDT electrode 18 or parameters other than the IDT electrode 18, two or more parameters may be varied according to the excitation angle θ_{c_prop} in the curved-line region. In these cases as well, resonant frequencies or anti-resonant frequencies can be made the same or substantially the same in at least a portion of or across the entirety or substantially the entirety of the curved-line region.

Using second to fifth modifications of the first example embodiment, the following description illustrates examples in which parameters other than the electrode finger pitch are varied according to the excitation angle θ_{c_prop}. According to the second to fifth modifications, similar to the first example embodiment, the resonance characteristics can be more reliably improved, and spurious waves can be effectively reduced or prevented.

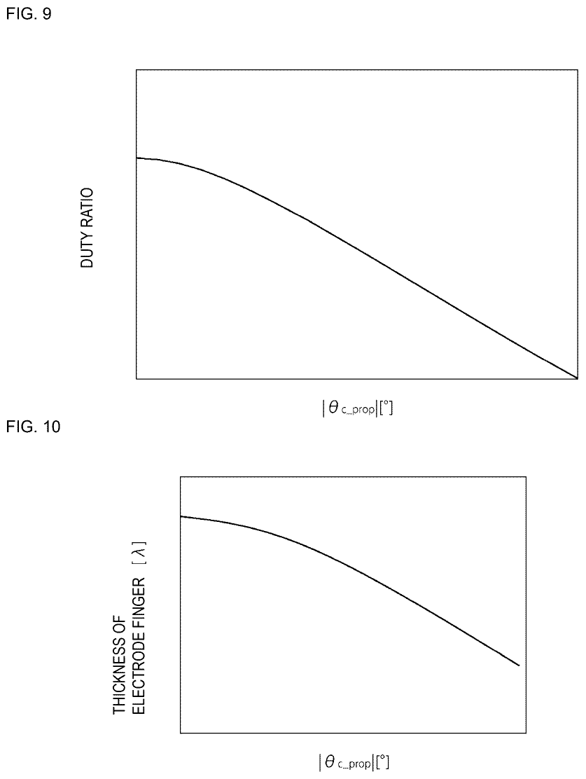

FIG. 9 is a diagram illustrating the relationship between the absolute value |θ_{c_prop}| of the excitation angle and the duty ratio in an IDT electrode according to the second modification of the first example embodiment.

In the second modification, the duty ratio is constant in portions of the plurality of first electrode fingers and the plurality of second electrode fingers where the excitation angle θ_{c_prop} is uniform. The duty ratio is the highest when the excitation angle θ_{c_prop} is about 0°. Among the portions where the excitation angle θ_{c_prop} is uniform, as the absolute value |θ_{c_prop}| of the excitation angle increases, the duty ratio decreases such that resonant frequencies or anti-resonant frequencies are the same or substantially the same throughout the entirety or substantially the entirety of the curved-line region.

The relationship between the duty ratio and the frequency of each mode varies depending on the slowness curve of the piezoelectric substrate. In a certain configuration of the piezoelectric substrate or a certain configuration on the piezoelectric substrate, resonant frequencies or anti-resonant frequencies may be the same or substantially the same throughout the entirety or substantially the entirety of the curved-line region when the duty ratio increases as the absolute value |θ_{c_prop}| of the excitation angle increases. An example thereof can be an acoustic wave device in which an IDT electrode is provided on a −4° rotated Y cut and X propagation substrate including only LiNbO₃ and embedded in a thick SiO₂ film. Alternatively, the duty ratio is not necessarily the highest or the lowest in the area where the excitation angle θ_{c_prop} is about 0°.

The configuration of the second modification is an example of the configuration in which the duty ratio varies according to the excitation angle θ_{c_prop}. For example, it is sufficient that among the portions where the excitation angle θ_{c_prop} is uniform, as the absolute value |θ_{c_prop}| of the excitation angle increases, the duty ratio increases or decreases such that resonant frequencies or anti-resonant frequencies are the same or substantially the same in at least a portion of the curved-line region. In this case as well, the resonance characteristics can be more reliably improved, and spurious waves can be effectively reduced or prevented.

FIG. 10 is a diagram illustrating the relationship between the absolute value |θ_{c_prop}| of the excitation angle and the thickness of electrode fingers in an IDT electrode according to the third modification of the first example embodiment.

In the third modification, the thickness of the plurality of first electrode fingers and the plurality of second electrode fingers is uniform in portions where the excitation angle θ_{c_prop} is uniform. The thickness is the largest when the excitation angle θ_{c_prop} is about 0°. Among the portions where the excitation angle θ_{c_prop} is uniform, as the absolute value |θ_{c_prop}| of the excitation angle increases, the thickness of the plurality of electrode fingers decreases such that resonant frequencies or anti-resonant frequencies are the same or substantially the same throughout the entirety of the curved-line region.

The relationship between the thickness of the first and second electrode fingers and the frequency of each mode varies depending on the slowness curve of the piezoelectric substrate. Therefore, in a certain configuration of the piezoelectric substrate or a certain configuration on the piezoelectric substrate, resonant frequencies or anti-resonant frequencies may be the same or substantially the same throughout the entirety or substantially the entirety of the curved-line region when the thickness of electrode fingers increases as the absolute value |θ_{c_prop}| of the excitation angle increases. An example thereof can be an acoustic wave device in which an IDT electrode is provided on a −4° rotated Y cut X propagation substrate including only LiNbO₃ and embedded in a thick SiO₂ film. Alternatively, the thickness of the first and second electrode fingers is not necessarily the largest or the smallest in the area where the excitation angle θ_{c_prop} is about 0°.

The configuration of the second modification is an example of the configuration in which the thickness of first and second electrode fingers varies according to the excitation angle θ_{c_prop}. It is sufficient that, for example, among the portions where the excitation angle θ_{c_prop} is uniform, as the absolute value |θ_{c_prop}| of the excitation angle increases, the thickness of the plurality of electrode fingers increases or decreases such that resonant frequencies or anti-resonant frequencies are the same or substantially the same in at least a portion of the curved-line region. In this case as well, the resonance characteristics can be more reliably improved, and spurious waves can be effectively reduced or prevented.

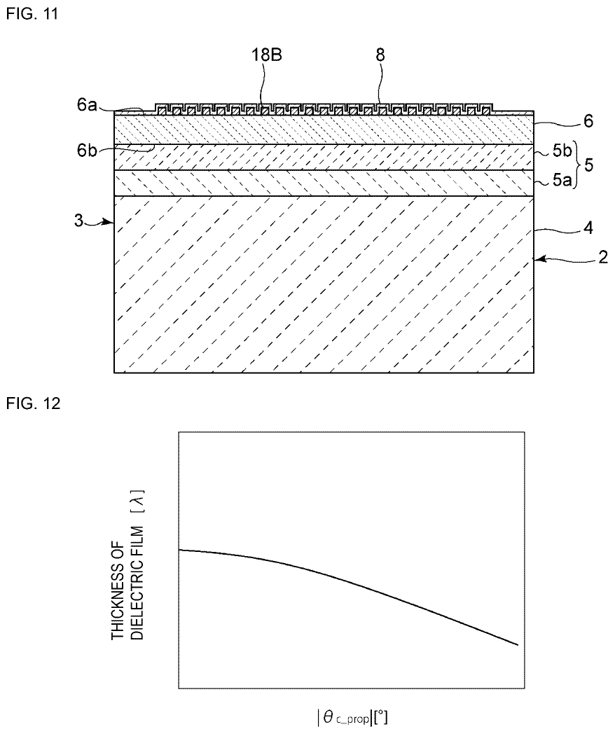

FIG. 11 is a schematic front sectional view of an acoustic wave device according to a fourth modification of the first example embodiment. FIG. 11 illustrates a section corresponding to the portion illustrated in FIG. 2. The same applies to the schematic front sectional views other than FIG. 11.

In the fourth modification, the dielectric film 8 is provided on the piezoelectric layer 6 so as to cover an IDT electrode 18B. The acoustic velocity of transversal waves propagating in the dielectric film 8 in the fourth modification is lower than that of the primary mode propagating in the dielectric film 8. In a portion of the dielectric film 8 that covers the curved-line region, the thickness of the dielectric film 8 is constant on the portions where the excitation angle θ_{c_prop} is uniform. The thickness of the dielectric film 8 varies according to the excitation angle θ_{c_prop}.

FIG. 12 is a diagram illustrating the relationship between the absolute value |θ_{c_prop}| of the excitation angle and the thickness of the portion of dielectric film that covers the curved-line region in the fourth modification of the first example embodiment.

In the fourth modification, as the absolute value |θ_{c_prop}| of the excitation angle increases, the thickness of the dielectric film 8 decreases on the portions where the excitation angle θ_{c_prop} is uniform such that resonant frequencies or anti-resonant frequencies are the same or substantially the same throughout the entirety or substantially the entirety of the curved-line region.

The description of a fifth modification of the first example embodiment refers to FIG. 11. The fifth modification differs from the fourth modification in the material used in the dielectric film 8 and the manner in which its thickness varies. Specifically, in the fifth modification, the acoustic velocity of transversal waves propagating in the dielectric film 8 is higher than that of the primary mode propagating in the dielectric film 8.

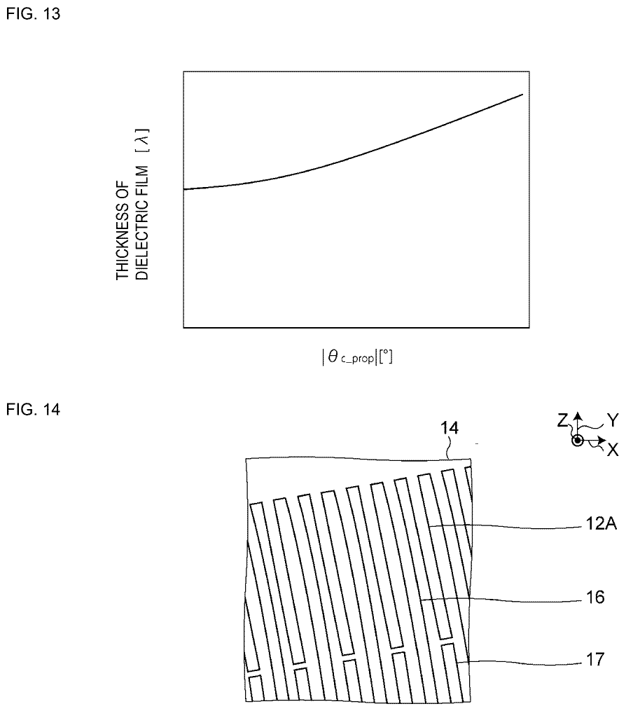

FIG. 13 is a diagram illustrating the relationship between the absolute value |θ_{c_prop}| of the excitation angle and the thickness of the portion of the dielectric film that covers the curved-line region, in the fifth modification of the first example embodiment.

In the fifth modification, as the absolute value |θ_{c_prop}| of the excitation angle increases, the thickness of the dielectric film 8 increases on the portions where the excitation angle θ_{c_prop} is uniform such that resonant frequencies or anti-resonant frequencies are the same or substantially the same throughout the entirety or substantially the entirety of the curved-line region.

In a certain configuration of the piezoelectric substrate or the like, the thickness of the dielectric film is not necessarily the largest or the smallest on the portions where the excitation angle θ_{c_prop} is about 0°.

The configurations of the fourth and fifth modifications are examples of the configuration in which the thickness of the dielectric film 8 varies according to the excitation angle θ_{c_prop}. For example, it is sufficient that as the absolute value |θ_{c_prop}| of the excitation angle increases, the thickness of the dielectric film 8 increases or decreases on the portions where the excitation angle θ_{c_prop} is uniform such that resonant frequencies or anti-resonant frequencies are the same or substantially the same in at least a part of the curved-line region. In this case as well, the resonance characteristics can be more reliably improved, and spurious waves can be effectively reduced or prevented.

According to the first example embodiment and the second to fifth modifications, the advantageous effects of effectively reducing or preventing spurious waves can be achieved even if the excitation angle θ_{c_prop} deviates, for example, approximately ±1° to 2° in the relationship between each parameter and the excitation angle θ_{c_prop}.

As illustrated in FIG. 3, it is preferable that the IDT electrode 18 includes the plurality of first offset electrodes 12. The primary mode excited in the overlap region D tends to leak to the first busbar 14 side. In the first example embodiment, the leaked primary mode can be reflected by the plurality of first offset electrodes 12 to the overlap region D side. This enables reduction or prevention of the leakage of the primary mode from the overlap region D to the first busbar 14 side.

Similarly, it is preferable that the IDT electrode 18 includes the plurality of second offset electrodes. This enables reduction or prevention of the leakage of the primary mode from the overlap region D to the second busbar 15 side.

In the first example embodiment, the plurality of first offset electrodes 12 have curved plan-view shapes. Each of the first offset electrodes 12 has a non-constant curvature. Specifically, the plurality of first offset electrodes 12 have curved plan-view shapes the same as or similar to the plurality of first electrode fingers 16 and the plurality of second electrode fingers 17. More specifically, the plurality of first offset electrodes 12 have plan-view shapes that can be approximated by circular arcs. When the plan-view shapes of any of the first offset electrode 12 and the second electrode finger 17 facing the first offset electrode 12 are individually approximated by circular arcs, the circles that include the respective circular arcs are the same or substantially the same.

The distal end portions of all of the first offset electrodes 12 in the acoustic wave device 1 have different curvatures from each other. This allows the conditions in the overlap region D, where the primary mode is excited, to be brought at least closer to, or even matched to, the conditions in the region where the plurality of first offset electrodes 12 are provided. The primary mode can thus be effectively reflected to the overlap region D side. This enables effective reduction or prevention of the leakage of the primary mode. However, it is sufficient that among the plurality of first offset electrodes 12, the distal end portions of at least one pair of first offset electrodes 12 have different curvatures from each other. The leakage of the primary mode can be reliably reduced or prevented in this case as well.

Similarly, the plurality of second offset electrodes have curved plan-view shapes. Each of the second offset electrodes has a non-constant curvature. More specifically, when the plan-view shapes of any second offset electrode and the first electrode finger 16 facing the second offset electrode are individually approximated by circular arcs, the circles that include the respective circular arcs are the same or substantially the same. The distal end portions of all of the second offset electrodes have different curvatures from each other. However, it is sufficient that among the plurality of second offset electrodes, the distal end portions of at least one pair of second offset electrodes have different curvatures from each other. Therefore, the leakage of the primary mode can be more reliably reduced or prevented.

In the curved-line region, when the plurality of electrode fingers have plan-view shapes that can be approximated by elliptical arcs, it is also preferable that the plurality of first offset electrodes 12 have curved plan-view shapes and each of the first offset electrodes 12 has a non-constant curvature. Preferably, the plurality of first offset electrodes 12 have plan-view shapes that can be approximated by elliptical arcs. When the plan-view shapes of a first offset electrode 12 and the second electrode finger 17 facing the given first offset electrode 12 are individually approximated by elliptical arcs, it is preferable that the ellipses that include the respective elliptical arcs are the same or substantially the same. Preferably, the distal end portions of at least one pair of first offset electrodes 12 among the plurality of first offset electrodes 12, have different curvatures from each other. More preferably, the distal end portions of all of the first offset electrodes 12 have different curvatures from each other. The leakage of the primary mode can thus be more reliably reduced or prevented. The same applies to the plurality of second offset electrodes.

The plan-view shapes of the first offset electrodes 12 and the second offset electrodes are not limited to curved shapes. In a sixth modification of the first example embodiment, illustrated in FIG. 14, first offset electrodes 12A and second offset electrodes have linear plan-view shapes. In this case, the distance between the distal end portion of each first offset electrode 12A and the first busbar 14 can be made short. Similarly, the distance between the distal end portion of each second offset electrode and the second busbar can be made short. This can reduce the electric resistance of the IDT electrode. When such an acoustic wave device is used in a filter device, it is therefore possible to reduce or prevent an increase in insertion loss. According to the sixth modification, in the same or similar manner to the first example embodiment, the resonance characteristics can be improved, and spurious waves can be effectively reduced or prevented.

As illustrated in FIG. 3, in the first example embodiment, the plurality of reflector electrode fingers 9c in the reflector 9A have plan-view shapes that can be approximated by circular arcs. The shapes of the reflector electrode fingers 9c correspond to the shapes of the respective electrode fingers in the curved-line region of the IDT electrode 18. More specifically, when the plan-view shapes of two different reflector electrode fingers 9c of the reflector 9A are approximated by circular arcs, the center positions of the circles that include the respective circular arcs are different from each other. The same applies to the plurality of reflector electrode fingers 9f of the reflector 9B, which is illustrated in FIG. 2. The resonance characteristics of the acoustic wave device 1 can thus be more reliably improved.

The plan-view shapes of the reflector electrode fingers may be curved or linear shapes that do not correspond to the shapes of the electrode fingers in the curved-line region of the IDT electrode 18. However, it is preferable that each reflector electrode finger includes a curved shape.

As described above, the direction in which the propagation axis extends is parallel or substantially parallel to the dash double-dotted line N, which is illustrated in FIG. 1. In the IDT electrode 18, the first envelope E1 and the second envelope E2 extend at an angle to the propagation axis. The first envelope E1 and the second envelope E2 may extend parallel or substantially parallel to the direction in which the propagation axis extends. However, it is preferable that at least one of the first envelope E1 and the second envelope E2 extend at an angle to the propagation axis. More preferably, both of the first envelope E1 and the second envelope E2 extend at an angle to the propagation axis. This enables reduction or prevention of transverse modes. The transverse modes are spurious waves produced between the resonant frequency and the anti-resonant frequency.

In the first example embodiment and each modification, the plan-view shapes of the plurality of electrode fingers and the plurality of reflector electrode fingers are smooth curved shapes. However, the curved lines in the plan-view shapes of the plurality of electrode fingers and the plurality of reflector electrode fingers do not need to be smooth curved lines. For example, the curved lines in the plan-view shapes of the plurality of electrode fingers and the plurality of reflector electrode fingers may have shapes configured by connecting straight lines of minute size.

In the cases where the duty ratio is varied, as in the second modification of the first example embodiment, the width of each electrode finger does not need to vary continuously along its length. The width of each electrode finger may vary discontinuously. In this case, for example, it is sufficient that each electrode finger has a structure corresponding to a structure in which a plurality of portions are connected, and at connecting portions in which different portions are connected, the connected portions differ in width from each other. The same applies to each reflector electrode finger.

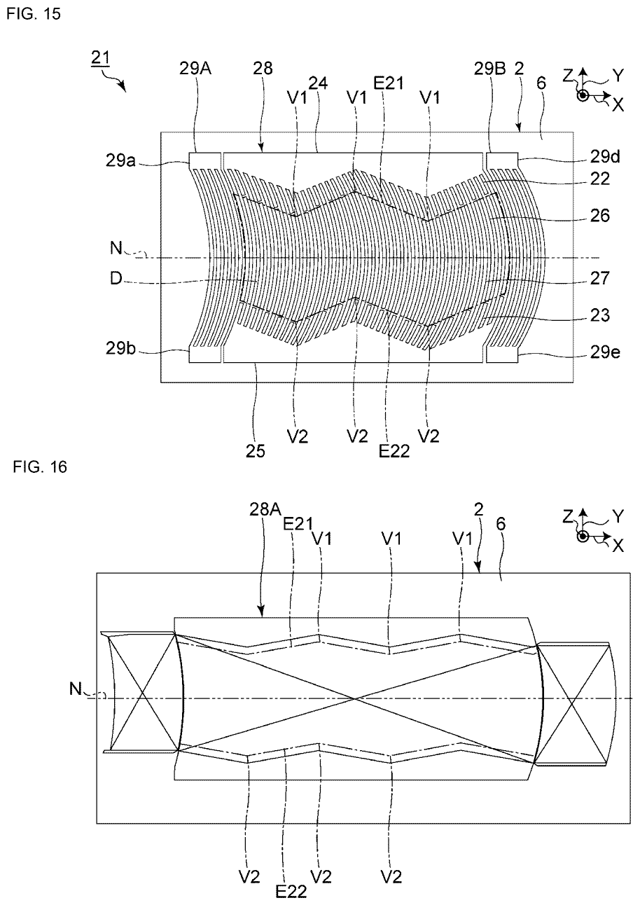

FIG. 15 is a schematic plan view of an acoustic wave device according to a second example embodiment of the present invention.

The second example embodiment differs from the first example embodiment in the configurations of an IDT electrode 28 and reflectors. Each reflector has a shape corresponding to the shape of the IDT electrode 28. An acoustic wave device 21 of the second example embodiment has the same or substantially the same configuration as the acoustic wave device 1 of the first example embodiment other than the above point.

A first envelope E21 in the acoustic wave device 21 includes a plurality of portions that are inclined with respect to the propagation axis. The first envelope E21 includes a plurality of bent portions V1. More specifically, the bent portions are portions at which the envelope changes its extending direction. In the second example embodiment, the first envelope E21 has a wavy shape configured by connecting each bent portion V1 to its adjacent bent portion V1 with a straight line. The first envelope E21 may have another wavy shape configured by connecting each bent portion V1 to its adjacent bent portion V1 with a curved line.

Similarly, a second envelope E22 also includes a plurality of portions that are inclined with respect to the propagation axis. The second envelope E22 includes a plurality of bent portions V2. The second envelope E22 has a wavy shape configured by connecting each bent portion V2 to its adjacent bent portion V2 with a straight line. The second envelope E22 may have another wavy shape configured by connecting each bent portion V2 to its adjacent bent portion V2 with a curved line.

As described above, in the second example embodiment, both of the first envelope E21 and the second envelope E22 include a plurality of bent portions. However, it is sufficient that at least one of the first envelope E21 and the second envelope E22 includes at least one bent portion.

The IDT electrode 28 includes a plurality of segments, which are partitioned by the electrode fingers passing through the respective bent portions V1 of the first envelope E21. The plurality of segments are arranged in the direction in which the propagation axis extends. FIG. 15 schematically illustrates four segments.

The plurality of electrode fingers of the IDT electrode 28 have plan-view shapes that can be approximated by circular arcs. In the IDT electrode 28, the curvature of circular arcs that approximate the plan-view shapes of the electrode fingers increases from the inner side to the outer side.

Herein, the excitation angle θ_{c_prop} in a portion located at each end portion or each bent portion V1 of the first envelope E21 is referred to as a first envelope excitation angle θ_{c_AP1_k}. k is a natural number. The first envelope excitation angle θ_{c_AP1_k} can be defined for each end portion or each bent portion V1 of the first envelope E21. Specifically, k in the first envelope excitation angle θ_{c_AP1_k} is 1, 2, 3, . . . in order from the end portion and the bent portion V1 on the inner side of the IDT electrode 28. In such a manner, k in the first envelope excitation angle θ_{c_AP1_k} has a smaller numerical value for a portion closer to the inner side. For example, the excitation angle θ_{c_prop} in a portion located at the above-described end portion on the inner side is the first envelope excitation angle θ_{c_AP1_1}. The excitation angle θ_{c_prop} in the innermost bent portion V1 is the first envelope excitation angle θ_{c_AP1_2}.

Similarly, the excitation angle θ_{c_prop} in a portion located at each end portion or each bent portion V2 of the second envelope E22 is referred to as a second envelope excitation angle θ_{c_AP2_k}. k in the second envelope excitation angle θ_{c_AP2_k} has a smaller numerical value for a portion located on the inner side.

In the second example embodiment, the first envelope excitation angles θ_{c_AP1_k} and the second envelope excitation angles θ_{c_AP2_k} are as follows. The following description illustrates examples for k=1 and k=2.

First envelope excitation angle: θ_{c_AP1_1}=about 11°, θ_{c_AP1_2}=about 10°

Second envelope excitation angle: θ_{c_AP2_1}=about 9°, θ_{c_AP2_2}=about 13°

FIG. 15 schematically illustrates four segments as described above. FIG. 16 illustrates five segments in the IDT electrode in a simplified manner. It is assumed for convenience that an IDT electrode 28A illustrated in FIG. 16 is an IDT electrode in a modification of the second example embodiment. The IDT electrode 28 of the second example embodiment may include five segments or six or more segments, for example. The first envelope excitation angles θ_{c_AP1_k} and the second envelope excitation angles θ_{c_AP2_k} in the IDT electrode 28A are as follows.

First envelope excitation angle: θ_{c_AP1_1}=about 11°, θ_{c_AP1_2}=about 9.5°, θ_{c_AP1_3}=about 13°, θ_{c_AP1_4}=about 10°, θ_{c_AP1_5}=about 13°, θ_{c_AP1_6}=about 100

Second envelope excitation angle: θ_{c_AP2_1}=about 9°, θ_{c_AP2_2}=about 12°, θ_{c_AP2_3}=about 10°, θ_{c_AP2_4}=about 12.8°, θ_{c_AP2_5}=about 10°, θ_{c_AP2_6}=about 13°

In the second example embodiment and the modification thereof, each electrode finger in the curved-line region has a non-constant curvature in the same or similar manner to the first example embodiment. Furthermore, on the first envelope E21 side in the plurality of electrode fingers, the distal end portions, the adjacent portions, or the distal end portions and the adjacent portions have different curvatures from each other. This enables effective reduction or prevention of spurious waves outside the pass band. In addition, the first envelope E21 and the second envelope E22 are inclined with respect to the propagation axis. This enables reduction or prevention of transverse modes.

Furthermore, among the portions where the excitation angle θ_{c_prop} is uniform, any one of the duty ratio, the electrode finger pitch, and the electrode finger thickness varies according to the excitation angle θ_{c_prop} such that resonant frequencies or anti-resonant frequencies are the same or substantially the same across the entirety or substantially the entirety of the curved-line region. This enables a more reliable improvement in the resonance characteristics in the same or similar manner to the first example embodiment. The above-described advantageous effects will be specifically illustrated below by comparing the second example embodiment with a first reference example and a comparative example.

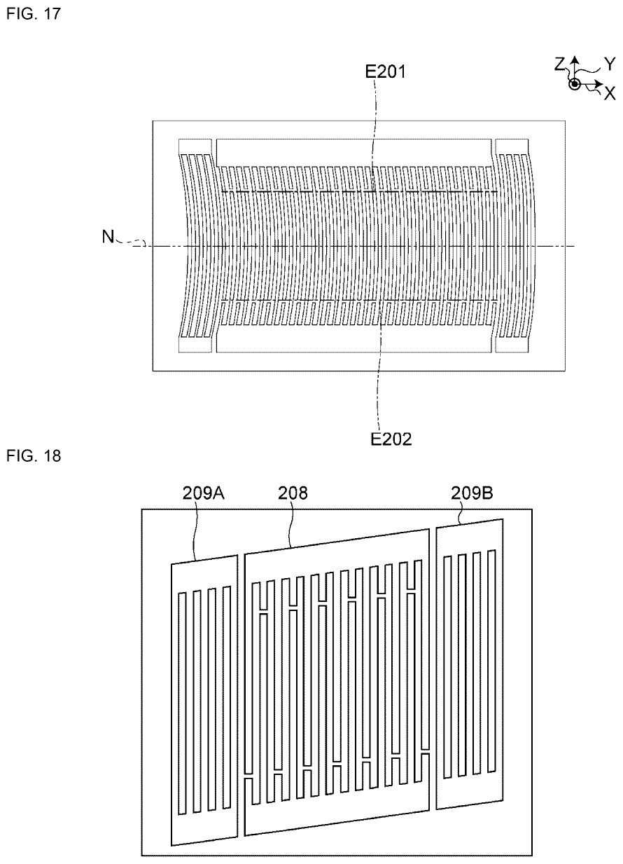

As illustrated in FIG. 17, the first reference example differs from the second example embodiment in that neither a first envelope E201 nor a second envelope E202 is inclined with respect to the propagation axis. Furthermore, the first reference example also differs from the second example embodiment in that the plan-view shapes of all of the electrode fingers of the IDT electrode and all of the reflector electrode fingers of the reflectors are circular arcs, and the circles that include the respective circular arcs are concentric.

The acoustic wave device of the comparative example is a conventional inclined acoustic wave device as illustrated in FIG. 18. In the acoustic wave device of the comparative example, each electrode finger of an IDT electrode 208 and each reflector electrode finger of reflectors 209A and 209B have a linear plan-view shape. The first and second busbars extend at an angle with respect to the direction perpendicular or substantially perpendicular to the direction in which the plurality of electrode fingers extend. In the IDT electrode 208, the overlap region is parallelogram-shaped, for example. The second example embodiment, the first reference example, and the comparative example are compared in terms of their impedance-frequency characteristics and phase characteristics. The second example embodiment and the first reference example are compared in terms of their return loss.

In the acoustic wave device 21 of the second example embodiment relating to the comparison, the absolute values of the inclination angles of the first envelope E21 and the second envelope E22 with respect to the propagation axis are set to about 10°, for example. The numbers of pairs of electrode fingers between adjacent bent portions V1 and between adjacent bent portions V2 are set to 20 pairs, for example. In the comparative example, the direction in which the plurality of electrode fingers extend is referred to as an electrode finger extension direction, and the dimension of the overlap region in the electrode finger extension direction is referred to as an overlap width. The overlap width in the IDT electrode 208 of the acoustic wave device of the comparative example is about 25λ, for example. The number of pairs of electrode fingers in the IDT electrode 208 is 100 pairs, for example. In the IDT electrode 208, the duty ratio is about 0.5, for example. The angle of each busbar with respect to the direction perpendicular or substantially perpendicular to the electrode finger extension direction is about 7.5°, for example.

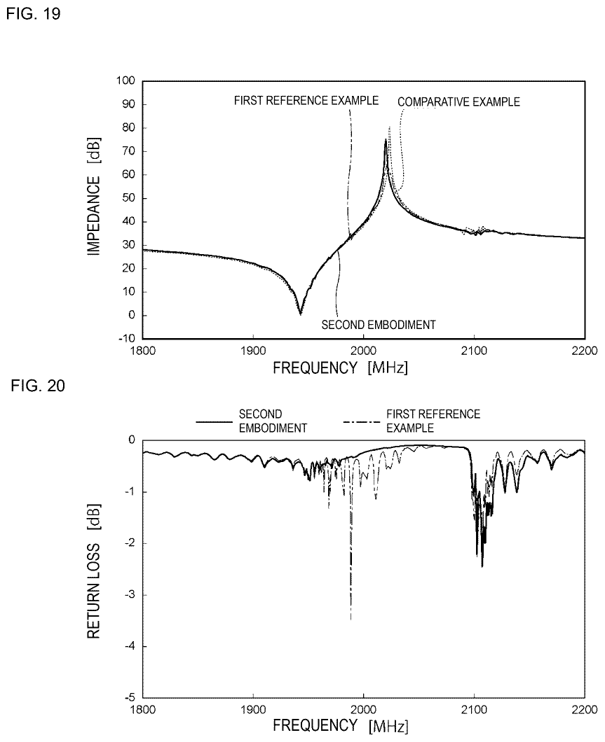

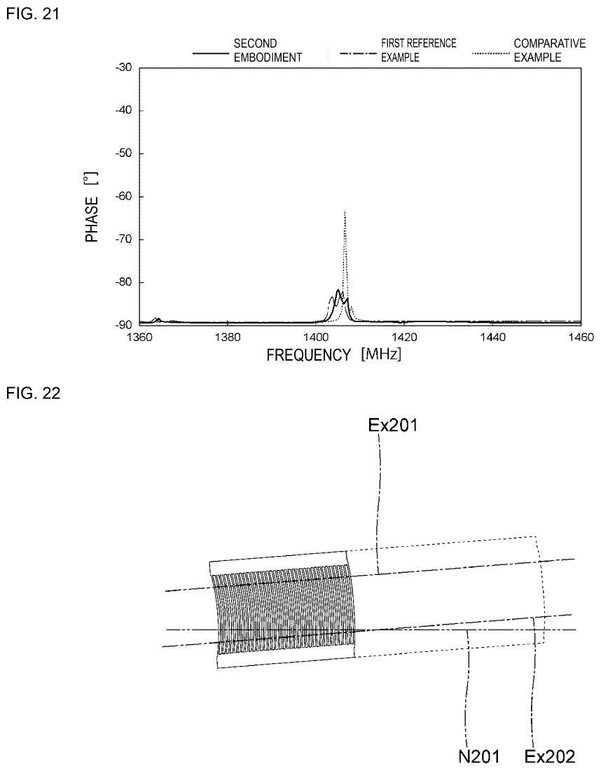

FIG. 19 is a diagram illustrating the impedance-frequency characteristics in the second example embodiment, the first reference example, and the comparative example. FIG. 20 is a diagram illustrating the return loss in the second example embodiment and the first reference example. FIG. 21 is a diagram illustrating the phase characteristics at lower frequencies than the resonant frequency in the second example embodiment, the first reference example, and the comparative example.

As illustrated in FIG. 19, there is no significant difference in resonance characteristics among the second example embodiment, the first reference example, and the comparative example. That is, in the second example embodiment, the deterioration in the resonance characteristics is reduced or prevented, and the resonance characteristics are favorable.

As illustrated in FIGS. 19 and 20, transverse modes are generated between the resonant frequency and the anti-resonant frequency in the first reference example. In contrast, transverse modes are reduced or prevented in the second example embodiment.

As illustrated in FIG. 21, large spurious waves are generated at lower frequencies than the resonant frequency in the comparative example. The spurious waves illustrated in FIG. 21 are Rayleigh waves. In contrast, it is revealed that spurious waves are reduced or prevented in the second example embodiment, compared to the comparative example.

In the second example embodiment, which is illustrated in FIG. 15, because each electrode finger has a curved plan-view shape in the same or similar manner to the first example embodiment, spurious waves can be reduced or prevented. In the second example embodiment, in addition, the first envelope excitation angle θ_{c_AP1_k} differs between each pair of adjacent bent portions V1 on the first envelope E21. Similarly, the second envelope excitation angle θ_{c_AP2_k} differs between each pair of adjacent bent portions V2 on the second envelope E22. Therefore, for each electrode finger, the excitation angle θ_{c_prop} varies within a different range.

As described above, the spacing between the slowness curves of the primary mode and spurious waves differs between portions that differ in the excitation angle θ_{c_prop}. In the second example embodiment, however, resonant frequencies or anti-resonant frequencies of the primary mode are the same or substantially the same throughout the entirety or substantially the entirety of the curved-line region. In the second example embodiment, furthermore, the circular arcs that approximate the plan-view shapes of the respective electrode fingers have different lengths. Therefore, the excitation angle θ_{c_prop} varies within a different range in each electrode finger as a whole. The frequency range of excited spurious waves varies with the location of each electrode finger. Therefore, spurious waves can be effectively dispersed. This enables effective reduction or prevention of spurious waves and transverse modes outside the pass band.

According to the second example embodiment, furthermore, spurious waves can be reduced or prevented while the Q factor is improved. This is because the first envelope E21 and the second envelope E22 of the second example embodiment include the bent portions. The details thereof will be described below with reference to a second reference example.

An acoustic wave device of the second reference example, which is schematically illustrated in FIG. 22, differs from the second example embodiment in that the first envelope and the second envelope do not include any bent portion. A dash-dotted line Ex201 in FIG. 22 is a virtual line including the first envelope and an extension of the first envelope. A dash-dotted line Ex202 is a virtual line including the second envelope and an extension of the second envelope. In the second reference example, the first envelope and the second envelope are inclined with respect to the propagation axis.

Generally, to improve the resonance characteristics of acoustic wave devices, the number of pairs of electrode fingers of the IDT electrode is increased. In acoustic wave devices, normally, among the components of the primary mode, the characteristics of the component propagating in the direction in which the propagation axis extends has the most favorable characteristics. A dash double-dotted line N201 in FIG. 22 indicates an area where the primary mode propagates in the direction in which the propagation axis extends. Specifically, the dash double-dotted line N201 is a virtual line indicating an area where the normal direction to the direction in which each curved electrode finger extends is parallel or substantially parallel to the direction in which the propagation axis extends.

To improve the Q factor and the resonance characteristics in the second reference example, for example, additional electrode fingers may be provided in the area indicated by the dashed line in FIG. 22. However, in this case, the IDT electrode includes a lot of electrode fingers that are not located on the dash double-dotted line N201. That means an increase in the proportion of the area where the primary mode does not propagate in the direction in which the propagation axis extends in the IDT electrode. In this case, it is difficult to sufficiently improve the Q factor.

On the other hand, in the second example embodiment, the region on the dash double-dotted line N in FIG. 15 corresponds to the region where the primary mode propagates in the direction in which the propagation axis extends. In the acoustic wave device 21, the first envelope E21 and the second envelope E22 include the bent portions. This can increase the proportion of the area where the primary mode propagates in the direction in which the propagation axis extends. Therefore, the Q factor can be effectively improved.

Preferably, for example, at least about 50% of all of the electrode fingers include a portion where the normal direction to the direction in which the electrode finger extends is the same or substantially the same as the direction in which the propagation axis extends. More preferably, for example, about 80% or more of all of the electrode fingers include a portion where the normal direction to the direction in which the electrode finger extends is the same or substantially the same as the direction in which the propagation axis extends. This enables more reliable improvement of the Q factor. In the second example embodiment, all of the electrode fingers include a portion where the normal direction to the direction in which the electrode finger extends is the same or substantially the same as the direction in which the propagation axis extends. Therefore, the Q factor can be improved even more reliably and effectively.

Preferably, the first envelope E21 includes a plurality of bent portions V1 in the same or similar manner to the second example embodiment. This allows for a configuration in which a larger number of electrode fingers include a portion where the normal direction to the direction in which the electrode finger extends is the same or substantially the same as the direction in which the propagation axis extends. Therefore, the Q factor can be more reliably improved.

In the second example embodiment, a portion of the first busbar 24 on the first envelope E21 side has a wavy plan-view shape as illustrated in FIG. 15. The distance between the first busbar 24 and the first envelope E21 in the direction perpendicular or substantially perpendicular to the propagation axis is constant. Furthermore, the plurality of first offset electrodes 22 have the same or substantially the same length. The gaps between the distal end portions of the second electrode fingers 27 and the distal end portions of the first offset electrodes 22 also have the same or substantially the same length. In such a manner, the gap length can be made uniform without extending the first offset electrodes 22 in accordance with the shape of the first envelope E21. This enables more reliable reduction or prevention of the leakage of the primary mode without increasing the electric resistance of the IDT electrode 28.

Similarly, the distance between the second busbar 25 and the second envelope E22 in the direction perpendicular or substantially perpendicular to the propagation axis is constant. A plurality of second offset electrodes 23 have the same or substantially the same length. The gaps between the distal end portions of the first electrode fingers 26 and the distal end portions of the second offset electrodes 23 also have the same or substantially the same length. This enables more reliable reduction or prevention of the leakage of the primary mode without increasing the electric resistance of the IDT electrode 28.

In the second example embodiment, the dimension corresponding to the period of the wavy shape and the dimension corresponding to the amplitude in the first envelope E21 are constant. Specifically, the dimension corresponding to the period refers to the component, in the direction in which the propagation axis extends, of the distance between the bent portions V1 located at both ends among three successive bent portions V1. The dimension corresponding to the amplitude refers to the component in the direction perpendicular or substantially perpendicular to the propagation axis, of the distance between adjacent bent portions V1. In the first envelope E21, at least one of the dimension corresponding to the period of the wavy shape and the dimension corresponding to the amplitude does not need to be constant. For example, in the first envelope E21, both of the dimension corresponding to the period of the wavy shape and the dimension corresponding to the amplitude may vary randomly. In this case, transverse modes can be effectively reduced or prevented.

The dimensions corresponding to the period and amplitude of the wavy shape of the second envelope E22 are defined in the same manner as the first envelope E21. In the second envelope E22 as well, at least one of the dimension corresponding to the period of the wavy shape and the dimension corresponding to the amplitude does not need to be constant. For example, in the second envelope E22, both of the dimension corresponding to the period of the wavy shape and the dimension corresponding to the amplitude may vary randomly.

In the second example embodiment, the inclination angles of the first envelope E21 and the second envelope E22 each have a constant absolute value. In example embodiments of the present invention, the inclination angles of the first envelope E21 and the second envelope E22 do not need to have a constant absolute value. For example, the inclination angle may vary randomly.

In the acoustic wave device 21, reflector busbars 29a and 29b of the reflector 29A extend parallel or substantially parallel to the direction in which the propagation axis extends. Similarly, reflector busbars 29d and 29e of the reflector 29B extend parallel or substantially parallel to the direction in which the propagation axis extends. However, each reflector busbar of each reflector may extend at an angle with respect to the propagation axis. A portion of each reflector busbar on the reflector electrode finger side may have a wavy plan-view shape in the same or similar manner to each busbar of the IDT electrode 28.

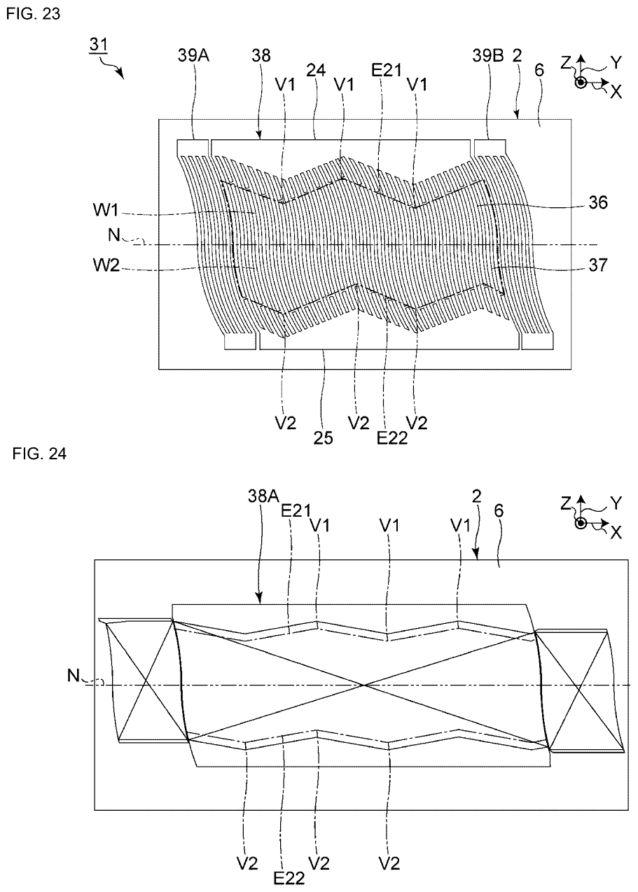

FIG. 23 is a schematic plan view of an acoustic wave device according to a third example embodiment of the present invention.

The third example embodiment differs from the second example embodiment in the configurations of an IDT electrode 38 and reflectors. Each reflector has a shape corresponding to the IDT electrode 38. An acoustic wave device 31 of the third example embodiment has the same or substantially the same configuration as the acoustic wave device 21 of the second example embodiment except for the above point.

In the acoustic wave device 31, the plan-view shapes of a plurality of first electrode fingers 36 and a plurality of second electrode fingers 37 each include an inflection point. The inflection point in this specification refers to a point at which different curved lines are connected to each other, or a point at which a curved line is connected to a straight line. When different curved lines are connected to each other at an inflection point, the direction of the curved shape differs on either side of the inflection point, which defines and functions as a boundary. The phrase “the direction of the curved shape differs” means, for example, that the direction in which the curved shape is bent differs. More specifically, for example, the direction of the curved shape differs between when the curved shape is bent convex to the left in FIG. 23 and when the curved shape is bent convex to the right. In the third example embodiment, two curved shapes are symmetric about the inflection point as the boundary.

Specifically, the plan-view shapes of the plurality of first electrode fingers 36 and the plurality of second electrode fingers 37 each include two portions that can individually be approximated by circular arcs. The plan-view shape of each electrode finger includes a shape in which those two portions are connected. The center of the circle including one of those circular arcs and the center of the circle including the other circular arc face each other across the IDT electrode 38. In the plan-view shape of each electrode finger, the portion at which the above-described two portions are connected is the inflection point.

The overlap region of the acoustic wave device 31 includes a plurality of curved-line regions. Specifically, the plurality of curved-line regions include a first curved-line region W1 and a second curved-line region W2. One edge of the first curved-line region W1 corresponds to the first envelope E1. The other edge of the first curved-line region W1 corresponds to the boundary between the first curved-line region W1 and the second curved-line region W2. One edge of the second curved-line region W2 corresponds to the second envelope E2. The other edge of the second curved-line region W2 corresponds to the boundary between the first curved-line region W1 and the second curved-line region W2. In each curved-line region, each of the plurality of first electrode fingers 36 and the plurality of second electrode fingers 37 has a plan-view shape that can be approximated by a single circular arc. The boundary between the first curved-line region W1 and the second curved-line region W2 passes through the inflection point of each electrode finger. In the third example embodiment, the boundary is located in the area through which the dash double-dotted line N passes.

The shape of each electrode finger including an inflection point is not limited to that described above. For example, portions that can be approximated by elliptical arcs may be connected to each other at an inflection point. Alternatively, curved lines whose shapes cannot be approximated by a circular or elliptical arc may be connected to each other at the inflection point. That is, the portion of each electrode finger in each curved-line region may have a shape that can be approximated by a circular or elliptical arc or may be a shape that cannot be approximated by either.

In the third example embodiment, the boundary between the curved-line regions extends parallel or substantially parallel to the direction in which the propagation axis extends. However, the boundary between the curved-line regions may extend at an angle with respect to the propagation axis.

The plan-view shape of each electrode finger in the overlap region may include two or more inflection points. The overlap region may include, for example, three or more curved-line regions.

As illustrated in FIG. 23, the first envelope E21 in the IDT electrode 38 includes a plurality of bent portions V1 in the same or similar manner to the second example embodiment. The second envelope E22 includes a plurality of bent portions V2. In the third example embodiment, the first envelope excitation angle θ_{c_AP1_k} and the second envelope excitation angle θ_{c_AP2_k} are as follows. The following description illustrates examples for k=1 and k=2.

First envelope excitation angle: θ_{c_AP1_1}=about 11°, θ_{c_AP1_2}=about 100

Second envelope excitation angle: θ_{c_AP2_1}=about 10.3°, θ_{c_AP2_2}=about 11°

FIG. 23 schematically illustrates four segments. FIG. 24 illustrates five segments in an IDT electrode in a simplified manner. It is assumed for convenience that an IDT electrode 38A illustrated in FIG. 24 is an IDT electrode of a modification of the third example embodiment. However, the IDT electrode 38 of the third example embodiment may include, for example, five segments or six or more segments. The first envelope excitation angle θ_{c_AP1_k} and the second envelope excitation angle θ_{c_AP2_k} in the IDT electrode 38A are as follows.

First envelope excitation angle: θ_{c_AP1_1}=about 11°, θ_{c_AP1_2}=about 9.5°, θ_{c_AP1_3}=about 13°, θ_{c_AP1_4}=about 10°, θ_{c_AP1_5}=about 13°, θ_{c_AP1_6}=about 10°

Second envelope excitation angle: θ_{c_AP2_1}=about 10.3°, θ_{c_AP2_2}=about 13.2°, θ_{c_AP2_3}=about 10.2°, θ_{c_AP2_4}=about 13°, θ_{c_AP2_5}=about 9.5°, θ_{c_AP2_6}=about 11°

In the third example embodiment and the modification thereof, each electrode finger has a non-constant curvature in the curved-line regions, in the same or similar manner to the second example embodiment. Furthermore, on the first envelope E21 side in the plurality of electrode fingers, the distal end portions, the adjacent portions, or the distal end portions and the adjacent portions have different curvatures from each other. This enables effective reduction or prevention of spurious waves outside the pass band. In addition, the first envelope E21 and the second envelope E22 are inclined with respect to the propagation axis. This enables reduction or prevention of transverse modes. Furthermore, the first envelope E21 and the second envelope E22 each include a plurality of bent portions. This enables improvement of the Q factor.

In the third example embodiment, the plan-view shapes of the plurality of electrode fingers are point-symmetric or substantially point-symmetric. In this case, each electrode finger includes a portion bent to be convex on the reflector 39A side and a portion bent to be convex on the reflector 39B side. When the piezoelectric layer 6 is, for example, a single-crystal film having material anisotropy, the phases of spurious waves propagating to the reflector 39A side and spurious waves propagating to the reflector 39B side may have signs opposite to each other. In this case, spurious waves can be effectively reduced or prevented.

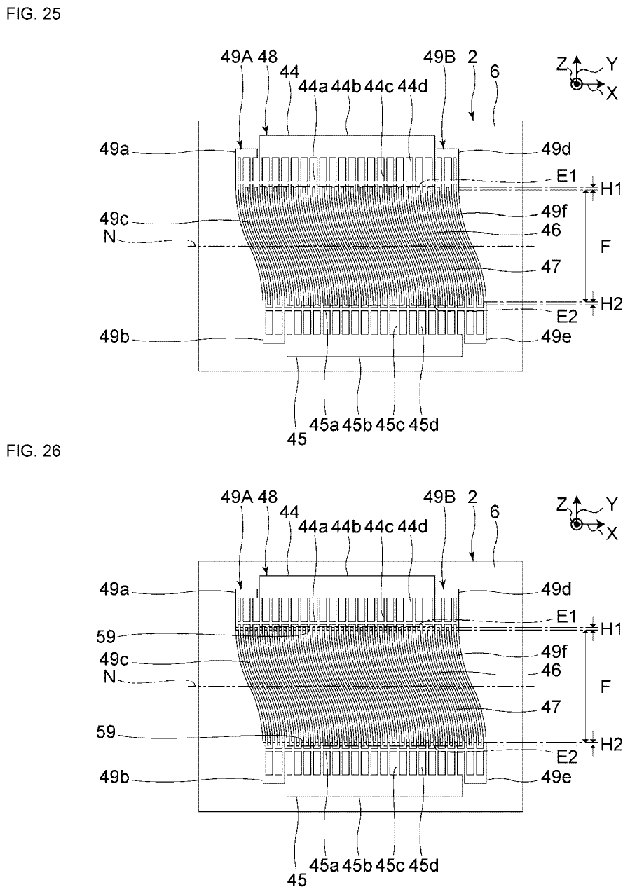

FIG. 25 is a schematic plan view of an acoustic wave device according to a fourth example embodiment of the present invention.

The fourth example embodiment differs from the first example embodiment in the configurations of an IDT electrode 48 and reflectors. Each reflector has a shape corresponding to the IDT electrode 48. The acoustic wave device of the fourth example embodiment has the same or substantially the same configuration as the acoustic wave device 1 of the first example embodiment except for the above point. The overlap region in the fourth example embodiment includes a first curved-line region and a second curved-line region in the same or similar manner to the third example embodiment. However, the first envelope E1 and the second envelope E2 extend parallel or substantially parallel to the direction in which the propagation axis extends.

A first busbar 44 is provided with a plurality of openings 44d. More specifically, the first busbar 44 includes a first inside busbar portion 44a, a first outside busbar portion 44b, and a plurality of first connecting portions 44c. The first inside busbar portion 44a and a first outside busbar portion 44b face each other. Of the first inside busbar portion 44a and the first outside busbar portion 44b, the first inside busbar portion 44a is located on the overlap region side. The plurality of first connecting portions 44c connect the first inside busbar portion 44a to the first outside busbar portion 44b. Each of the plurality of openings 44d is an opening bounded by the first inside busbar portion 44a, the first outside busbar portion 44b, and the plurality of first connecting portions 44c.

Similarly, a second busbar 45 includes a second inside busbar portion 45a, a second outside busbar portion 45b, and a plurality of second connecting portions 45c. The second busbar 45 is provided with a plurality of openings 45d.

The first inside busbar portion 44a extends parallel or substantially parallel to the first envelope E1. The first inside busbar portion 44a faces the plurality of second electrode fingers 47 across gaps. The second inside busbar portion 45a extends parallel or substantially parallel to the second envelope E2. The second inside busbar portion 45a faces the plurality of first electrode fingers 46 across gaps.

The overlap region of the IDT electrode 48 includes a central region F and a pair of edge regions. Specifically, the pair of edge regions include a first edge region H1 and a second edge region H2. The first edge region H1 includes the first envelope E1 as an edge. More specifically, the first edge region H1 is a region where the distal end portions of the plurality of second electrode fingers 47 and the adjacent portions of the plurality of first electrode fingers 46 are arranged.

The second edge region H2 includes the second envelope E2 as an edge. More specifically, the second edge region H2 is a region where the distal end portions of the plurality of first electrode fingers 46 and the adjacent portions of the plurality of second electrode fingers 47 are arranged. The first edge region H1 and the second edge region H2 face each other across the central region F. It is noted that each overlap region in the other example embodiments also includes a first edge region, a second edge region, and a central region.

The plurality of first connecting portions 44c of the first busbar 44 extend along the extensions of the respective first electrode fingers 46. The plurality of first connecting portions 44c are not provided on the extensions of the respective second electrode fingers 47. On the other hand, in the overlap region, the first electrode fingers 46 and the second electrode fingers 47 are alternately arranged. Therefore, the acoustic velocity in the region of the first busbar 44 where the plurality of openings 44d are provided is higher than that in the overlap region. The region of the first busbar 44 where the plurality of openings 44d are provided thus defines a high velocity region. The high velocity region refers to a region where the acoustic velocity is higher than that in the central region F. Similarly, the high-velocity region is also provided in the region of the second busbar 45 where the plurality of openings 45d are provided.

Herein, leakage of acoustic wave energy may occur because of mode conversion of the primary mode. For example, when SH waves are used as the primary mode of acoustic waves, conversion from SH waves to Rayleigh waves or from SH waves to bulk waves causes leakage of acoustic wave energy. Such leakage occurs from the overlap region side toward the busbar sides.

In the fourth example embodiment, the first inside busbar portion 44a faces the plurality of second electrode fingers 47 across gaps. This enables reduction or prevention of the leakage of acoustic wave energy due to the mode conversion. Furthermore, the second inside busbar portion 45a faces the plurality of first electrode fingers 46 across gaps. This enables reduction or prevention of the leakage of acoustic wave energy due to the mode conversion.

The distance between the first inside busbar portion 44a and the second electrode fingers 47 is, for example, preferably about 0.5λ or less. Similarly, the distance between the second inside busbar portion 45a and the first electrode fingers 46 is, for example, preferably about 0.5λ or less. This enables effective reduction or prevention of the leakage of acoustic wave energy due to mode conversion.

In addition, the high velocity region is provided between the first inside busbar portion 44a and the first outside busbar portion 44b. This enables effective confinement of acoustic wave energy to the overlap region side. Similarly, the high velocity region is provided between the second inside busbar portion 45a and the second outside busbar portion 45b. This enables effective confinement of acoustic wave energy to the overlap region side.

In the fourth example embodiment, each electrode finger has a non-constant curvature in the curved-line regions in the same or similar manner to the first example embodiment. Furthermore, on the first envelope E1 side in the plurality of electrode fingers, the distal end portions, the adjacent portions, or the distal end portions and the adjacent portions have different curvatures from each other. This enables effective reduction or prevention of spurious waves outside the pass band.

As illustrated in FIG. 25, each of the reflector electrode fingers 49c of the reflector 49A and the reflector electrode fingers 49f of the reflector 49B has a curved plan-view shape including an inflection point in the same or similar manner to the plan-view shape of each electrode finger of the IDT electrode 48. The reflector busbar 49a of the reflector 49A and the reflector busbar 49d of the reflector 49B are each provided with a plurality of openings in the same or similar manner to the first busbar 44. The reflector busbar 49b of the reflector 49A and the reflector busbar 49e of the reflector 49B are each provided with a plurality of openings in the same or similar manner to the second busbar 45. However, each reflector busbar of each reflector does not need to be provided with an opening.

In the fourth example embodiment, the first envelope E1 and the second envelope E2 extend parallel or substantially parallel to the direction in which the propagation axis extends. However, the first busbar may include a first inside busbar portion, a first outside busbar portion, and a plurality of first connecting portions when the first envelope E1 includes a plurality of bent portions V1 in the same or similar manner to the second example embodiment illustrated in FIG. 15. The same applies to the second busbar.

Acoustic wave devices according to example embodiments of the present invention may have a configuration that allows use of the piston mode. A configuration example that allows use of the piston mode is illustrated in a fifth example embodiment of the present invention.

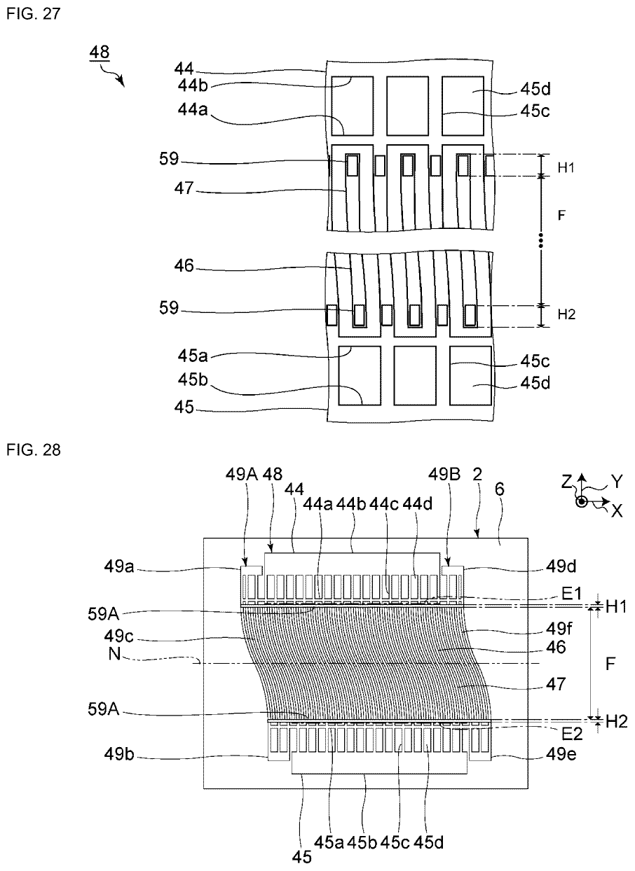

FIG. 26 is a schematic plan view of an acoustic wave device according to the fifth example embodiment. FIG. 27 is a schematic enlarged plan view of the vicinity of a first edge region and the vicinity of a second edge region in the fifth example embodiment.

The fifth example embodiment differs from the fourth example embodiment in that a mass-adding film 59 is provided on each of the electrode fingers and the reflector electrode fingers. The acoustic wave device of the fifth example embodiment has the same or substantially the same configuration as the acoustic wave device of the fourth example embodiment except for the above point.

In the first edge region H1, a plurality of mass-adding films 59 are provided. Specifically, mass-adding films 59 are individually provided on the first electrode fingers 46 and the second electrode fingers 47 in the first edge region H1. This defines a low-velocity region in the first edge region H1. The low-velocity region refers to a region where the acoustic velocity is lower than that in the central region F.

Similarly, a plurality of mass-adding films 59 are provided in the second edge region H2. This defines a low-velocity region in the second edge region H2. In the fifth example embodiment, each mass-adding film 59 is provided on only a single electrode finger. In this case, the mass-adding films 59 can be made of a proper metal or dielectric, for example.

In each region extended from each edge region in the direction in which the first busbar 44 extends, the mass-adding films 59 are provided on the reflector electrode fingers 49c of the reflector 49A and are similarly provided on the reflector electrode fingers 49f of the reflector 49B. However, the mass-adding films 59 do not need to be provided on the reflector electrode fingers.

In the fifth example embodiment, the central region F and the pair of low-velocity regions are arranged in this order from the inside toward the outside in the direction in which the first busbar 44 and the second busbar 45 face each other. This allows the piston mode to occur. The energy of the primary mode can thus be effectively confined to the center side of the overlap region. Therefore, the characteristics of the primary mode can be improved, and transverse modes can be reduced or prevented.

In addition, the IDT electrode 48 of the fifth example embodiment is configured in the same or substantially the same manner as the fourth example embodiment. Therefore, the leakage of acoustic wave energy due to mode conversion can be reduced or prevented. Furthermore, spurious waves outside the pass band can be effectively reduced or prevented.

It is sufficient that the low-velocity region is provided in at least one of the first edge region H1 and the second edge region H2. However, it is preferable that the low-velocity region provided in both of the first edge region H1 and the second edge region H2. This allows the piston mode to occur more reliably.

It is sufficient that the mass-adding films 59 are laminated on at least one of the plurality of electrode fingers in at least one of the first edge region H1 and the second edge region H2. However, it is preferable that the mass-adding films 59 is laminated on two or more of the plurality of electrode fingers in at least one of the first edge region H1 and the second edge region H2, and more preferably, the mass-adding films 59 are laminated on all of the electrode fingers. Still more preferably, the mass-adding films 59 are laminated on two or more electrode fingers in both of the first edge region H1 and the second edge region H2. This allows the piston mode to occur more reliably. Even still more preferably, the mass-adding films 59 are laminated on all of the electrode fingers in the both edge regions. In this case, the low-velocity region is provided throughout the entireties or substantially the entireties of both edge regions. This allows the piston mode to occur even more reliably.

In the fifth example embodiment, in the laminated structure of any electrode finger and the mass-adding film 59 thereon, these layers are stacked in the order of the piezoelectric substrate 2, the electrode finger, and the mass-adding film 59. However, in the laminated structure of any electrode finger and the mass-adding film 59 thereon, these layers are stacked in the order of the piezoelectric substrate 2, the mass-adding film 59, and the electrode finger. That is, the mass-adding film 59 may be provided between the piezoelectric substrate 2 and the electrode finger.

In the fifth example embodiment, the first envelope E1 and the second envelope E2 extend parallel or substantially parallel to the direction in which the propagation axis extends. However, the low-velocity region may be provided in the first edge region even when the first envelope E21 includes a plurality of the bent portions V1 in the same or similar manner to the second example embodiment illustrated in FIG. 15. Even when a portion of the first busbar 24 on the first envelope E21 side has a wavy plan-view shape, the first edge region is a region where the distal end portions of the plurality of second electrode fingers 27 and the adjacent portions of the plurality of first electrode fingers 26 are arranged. In this case, it is sufficient that, for example, the mass-adding films 59 are individually provided on the distal end portions of the plurality of second electrode fingers 27 and the adjacent portions of the plurality of first electrode fingers 26.

The same applies to the relationship between the second envelope E22, the second busbar 25, and the second edge region. A low-velocity region may be defined by providing a plurality of the mass-adding films 59 in the second edge region.

One mass-adding film 59 may be provided over two or more electrode fingers. In a modification of the fifth example embodiment illustrated in FIG. 28, for example, each of the first edge region H1 and the second edge region H2 is provided with one mass-adding film 59A. A low-velocity region is thus provided in each of the first edge region H1 and the second edge region H2.

More specifically, each mass-adding film 59A has a belt shape. One of the pair of mass-adding films 59A is provided over the plurality of electrode fingers in the first edge region H1. Similarly, the other mass-adding film 59A is provided over the plurality of electrode fingers in the second edge region H2. Each mass-adding film 59A is also provided between electrode fingers on the piezoelectric layer 6. The mass-adding films 59A can be made of a proper dielectric.

It is sufficient that any mass-adding film 59A is laminated on at least one of the plurality of electrode fingers in at least one of the first edge region H1 and the second edge region H2. In this case, the mass-adding film 59A may be provided on the electrode fingers and between the electrode fingers. However, it is preferable that the mass-adding film 59A is laminated on two or more of the plurality of electrode fingers in at least one of the first edge region H1 and the second edge region H2, and more preferably, the mass-adding film 59A is laminated on all of the plurality of electrode fingers. Still more preferably, the mass-adding film 59A is laminated on two or more electrode fingers in both of the first edge region H1 and the second edge region H2, and even still more preferably, the mass-adding film 59A is laminated on all of the electrode fingers. This allows the piston mode to occur more reliably.

In this modification, the IDT electrode 48 is configured in the same manner as that of the fourth and fifth example embodiments. Therefore, the leakage of acoustic wave energy due to mode conversion can be reduced or prevented, and spurious waves outside the pass band can be effectively reduced or prevented.

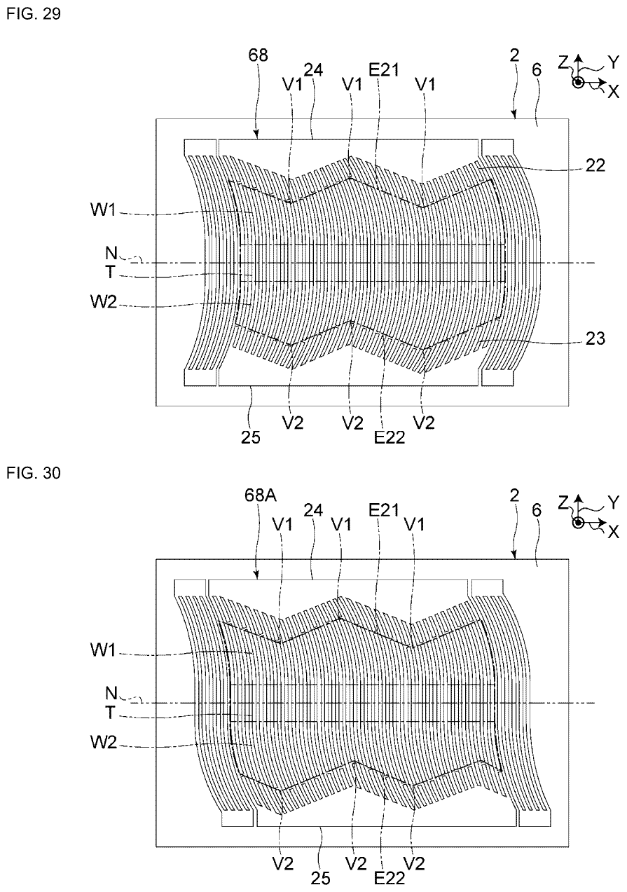

FIG. 29 is a schematic plan view of an acoustic wave device according to a sixth example embodiment of the present invention.

The sixth example embodiment differs from the second example embodiment in that the plurality of electrode fingers of an IDT electrode 68 include a linear portion. The sixth example embodiment also differs from the second example embodiment in that the plurality of reflector electrode fingers of each reflector include a linear portion. The acoustic wave device of the sixth example embodiment has the same or substantially the same configuration as the acoustic wave device 21 of the second example embodiment except for the above points.

The overlap region of the IDT electrode 68 includes a first curved-line region W1, a second curved-line region W2, and a straight-line region T. The first curved-line region W1, the second curved-line region W2, and the straight-line region T are arranged in the direction in which the first busbar 24 and the second busbar 25 face each other. More specifically, the first curved-line region W1 and the second curved-line region W2 face each other across the straight-line region T.

In the IDT electrode 68, the plan-view shape of each electrode finger includes two inflection points. Each inflection point refers to a point at which a curved-line that can be approximated by a circular arc and a straight line are connected to each other.

In the straight-line region T, the excitation direction of acoustic waves is also any one of the above-described first to third directions in the same or similar manner to each curved-line region. The first to third directions are the same in the straight-line region T. The excitation angle θ_{c_prop} is uniform in the straight-line region T. More specifically, the excitation angle θ_{c_prop} is about 0° at the boundary between the straight-line region T and the first curved-line region W1. Similarly, the excitation angle θ_{c_prop} is about 0° at the boundary between the straight-line region T and the second curved-line region W2. Therefore, the excitation angle θ_{c_prop} is about 0° in the straight-line region T. The excitation angle θ_{c_prop} does not need to be about 0° in the straight-line region T.

In the sixth example embodiment, the X propagation direction, which is the direction in which the propagation axis of the piezoelectric layer 6 extends, is perpendicular or substantially perpendicular to the direction in which the plurality of electrode fingers extend, in the entirety or substantially the entirety of the straight-line region T. Therefore, the straight-line region T is a stable region with respect to the propagation axis. The straight-line region T being included in the overlap region can minimize the change in propagation direction in the IDT electrode 68 as a whole, enabling stable propagation of acoustic waves.

In addition, the first curved-line region W1 and the second curved-line region W2 are configured in the same or substantially the same manner as those of the second example embodiment. Therefore, transverse modes can be reduced or prevented, and spurious waves outside the pass band can be reduced or prevented. Furthermore, the Q factor can be improved.

The duty ratio, the electrode finger pitch, the thickness of the plurality of electrode fingers, or any other relevant parameter may be varied according to the excitation angle θ_{c_prop} such that resonant frequencies or anti-resonant frequencies are the same across the entirety or substantially the entirety of the first curved-line region W1 and the entirety or substantially the entirety of the second curved-line region W2. In this case, resonant frequencies or anti-resonant frequencies in the straight-line region T may be the same or substantially the same as those in the first and second curved-line regions W1 and W2. Resonant frequencies or anti-resonant frequencies can thus be the same or substantially the same throughout the entirety or substantially the entirety of the overlap region including the straight-line region T. This enables a more reliable improvement in the resonance characteristics.

Preferably, the curved-line regions define at least about 50% of the overlap region. This enables more reliable and effective reduction or prevention of spurious waves.

The configuration of the IDT electrode 68, which includes the straight-line region T, is not limited to that described above. In a modification of the sixth example embodiment, which is illustrated in FIG. 30, for example, first and second curved-line regions W1 and W2 of an IDT electrode 68A are configured in the same or substantially the same manner as those in the third example embodiment. The first curved-line region W1 and the second curved-line region W2 face each other across the straight-line region T. In this case as well, the change in propagation direction can be minimized in the IDT electrode 68A as a whole, in the same or similar manner to the sixth example embodiment. This enables stable propagation of acoustic waves and reduction or prevention of spurious waves outside the pass band.

The first and second curved-line regions W1 and W2 of this modification are configured in the same or substantially the same manner as those in the third example embodiment. Therefore, transverse modes can be reduced or prevented. In addition, the Q factor can be improved.

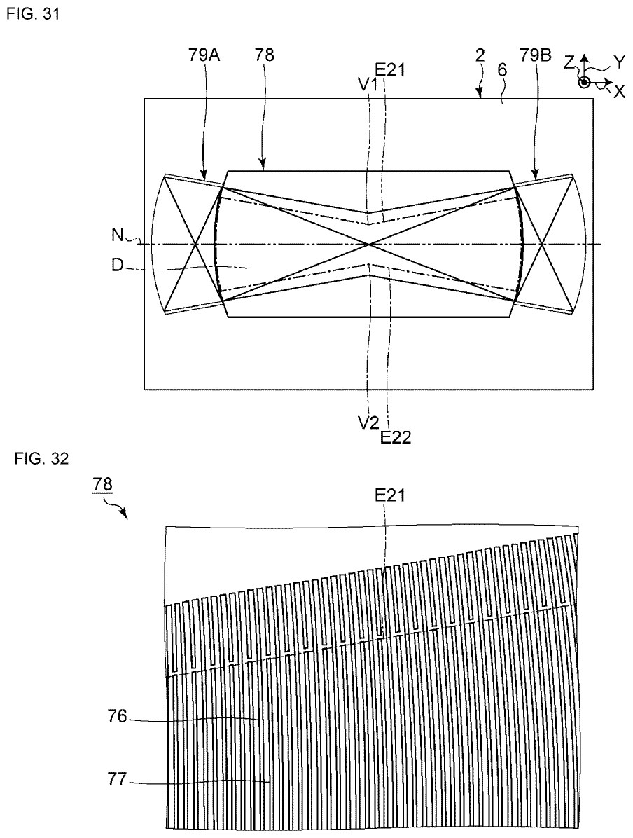

FIG. 31 is a simplified plan view of an acoustic wave device according to a seventh example embodiment of the present invention. FIG. 32 is a schematic enlarged plan view of a part of the IDT electrode in the seventh example embodiment.

As illustrated in FIG. 31, the seventh example embodiment differs from the first example embodiment in the configurations of an IDT electrode 78 and reflectors. The acoustic wave device of the seventh example embodiment has the same or substantially the same configuration as the acoustic wave device 1 of the first example embodiment except for the above point.

The IDT electrode 78 has a symmetric plan-view shape about its center, defining and functioning as the boundary, in the direction in which the propagation axis extends. More specifically, a plurality of electrode fingers of the IDT electrode 78 and a plurality of reflector electrode fingers each have a shape that can be approximated by a circular arc. The electrode fingers located on the reflector 79A side of the above-described boundary are bent to be convex in the direction of the reflector 79A in plan view. The reflector electrode fingers of the reflector 79A are bent to be convex in the same direction as the electrode fingers located on the reflector 79A side.

The electrode fingers located on the other reflector 79B side of the above-described boundary are bent to be convex in the direction of the reflector 79B in plan view. The reflector electrode fingers of the reflector 79B are bent to be convex in the same direction as the electrode fingers located on the reflector 79B side.

In the IDT electrode 78, the curvature of the plurality of electrode fingers increases with increasing distance from its center in the direction in which the propagation axis extends. Specifically, the curvature in the above-described three examples increases.

As illustrated in FIG. 32, as the first and second examples, the curvature of the distal end portion or the adjacent portion of any first electrode finger 76 or any second electrode finger 77 that is located on the outer side is greater than that of the distal end portion or the adjacent portion of any first electrode finger 76 or any second electrode finger 77 that is located on the center side. More specifically, as the first example, the curvature of the distal end portion of any second electrode finger 77 located on the outer side or the adjacent portion of any first electrode finger 76 located on the outer side is greater than that of the distal end portion of any second electrode finger 77 located on the center side or the adjacent portion of any electrode finger 76 located on the center side. As the second example, the curvature of the distal end portion of any first electrode finger 76 located on the outer side or the adjacent portion of any second electrode finger 77 located on the outer side is greater than that of the distal end portion of any first electrode finger 76 located on the center side or the adjacent portion of any second electrode finger 77 located on the center side.

As the third example, among the portions of all of the first electrode fingers 76 and all of the second electrode fingers 77 that are located in the area where the excitation angle θ_{c_prop} is about 0°, the curvature of the portion of any electrode finger located on the outer side is greater than that of the portion of any electrode finger located on the center side. The seventh example embodiment satisfies all of the magnitude relationships in curvature in the above-described three type examples. However, it is sufficient that the present example embodiment satisfies at least one of the magnitude relationships in curvature of the three examples.

In the IDT electrode 78, the electrode finger pitch varies among the portions where the excitation angle θ_{c_prop} is uniform. More specifically, among the portions where the excitation angle θ_{c_prop} is constant, the electrode finger pitch increases with increasing distance from the center of the IDT electrode 78 in the direction in which the propagation axis extends. This allows the curvature of electrode fingers to further increase with increasing distance from the center. In the seventh example embodiment, resonant frequencies or anti-resonant frequencies slightly decrease with increasing distance from the center. On the other hand, the change in curvature between the electrode fingers can be increased as described above. This can further increase the frequency variation of spurious waves outside the pass band and further reduce or prevent spurious waves outside the pass band.

Among the portions where the excitation angle θ_{c_prop} is uniform, the electrode finger pitch may decrease with increasing distance from the center of the IDT electrode 78 in the direction in which the propagation axis extends. Spurious waves outside the pass band can be effectively reduced or prevented in this case as well.

As illustrated in FIG. 31, the first envelope E21 in the IDT electrode 78 includes one bent portion V1. The bent portion V1 is located at the center of the first envelope E21 in the direction in which the propagation axis extends. Similarly, the second envelope E22 includes one bent portion V2. The bent portion V2 is located at the center of the second envelope E22 in the direction in which the propagation axis extends. However, each of the first envelope E21 and the second envelope E22 may include a plurality of bent portions in the same or similar manner to the second example embodiment and the like.

In the seventh example embodiment, the entirety or substantially the entirety of the overlap region D of the IDT electrode 78 includes a curved-line region. However, the overlap region D of the IDT electrode 78 may include a straight-line region in the same or similar manner to the sixth example embodiment.

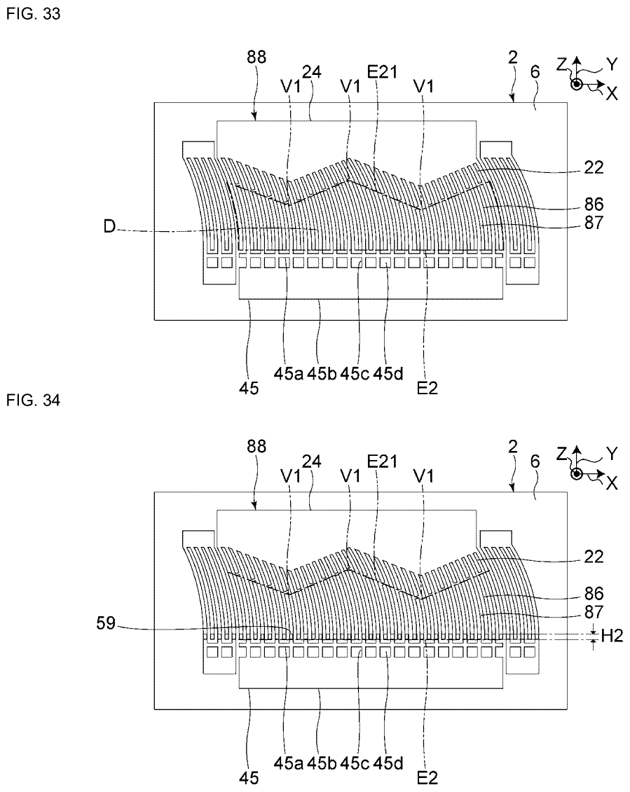

FIG. 33 is a schematic plan view of an acoustic wave device according to an eighth example embodiment of the present invention.

The eighth example embodiment differs from the second example embodiment in that an IDT electrode 88 includes the second busbar 45, which is configured in the same or substantially the same manner as that of the fourth example embodiment, and in the shape of each electrode finger. The IDT electrode 88 includes the plurality of first offset electrodes 22 and does not include the plurality of second offset electrodes. The eighth example embodiment also differs from the second example embodiment in the configuration of each reflector accordingly. The acoustic wave device of the eighth example embodiment has the same or substantially the same configuration as the acoustic wave device 21 of the second example embodiment except for the above points.

The distal end portions of a plurality of second electrode fingers 87 face the distal end portions of the plurality of first offset electrodes 22 across gaps in the same or similar manner to the second example embodiment. On the other hand, the distal end portions of a plurality of first electrode fingers 86 face the second inside busbar portion 45a of the second busbar 45 across gaps in the same or similar manner to the fourth example embodiment.

In the eighth example embodiment, each electrode finger has a non-constant curvature in the curved-line region in the same or similar manner to the second example embodiment. Furthermore, on the first envelope E21 side in the plurality of electrode fingers, the distal end portions, the adjacent portions, or the distal end portions and the adjacent portions have different curvatures from each other. This enables effective reduction or prevention of spurious waves outside the pass band.

An acoustic wave device including the IDT electrode 88 may have a configuration that allows use of the piston mode in the same or similar manner to the fifth example embodiment described above. In a modification of the eighth example embodiment illustrated in FIG. 34, the distal end portions of the plurality of first electrode fingers 86 and the adjacent portions of the plurality of second electrode fingers 87 are arranged in the second edge region H2. On the other hand, in the first edge region, the distal end portions of the plurality of second electrode fingers 87 and the adjacent portions of the plurality of first electrode fingers 86 are arranged. As illustrated in FIG. 34, the mass-adding films 59 are individually provided on the distal end portions of the plurality of first electrode fingers 86 and the adjacent portions of the plurality of second electrode fingers 87. This defines a low-velocity region in the second edge region H2. Therefore, the piston mode can occur, and transverse modes can be reduced or prevented. In addition, spurious waves outside the pass band can be effectively reduced or prevented in the same or similar manner to the eighth example embodiment.

As illustrated in FIG. 34, the mass-adding films 59 are also individually provided on the reflector electrode fingers in each region extended from the second edge region H2 in the direction in which the second busbar 45 extends. In this modification, the mass-adding films 59 are provided only in the second edge region H2, of the first edge region and the second edge region H2. However, the mass-adding films 59 may be individually provided on the distal end portions of the plurality of second electrode fingers 87 and the adjacent portions of the plurality of first electrode fingers 86 in the first edge region. A low-velocity region may thus be provided in the first edge region.

In acoustic wave devices according to example embodiments of the present invention, the laminate structure of the piezoelectric substrate is not limited to that illustrated in FIG. 2. An example in which the acoustic wave device includes a different piezoelectric substrate from that of the first example embodiment will be illustrated using a ninth example embodiment of the present invention.

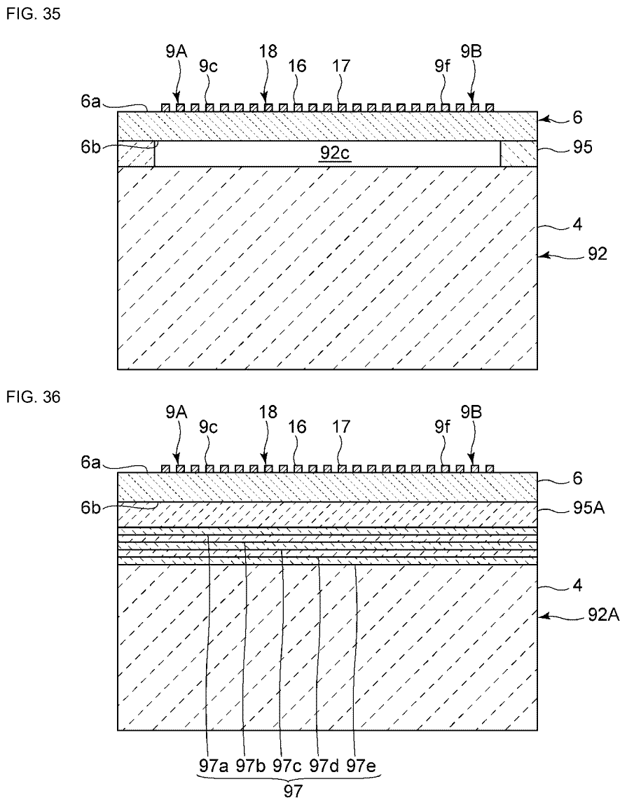

FIG. 35 is a schematic front sectional view of an acoustic wave device according to the ninth example embodiment.

The ninth example embodiment differs from the first example embodiment in the laminate structure of a piezoelectric substrate 92. The acoustic wave device of the ninth example embodiment has the same or substantially the same configuration as the acoustic wave device of the first example embodiment except for the above point.

The piezoelectric substrate 92 includes the support substrate 4, an intermediate layer 95, and the piezoelectric layer 6. The intermediate layer 95 is provided on the support substrate 4. The piezoelectric layer 6 is provided on the intermediate layer 95. The intermediate layer 95 has a frame shape in the ninth example embodiment. That is, the intermediate layer 95 includes a through-hole. The support substrate 4 closes one end of the through-hole of the intermediate layer 95. The piezoelectric layer 6 closes the other end of the through-hole of the intermediate layer 95. A hollow portion 92c is thus provided in the piezoelectric substrate 92. A portion of the piezoelectric layer 6 and a portion of the support substrate 4 face each other across the hollow portion 92c.

In the ninth example embodiment, the primary mode can be reflected to the piezoelectric layer 6 side. Therefore, acoustic wave energy can be effectively confined to the piezoelectric layer 6 side. In addition, spurious waves can be effectively reduced or prevented in the same or similar manner to the first example embodiment.

The following description illustrates first and second modifications of the ninth example embodiment, which are different from the ninth example embodiment only in the laminate structure of the piezoelectric substrate. In the same or similar manner to the ninth example embodiment, spurious waves can be effectively reduced or prevented in the first and second modifications as well. Furthermore, acoustic wave energy can be effectively confined to the piezoelectric layer 6 side.

In the first modification, which is illustrated in FIG. 36, a piezoelectric substrate 92A includes the support substrate 4, an acoustic reflective film 97, an intermediate layer 95A, and the piezoelectric layer 6. The acoustic reflective film 97 is provided on the support substrate 4. The intermediate layer 95A is provided on the acoustic reflective film 97. The piezoelectric layer 6 is provided on the intermediate layer 95A. The intermediate layer 95A is a low-velocity film.

The acoustic reflective film 97 is a laminate of plural acoustic impedance layers. Specifically, the acoustic reflective film 97 includes a plurality of low acoustic impedance layers and a plurality of high acoustic impedance layers. The high acoustic impedance layers are layers with relatively high acoustic impedance. The plurality of high acoustic impedance layers of the acoustic reflective film 97 are, more specifically, a high acoustic impedance layer 97a, a high acoustic impedance layer 97c, and a high acoustic impedance layer 97e. The low acoustic impedance layers are layers with relatively low acoustic impedance. The plurality of low acoustic impedance layers of the acoustic reflective film 97 are, more specifically, a low acoustic impedance layer 97b and a low acoustic impedance layer 97d. The low acoustic impedance layers and the high acoustic impedance layers are alternately laminated on top of each other. The high acoustic impedance layer 97a is the closest layer to the piezoelectric layer 6 in the acoustic reflective film 97.

The acoustic reflective film 97 includes, for example, two low acoustic impedance layers and three high acoustic impedance layers. However, it is sufficient that the acoustic reflective film 97 includes at least one low acoustic impedance layer and at least one high acoustic impedance layer.

Examples of the material of the low acoustic impedance layers include silicon oxide and aluminum. Examples of the material of the high acoustic impedance layers include metal such as platinum or tungsten and dielectrics such as aluminum nitride or silicon nitride. The material of the intermediate layer 95A may be the same as that of the low acoustic impedance layers.

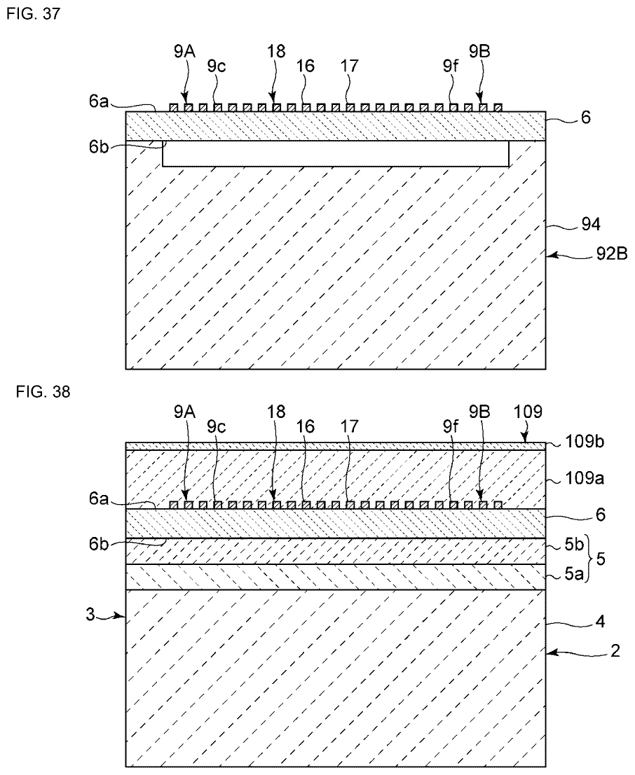

In the second modification, which is illustrated in FIG. 37, a piezoelectric substrate 92B includes a support substrate 94 and the piezoelectric layer 6. The piezoelectric layer 6 is provided directly on the support substrate 94. More specifically, the support substrate 94 includes a recess portion. The piezoelectric layer 6 is provided on the support substrate 94 to close the recess portion. The piezoelectric substrate 92B thus includes a hollow portion. The hollow portion overlaps at least a portion of the IDT electrode 18 in plan view.

FIG. 38 is a schematic front sectional view of an acoustic wave device according to a tenth example embodiment of the present invention.

The tenth example embodiment is different from the first example embodiment in that the IDT electrode 18 is embedded in a protection film 109. The acoustic wave device of the tenth example embodiment has the same or substantially the same configuration as the acoustic wave device 1 of the first example embodiment except for the above point.

Specifically, the protection film 109 is provided on the piezoelectric layer 6 so as to cover the IDT electrode 18. The protection film 109 is thicker than the IDT electrode 18. The IDT electrode 18 is embedded in the protection film 109. The IDT electrode 18 is therefore less likely to be damaged.

The protection film 109 includes a first protection layer 109a and a second protection layer 109b. The IDT electrode 18 is embedded in the first protection layer 109a. The second protection layer 109b is provided on the first protection layer 109a. The protection film 109 therefore provides multiple advantageous effects. Specifically, the first protection layer 109a is made of, for example, silicon oxide in the tenth example embodiment. This enables a reduction in the absolute value of the temperature coefficient of frequency (TCF) of the acoustic wave device, so as to improve the temperature characteristics of the acoustic wave device. The second protection layer 109b is made of silicon nitride, for example. This can improve the resistance to humidity.

In addition, in the same or similar manner to the first example embodiment, spurious waves can be effectively reduced or prevented in the tenth example embodiment as well.

The materials of the first and second protection layers 109a and 109b are not limited to those described above. The protection film 109 may include a single layer or a laminate including three layers or more.

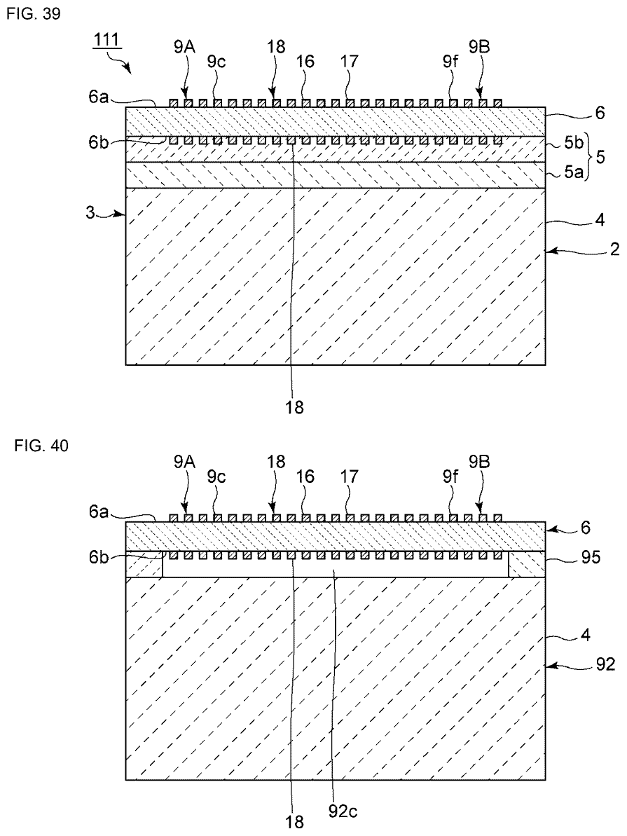

FIG. 39 is a schematic front sectional view of an acoustic wave device according to an eleventh example embodiment of the present invention.

The eleventh example embodiment differs from the first example embodiment in that the IDT electrode 18 is provided on both of a first major surface 6a and a second major surface 6b of the piezoelectric layer 6. The IDT electrode 18 provided on the second major surface 6b is embedded in the second layer 5b of the intermediate layer 5. The acoustic wave device of the eleventh example embodiment has the same or substantially the same configuration as the acoustic wave device 111 of the first example embodiment except for the above point.

The IDT electrode 18 provided on the first major surface 6a of the piezoelectric layer 6 and the IDT electrode 18 provided on the second major surface 6b face each other across the piezoelectric layer 6. In the same or similar manner to the first example embodiment, spurious waves can be effectively reduced or prevented in the eleventh example embodiment as well.

The IDT electrode 18 provided on the first major surface 6a of the piezoelectric layer 6 may have different design parameters from those of the IDT electrode 18 provided on the second major surface 6b, for example.

The following description will illustrate first to third modifications of the eleventh example embodiment, which differ from the eleventh example embodiment in at least one of the following: the configuration of the electrode provided on the second major surface of the piezoelectric layer or the laminate structure of the piezoelectric substrate. In the same or similar manner to the eleventh example embodiment, spurious waves can be effectively reduced or prevented in the first to third modifications as well.

In the first modification, which is illustrated in FIG. 40, the piezoelectric substrate 92 is configured in the same or similar manner as that of the ninth example embodiment. Specifically, the piezoelectric substrate 92 includes the support substrate 4, the intermediate layer 95, and the piezoelectric layer 6. The IDT electrode 18 provided on the second major surface 6b of the piezoelectric layer 6 is located within the hollow portion 92c.

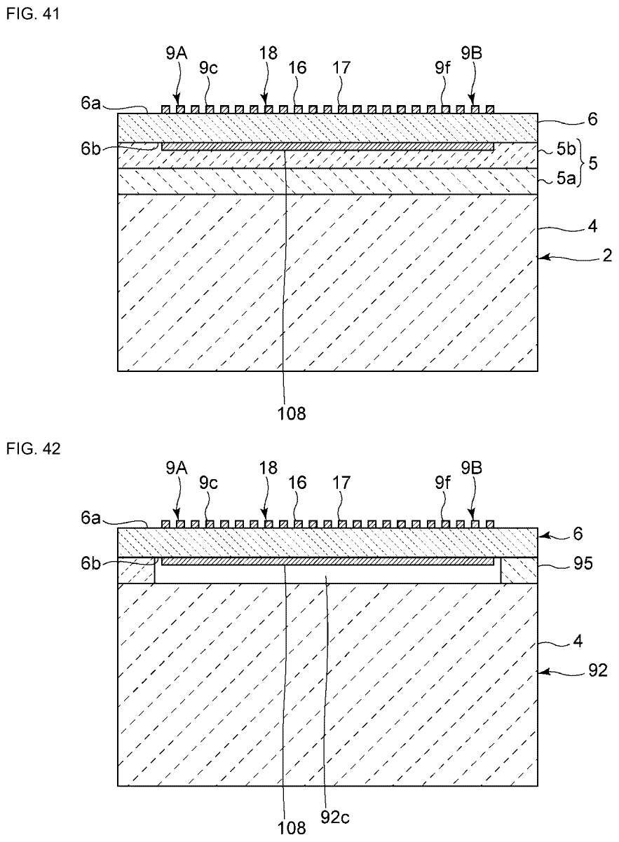

In the second modification, which is illustrated in FIG. 41, a plate-shaped electrode 108 is provided on the second major surface 6b of the piezoelectric layer 6. The electrode 108 is embedded within the second layer 5b of the intermediate layer 5. The IDT electrode 18 and the electrode 108 face each other across the piezoelectric layer 6.

In the third modification, which is illustrated in FIG. 42, the piezoelectric substrate 92 is configured in the same or similar manner as that in the first modification, and the same electrode 108 as that of the second modification is provided on the second major surface 6b of the piezoelectric layer 6. The electrode 108 is located within the hollow portion 92c. The IDT electrode 18 and the electrode 108 face each other across the piezoelectric layer 6.

Acoustic wave devices according to example embodiments of the present invention can be applied to, for example, a filter device. An example thereof will be described below.

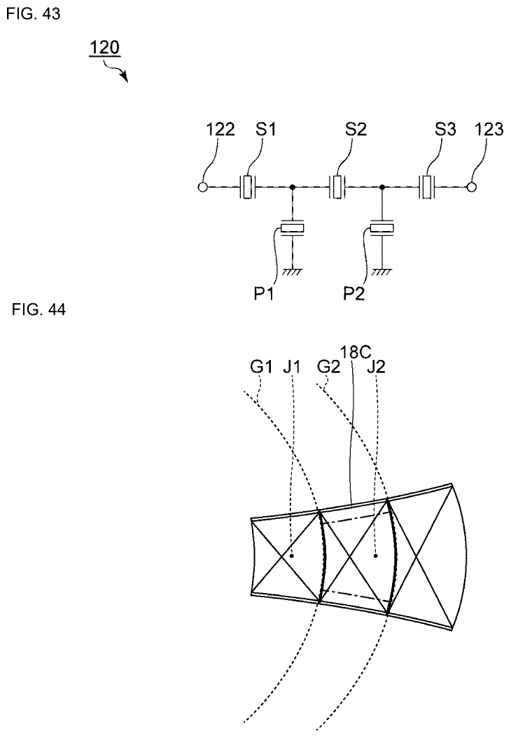

FIG. 43 is a circuit diagram of a filter device according to a twelfth example embodiment.

A filter device 120 of the twelfth example embodiment is a ladder filter. The filter device 120 includes a first signal terminal 122, a second signal terminal 123, a plurality of series arm resonators, and a plurality of parallel arm resonators. In the filter device 120, all of the series arm resonators and all of the parallel arm resonators are acoustic wave resonators. Furthermore, all of the series arm resonators and all of the parallel arm resonators are acoustic wave devices according to example embodiments the present invention. However, it is sufficient that at least one of the plurality of acoustic wave resonators of the filter device 120 is an acoustic wave device according to one of example embodiments of the present invention.

The first signal terminal 122 is an antenna terminal. The antenna terminal is coupled to an antenna. However, the first signal terminal 122 does not need to be an antenna terminal. The first signal terminal 122 and the second signal terminal 123 may be configured as electrode pads or wiring, for example.

Specifically, the plurality of series arm resonators of the twelfth example embodiment include a series arm resonator S1, a series arm resonator S2, and a series arm resonator S3. The plurality of series arm resonators are coupled to each other in series between the first signal terminal 122 and the second signal terminal 123. The plurality of parallel arm resonators specifically include a parallel arm resonator P1 and a parallel arm resonator P2. The parallel arm resonator P1 is coupled between the ground potential and the connecting point of the series arm resonators S1 and S2. The parallel arm resonator P2 is coupled between the ground potential and the connecting point of the series arm resonators S2 and S3. The circuit configuration of the filter device 120 is not limited to that described above. The filter device 120 may include a longitudinally-coupled resonator acoustic wave filter, for example.

Each acoustic wave resonator of the filter device 120 is an acoustic wave device according to one of example embodiments of the present invention. Therefore, spurious waves can be effectively reduced or prevented in the acoustic wave resonators of the filter device 120. This enables an improvement in filter characteristics of the filter device 120.

The above description illustrates the shapes that can be approximated by circular or elliptical arcs as the plan-view shape examples of each electrode finger in one curved-line region. The plan-view shape of each electrode finger may be a shape that can be approximated by a parabola or may be a shape that can be approximated by one branch of a hyperbola, for example. These examples are illustrated using seventh and eighth modifications of the first example embodiment below. In the same or similar manner to the first example embodiment, spurious waves can be reduced or prevented in the seventh and eighth modifications as well.

In the seventh modification of the first example embodiment, which is illustrated in FIG. 44, the plan-view shape of each electrode finger is a shape that can be approximated by a parabola. In FIG. 44, dashed lines indicate two parabolas G1 and G2. The parabola G1 has a focus J1. The parabola G2 has a focus J2. When the plan-view shape of each electrode finger is approximated by a parabola, the side closer to the focus of the parabola is referred to as the inner side while the farther side is referred to as the outer side. The parabola G1 is a parabola that approximates the plan-view shape of the electrode finger located closest to the inner side in an IDT electrode 18C. The parabola G2 is a parabola that approximates the plan-view shape of the electrode finger located closest to the outer side in the IDT electrode 18C.

In the seventh modification, the distance between the vertex and the focus J2 of the parabola G2 is shorter than the distance between the vertex and the focus J1 of the parabola G1. Therefore, the curvature of the electrode finger approximated by the parabola G1 is smaller than the curvature of the electrode finger approximated by the parabola G2.

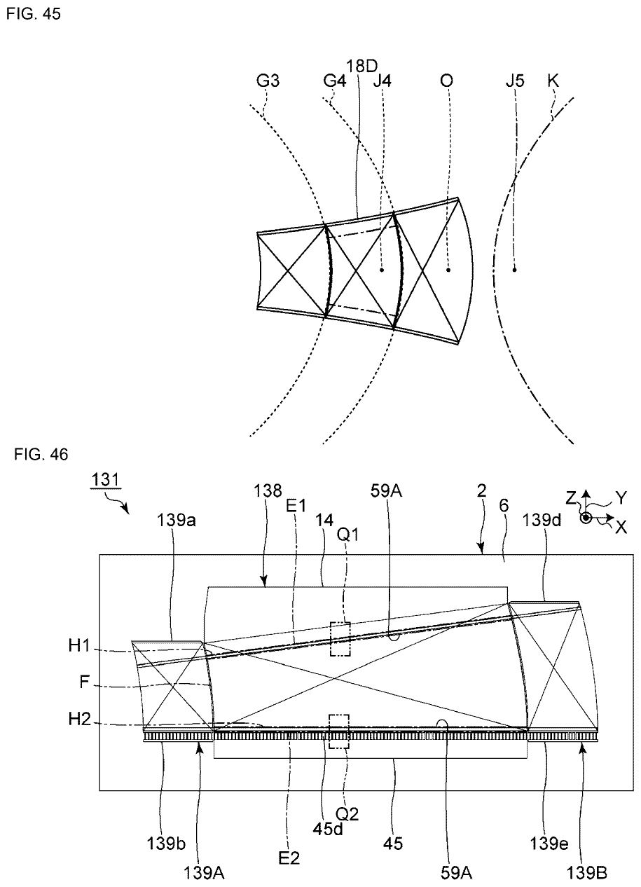

In the eighth modification of the first example embodiment, which is illustrated in FIG. 45, the plan-view shape of each electrode finger is a shape that can be approximated by one branch of a hyperbola. A curved line G3, which is indicated by a dashed line in FIG. 45, is one branch of a hyperbola. Similarly, a curved line G4, which is indicated by another dashed line in FIG. 45, is one branch of another hyperbola. A curved line K, which is indicated by a dash dotted line, is the other branch of the hyperbola corresponding to the curved line G4. The hyperbola including the curved lines G4 and K and includes foci J4 and J5. The hyperbola includes a centroid 0 of the foci J4 and J5. The hyperbola including the curved line G3 also includes the centroid of the foci, not illustrated.

When the plan-view shape of each electrode finger is approximated by one branch of a hyperbola, the side closer to the centroid of the foci of the parabola is referred to as the inner side while the farther side is referred to as the outer side. The curved line G3 is one branch of a hyperbola that approximates the plan-view shape of the electrode finger located closest to the inner side in an IDT electrode 18D. The curved line G4 is one branch of a hyperbola that approximates the plan-view shape of the electrode finger located closest to the outer side in the IDT electrode 18D. In the eighth modification, the curvature of the electrode finger approximated by the curved line G4 is smaller than the curvature of the electrode finger approximated by the curved line G3.

It is preferable that the seventh and eighth modifications satisfy at least one of the magnitude relationships in curvature in the following three examples. Specifically, as the first and second examples, the curvature of the distal end portion or the adjacent portion of any first electrode finger 16 or any second electrode finger 17 located on the outer side is smaller than that of the distal end portion or the adjacent portion of any first electrode finger 16 or any second electrode finger 17 located on the inner side.

More specifically, as the first example, the curvature of the distal end portion of any second electrode finger 17 located on the outer side or the adjacent portion of any first electrode finger 16 located on the outer side is smaller than that of the distal end portion of any second electrode finger 17 located on the inner side or the adjacent portion of any first electrode finger 16 located on the inner side. As the second example, the curvature of the distal end portion of any first electrode finger 16 located on the outer side or the adjacent portion of any second electrode finger 17 located on the outer side is smaller than that of the distal end portion of any first electrode finger 16 located on the inner side or the adjacent portion of any second electrode finger 17 located on the inner side.

As the third example, among the portions of all of the first electrode fingers 16 and all of the second electrode fingers 17 that are located in the area where the excitation angle θ_{c_prop} is about 0°, the curvature of the portion of any electrode finger located on the outer side is smaller than that of the portion of any electrode finger on the inner side. Satisfying at least one of the magnitude relationships in curvature in the above-described three examples enables reduction or prevention of deterioration in the major electric characteristics, such as the fractional bandwidth, the fractional stopband width, and the Q factor. In addition, spurious waves can be effectively reduced or prevented.

When each electrode finger has a plan-view shape that can be approximated by a parabola or when each electrode finger has a plan-view shape that can be approximated by one branch of a hyperbola, it is preferable that at least one of the magnitude relationships in curvature in the following three examples be satisfied. Specifically, as the first and second examples, the curvature of the distal end portion or the adjacent portion of any first electrode finger or any second electrode finger located on the outer side is greater than that of the distal end portion or the adjacent portion of any first electrode finger or any second electrode finger located on the inner side.

More specifically, as the first example, the curvature of the distal end portion of any second electrode finger located on the outer side or the adjacent portion of any first electrode finger located on the inner side is greater than that of the distal end portion of any second electrode finger located on the inner side or the adjacent portion of each first electrode finger located on the inner side. As the second example, the curvature of the distal end portion of any first electrode finger located on the outer side or the adjacent portion of any second electrode finger located on the outer side is greater than that of the distal end portion of any first electrode finger located on the inner side or the adjacent portion of any second electrode finger located on the inner side.

As the third example, among the portions of all of the first electrode fingers and all of the second electrode fingers that are located in the area where the excitation angle θ_{c_prop} is about 0°, the curvature of the portion of any electrode finger located on the outer side is greater than that of the portion of any electrode finger located on the inner side. Satisfying at least one of the magnitude relationships in curvature in the above-described three examples enables effective reduction or prevention of spurious waves.

In the first example embodiment, which is illustrated in FIG. 3 and other drawings, in the curved-line region, the plan-view shape of each of the plurality of first electrode fingers 16 and the plurality of second electrode fingers 17 appears to be approximated by a circular arc in plan view. However, it is not required that the entirety or substantially the entirety of one electrode finger appears to be roughly approximated by a circular arc in plan view. In this case, one electrode finger may partially appear to be roughly approximated by a circular arc in plan view. Alternatively, one electrode finger may partially appear to be roughly approximated by an elliptical arc, a parabola, or one branch of a hyperbola.

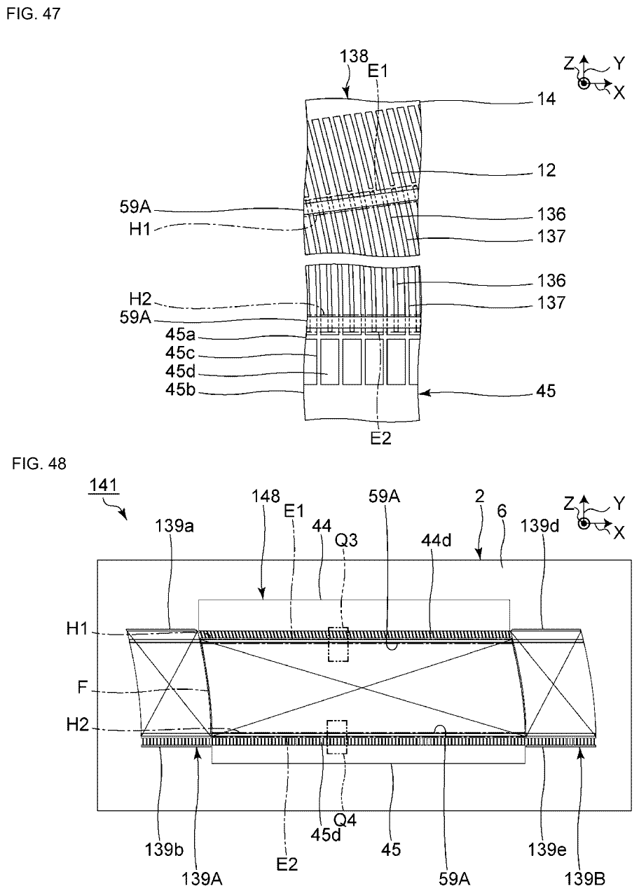

FIG. 46 is a simplified plan view of an acoustic wave device according to a thirteenth example embodiment of the present invention. FIG. 47 is a schematic enlarged plan view of areas bounded by dash double-dotted lines Q1 and Q2 in FIG. 46.

As illustrated in FIG. 46, the thirteenth example embodiment differs from the eighth example embodiment in that the first envelope E1 in an IDT electrode 138 is linear. The thirteenth example embodiment also differs from the eighth example embodiment in the shape and arrangement of the mass-adding films 59A. Furthermore, the thirteenth example embodiment also differs from the eighth example embodiment in that the distance between the reflector busbars differs between a pair of reflectors 139A and 139B. An acoustic wave device 131 of the thirteenth example embodiment has the same or substantially the same configuration as the acoustic wave device of the eighth example embodiment except for the above points.

In this specification, the distance between reflector busbars refers to the distance between points within a pair of reflector busbars through which the normal line to the propagation axis of the piezoelectric layer passes. Similarly, the distance between busbars refers to the distance between points within a pair of busbars through which the normal line to the propagation axis of the piezoelectric layer passes. Therefore, the distance between busbars and the distance between reflector busbars are not always constant. When the normal line to the propagation axis does not pass through both of the pair of busbars, a line other than the propagation axis may be defined as the reference line for the distance between busbars. The same applies to the distance between reflector busbars.

In the IDT electrode 138, the first envelope E1 extends at an angle to the propagation axis. Specifically, the inclination angle of the first envelope E1 with respect to the propagation axis is about 7.5°, for example. However, the inclination angle of the first envelope E1 is not limited to that described above. On the other hand, the second envelope E2 extends parallel or substantially parallel to the direction in which the propagation axis extends. The second envelope E2 may extend at an angle with respect to the propagation angle.

In the thirteenth example embodiment, the overlap region includes one curved-line region and one straight-line region. More specifically, the central region F and the first edge region H1 are included in the one curved-line region. The second edge region H2 is the straight-line region. As illustrated in FIG. 47, therefore, the distal end portions of a plurality of first electrode fingers 136 and the adjacent portions of a plurality of second electrode fingers 137 extend linearly.

In the IDT electrode 138, the distal end portions of the plurality of first offset electrodes 12 and the distal end portions of the plurality of second electrode fingers 137 face each other across gaps. The distal end portions of the plurality of second electrode fingers 137 and the adjacent portions of the plurality of first electrode fingers 136 extend at an angle with respect to the direction in which the propagation axis extends and the normal direction to the propagation axis. The IDT electrode 138 does not need to include the plurality of first offset electrodes 12. For example, a plurality of openings may be provided in the first busbar 14 in the same or similar manner to the fourth example embodiment, which is illustrated in FIG. 25, or other example embodiments.

The second busbar 45 is provided with the plurality of openings 45d. The second busbar 45 does not need to be provided with the plurality of openings 45d. The IDT electrode 138 may include a plurality of second offset electrodes. In this case, the distal end portions of the plurality of second offset electrodes and the distal end portions of the plurality of first electrode fingers 136 face each other across gaps. Preferably, the plurality of second offset electrodes have linear plan-view shapes. In this case, the distal end portions of the plurality of first electrode fingers 136 and the plurality of second offset electrodes have linear plan-view shapes. This enables effective reduction or prevention of the leakage of the primary mode.

Each of the plurality of electrode fingers has a plan-view shape that can be approximated by a circular arc. However, each of the plurality of electrode fingers may have a plan-view shape that can be approximated by, for example, an elliptical arc, a parabola, or one branch of a hyperbola.

In the thirteenth example embodiment, each electrode finger has a non-constant curvature in the curved-line region in the same or similar manner to the eighth example embodiment. Furthermore, on the first envelope E1 side in the plurality of electrode fingers, the distal end portions, the adjacent portions, or the distal end portions and the adjacent portions have different curvatures from each other. This enables effective reduction or prevention of spurious waves outside the pass band.

The first envelope E1 has a linear shape and extends at an angle to the propagation axis. The second envelope E2 extends parallel or substantially parallel to the direction in which the propagation axis extends. Therefore, the distance between the pair of busbars increases from one side to the other side in the direction in which the propagation axis extends. Specifically, the distance between the first busbar 14 and the second busbar 45 increases from the reflector 139A side to the reflector 139B side.

The distance between the reflector busbars 139d and 139e in the reflector 139B is accordingly longer than that between the reflector busbars 139a and 139b in the reflector 139A.

In the reflector 139A, the pair of reflector busbars 139a and 139b extend parallel or substantially parallel to the direction in which the propagation axis extends. Therefore, the distance between the reflector busbars 139a and 139b is constant. In the reflector 139B, similarly, the pair of reflector busbars 139d and 139e extend parallel or substantially parallel to the direction in which the propagation axis extends. Therefore, the distance between the reflector busbars 139d and 139e is constant.

When the acoustic wave device 131 is used in a filter device, another resonator is arranged together with the acoustic wave device 131. When the resonator is a conventional acoustic wave resonator including an IDT electrode, the busbars and reflector busbars of the conventional acoustic wave resonator often extend parallel or substantially parallel to the direction in which the propagation axis of the piezoelectric layer extends. This is because such a configuration enables both reduction or prevention of an increase in size of the acoustic wave resonator and an improvement in the resonance characteristics. More specifically, it is possible to align the direction perpendicular or substantially perpendicular to the direction in which the plurality of electrode fingers extend with the direction in which the propagation axis extends without increasing the area of the acoustic wave resonator.

In the acoustic wave device 131, each reflector busbar extends parallel or substantially parallel to the direction in which the propagation axis extends. This facilitates the arrangement of another acoustic wave resonator and the acoustic wave device 131 without increasing the distance therebetween. It is therefore possible to improve layout flexibility and promote the miniaturization of filter devices and the like.

As illustrated in FIG. 46, the excitation angle θ_{c_prop} is about 0° or more at any portion of the curved-line region in the thirteenth example embodiment. The maximum value of the absolute value |θ_{c_prop}| of the excitation angle can thus be increased without increasing the length of each electrode finger. It is therefore possible to effectively disperse spurious waves outside the pass band without increasing the size of the acoustic wave device 131. The excitation angle θ_{c_prop} may be about 0° or less at any portion of the curved-line region. It is possible to effectively disperse spurious waves outside the pass band without increasing the size of the acoustic wave device 131 in this case as well.

The first edge region H1 and the second edge region H2 are each provided with one mass-adding film 59A. A low-velocity region is thus provided in each of the first edge region H1 and the second edge region H2. Each mass-adding film 59A has a belt shape. Each of the first edge region H1 and the second edge region H2 may be provided with plural mass-adding films.

In the acoustic wave device 131, the piston mode occurs. This enables effective confinement of the energy of the primary mode to the center side of the overlap region, so as to improve the characteristics of the primary mode. In addition, transverse modes can be reduced or prevented.

In the present example embodiment, the dimension in the normal direction to the first envelope E1, of the mass-adding film 59A located in the first edge region H1 is equal or substantially equal to the dimension in the normal direction to the second envelope E2, of the mass-adding film 59A located in the second edge region H2. However, the dimension in the normal direction to the first envelope E1, of the mass-adding film 59A located in the first edge region H1 may be different from the dimension in the normal direction to the second envelope E2, of the mass-adding film 59A located in the second edge region H2.

Any mass-adding film 59A may be provided in the region where the distal end portions of the plurality of first offset electrodes 12 are arranged. In other words, any mass-adding film 59A may be provided in a region that faces the first edge region H1 across gaps. For example, the mass-adding film 59A may be provided in that region while the mass-adding film 59A is not provided in the first edge region H1. The leakage of the primary mode from the overlap region to the first busbar 14 side can be effectively reduced or prevented in this case as well. In addition, transverse modes can be reduced or prevented.

Alternatively, any mass-adding film 59A may be provided in both of the region that faces the first edge region H1 across gaps and the first edge region H1. This enables further reduction or prevention of the leakage of the primary mode from the overlap region to the first busbar 14 side. In addition, transverse modes can be reduced or prevented.

In the laminated structure of the first electrode fingers 136 or the first offset electrodes 12 and the mass-adding film 59A thereon, the order of these layers is not limited. For example, these layers may be stacked in the order of the piezoelectric substrate 2, the first electrode fingers 136 or the first offset electrodes 12, and the mass-adding film 59A. Alternatively, for example, these layers may be arranged in the order of the piezoelectric substrate 2, the mass-adding film 59A, and the first electrode fingers 136 or the first offset electrodes 12. That is, the mass-adding film 59A may be provided between the piezoelectric substrate 2 and the first electrode fingers 136 or the first offset electrodes 12.

A plurality of the mass-adding films 59, which are illustrated in FIG. 34 or other drawings, may be provided in a region that faces the first edge region H1 across gaps. In this case, for example, the mass-adding films 59 may be laminated on the respective distal end portions of the first offset electrodes 12 or respective portions of the first electrode fingers 136 that are adjacent thereto.

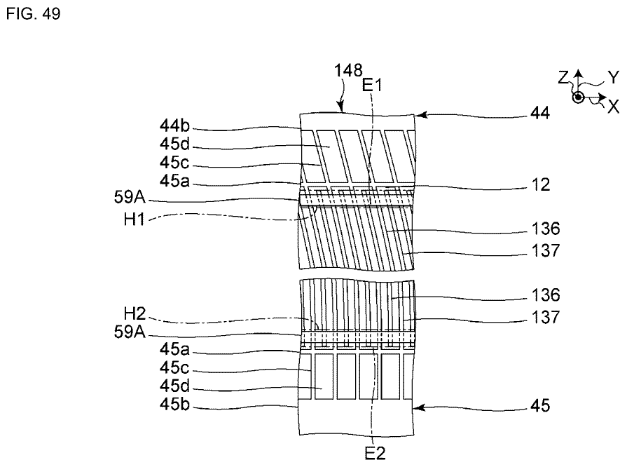

FIG. 48 is a simplified plan view of an acoustic wave device according to a fourteenth example embodiment of the present invention. FIG. 49 is a schematic enlarged plan view of areas bounded by dash double-dotted lines Q3 and Q4 in FIG. 48.

As illustrated in FIG. 48, the fourteenth example embodiment differs from the thirteenth example embodiment in that the first envelope E1 in an IDT electrode 148 extends parallel or substantially parallel to the direction in which the propagation axis extends. As illustrated in FIG. 49, the fourteenth example embodiment also differs from the thirteenth example embodiment in that the first offset electrodes are not provided and the first busbar 44 is provided with the plurality of openings 44d. Back to FIG. 48, the fourteenth example embodiment also differs from the thirteenth example embodiment in that the pair of reflectors 139A and 139B have the same or substantially the same distance between the reflector busbars. The acoustic wave device 141 of the fourteenth example embodiment has the same or substantially the same configuration as the acoustic wave device 131 of the thirteenth example embodiment except for the above points.

In an IDT electrode 148, the first envelope E1 and the second envelope E2 extend parallel or substantially parallel to the direction in which the propagation axis extends. In the fourteenth example embodiment, the distance between the first busbar 44 and the second busbar 45 is constant. Furthermore, the distance between the reflector busbars is the same or substantially the same for the pair of the reflectors 139A and 139B as described above.

In the same or similar manner to in the thirteenth example embodiment, each electrode finger has a non-constant curvature in the curved-line region in the fourteenth example embodiment as well. Furthermore, on the first envelope E1 side in the plurality of electrode fingers, the distal end portions, the adjacent portions, or the distal end portions and the adjacent portions have different curvatures from each other. The excitation angle θ_{c_prop} is about 0° or more at any portion of the curved-line region. This enables effective reduction or prevention of spurious waves outside the pass band without increasing the size of the acoustic wave device 141.

Each of the first edge region H1 and the second edge region H2 is provided with one mass-adding film 59A. A low-velocity region is thus provided in each of the first edge region H1 and the second edge region H2. In the acoustic wave device 141, the piston mode occurs. This enables effective confinement of the energy of the primary mode to the center side of the overlap region, so as to improve the characteristics of the primary mode. In addition, transverse modes can be reduced or prevented.

The following will summarize the examples of the acoustic wave device and the filter device according to example embodiments of the present invention.

An elastic wave device according to the first to fourteenth example embodiments has the following configurations 1) and 2).
1) at least one curved region includes a curved region whose one end edge is the first envelope line, and in the curved region, the curvature of each of the first electrode fingers and the second electrode fingers is not constant.
2) at least one pair of the first electrode fingers and second electrode fingers has different curvatures between the tip portions located on the first envelope line side, between adjacent portions, or between the tip portions and adjacent portions.

These 1) and 2) define a first configuration of the present invention.

However, the elastic wave devices according to example embodiments of the present invention may have a second configuration described below. The first configuration and the second configuration have the following points in common. The common points are that, in the portion located at the end edge on the first envelope side of the curved region of at least one pair of the plurality of first electrode fingers and the plurality of second electrode fingers, the curvature is different from each other. The details of the second configuration and an example of a elastic wave device with the second configuration are described below.

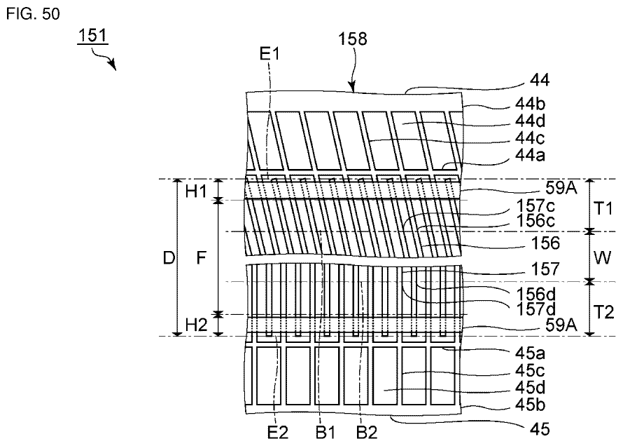

FIG. 50 is an enlarged schematic plan view of the areas near the first bus bar and the second bus bar of an IDT electrode in a fifteenth example embodiment of the present invention.

The fifteenth example embodiment differs from the fourteenth example embodiment in the configuration of the plurality of electrode fingers of the IDT electrode 158 and each reflector. The shape of each reflector is configured to correspond to the shape of the IDT electrode 158. Except for the above points, the elastic wave device 151 of the present example embodiment has the same or substantially the same configuration as the elastic wave device 141 of the fourteenth example embodiment.

A cross-sectional region D in the elastic wave device 151 includes a curved region W, a first straight region T1, and a second straight region T2. The curved region W, the first straight region T1, and the second straight region T2 are arranged in a direction in which the first busbar 44 and the second busbar 45 face each other. More specifically, the first straight region T1 and the second straight region T2 are arranged facing each other with the curved region W in between. The first straight region T1 includes a portion of the central region F and the first edge region H1 in the cross-sectional region D. The second straight region T2 includes a portion of the central region F and the second edge region H2. The curved region W is included in the central region F.

One end edge of the curved region W is the boundary between the curved region W and the first straight region T1. This end edge is the first intersection line B1 shown in FIG. 50. Specifically, the first intersection line B1 is a virtual line that extends parallel or substantially parallel to the first envelope line E1 and passes through the central region F in the intersection region D.

The other end edge of the curved region W is the boundary between the curved region W and the second straight region T2. This end edge is the second intersection line B2. Specifically, the second intersection line B2 is a virtual line that extends parallel or substantially parallel to the second envelope line E2 and passes through the central region F.

In each first electrode finger 156, the portion intersecting with the first intersection line B1 is the first intersection portion 156c. In each second electrode finger 157, the portion intersecting with the first intersection line B1 is the second intersection portion 157c. On the other hand, in each first electrode finger 156, the portion intersecting with the second crossing line B2 is the third crossing portion 156d. In each second electrode finger 157, the portion intersecting with the second crossing line B2 is the fourth crossing portion 157d.

The first intersection portion 156c is located within the curved region W and is defined as the portion extending approximately 1λ in the direction along which the first electrode finger 156 extends from the first intersection line B1. Similarly, the second intersection portion 157c is a portion located within the curved region W, and is defined as the portion extending approximately 1λ in the direction along which the second electrode finger 157 extends from the first intersection line B1. On the other hand, the third intersection portion 156d is a portion located within the curved region W, and is defined as the portion extending approximately 1λ in the direction along which the first electrode finger 156 extends from the second intersection line B2. The fourth intersection 157d is a portion located within the curved region W, and is defined as the portion extending approximately 1λ in the direction along the second electrode finger 157 extends from the second intersection line B2.

The elastic wave device 151 of the present example embodiment has the second configuration of the present invention. The second configuration is one of the configurations (1) and (2), or the configurations (3) and (4) below. The configurations (1) and (2) are the configurations when the cross line is the first cross line B1. The configurations (3) and (4) are the configurations when the cross line is the second cross line B2.
1) at least one curved region includes a curved region W whose one end edge is the first crossing line B1, and in the curved region W, the curvature at each of the first electrode fingers 156 and the second electrode fingers 157 is not constant.
2) in at least one pair of electrode fingers among the plurality of first electrode fingers 156 and the plurality of second electrode fingers 157, the curvatures are different from each other at the first intersection points 156c, or at the second intersection points 157c, or between the first intersection points 156c and the second intersection points 157c.
3) at least one curved region includes a curved region W whose one end edge is the second cross line B2, and in the curved region W, the curvature of each of the first electrode fingers 156 and the second electrode fingers 157 is not constant.
4) in at least one pair of the plurality of first electrode fingers 156 and the plurality of second electrode fingers 157, the curvatures are different from each other at the third intersection points 156d, or at the fourth intersection points 157d, or between the third intersection points 156d and the fourth intersection points 157d. In the configuration of 4), for convenience, the third cross-section 156d may be referred to as the first cross-section, and the fourth cross-section 157d may be referred to as the second cross-section.

The elastic wave device 151 has the configuration described in the above (1) to (4) and has the second configuration. As a result, in the curved region W of the elastic wave device 151, when viewed in plan view, the shapes of at least one pair of electrode fingers at the IDT electrode 158 are different curved shapes. Thus, in the present example embodiment, as in the first to fourteenth example embodiments, unwanted waves can be reduced or prevented.

As described above, in the cross-sectional region, the excitation direction of elastic waves at any portion of any electrode finger among the plurality of electrode fingers is one of the first to third directions. In the present example embodiment, the excitation direction is the first direction. Specifically, the first direction as the excitation direction of elastic waves at any portion of any electrode finger is perpendicular or substantially perpendicular to the direction in which the electrode finger extends. The excitation direction may also be the second direction or the third direction.

As in the first to fourteenth example embodiments, when the elastic wave device has the first configuration, it is preferable that the shapes of all electrode fingers in the plan view of the IDT electrode are different curved shapes. Similarly, as shown in the present example embodiment illustrated in FIG. 50, when the elastic wave device 151 has the second configuration, it is also preferable that the shapes of all electrode fingers of the IDT electrode 158, as viewed in plan view, are different curved shapes. This example is specifically illustrated in three examples.

As the first example, it is preferable that the curvatures are different from each other between all first cross sections 156c of all first electrode fingers 156 and all second electrode fingers 157, or between all second cross sections 157c of all second electrode fingers 157, or between the first cross sections 156c and the second cross sections 157c. More specifically, it is preferable that all of the following are satisfied. The curvature between all first cross sections 156c of all first electrode fingers 156 is different from each other, the curvature between all second cross sections 157c of all second electrode fingers 157 is different from each other, and the curvature between the first crossing portion 156c of all first electrode fingers 156 and the second cross sections 157c of all second electrode fingers 157 is different from each other.

As the second example, it is preferable that the curvatures are different from each other between all third cross sections 156d, between all fourth cross sections 157d, or between the third cross sections 156d and the fourth cross sections 157d in all first electrode fingers 156 and all second electrode fingers 157. More specifically, it is preferable that all of the following conditions are satisfied. The curvature between all third cross-sections 156d of all first electrode fingers 156 is different from each other, the curvature between all fourth cross-sections 157d of all second electrode fingers 157 is different from each other, and the curvature between the third cross sections 156d of all first electrode fingers 156 and the fourth cross sections 157d of all second electrode fingers 157 is different from each other.

As the third example, it is preferable that the curvature differs between portions located at positions where the excitation angle θC_prop is about 0° in all first electrode fingers 156 and all second electrode fingers 157. As such, with the planar shapes of all electrode fingers in the IDT electrode 158 being different curved shapes, unwanted waves can be more reliably and effectively reduced or prevented.

In the curved region W of the elastic wave device 151, the shape of all electrode fingers as viewed in plan view is approximately circular and has a different curved shape from each other. Therefore, in the curved region W, the relationship shown in the above FIG. 14 is satisfied. More specifically, in the curved region W, when the shapes of all first electrode fingers 156 and all second electrode fingers 157 as viewed in plan are approximated as arcs, the centers of the circles including these arcs are mutually different.

However, the configuration of the curved region W in the present example embodiment is an example of a case where the elastic wave device has a second configuration. For example, in the curved region W, the shapes of the plurality of first electrode fingers 156 and the plurality of second electrode fingers 157 as viewed in plan may be shapes approximating elliptical arcs. Alternatively, the shapes of the plurality of first electrode fingers 156 and the plurality of second electrode fingers 157 as viewed in plan may be parabolic shapes that cannot be approximated by circular arcs or elliptical arcs.

In the example embodiment shown in FIG. 50, the portion where the excitation angle θC_prop is about 0° in the curved region W is the portion on the second intersection line B2. In any portion of the curved region W, the excitation angle θC__prop is about 0° or greater. However, the curved region W may include a portion where the excitation angle θC__prop is less than about 0. It is preferable that the maximum absolute value of the excitation angle θC__prop is, for example, about 5° or more for each of the multiple first electrode fingers 156 and the multiple second electrode fingers 157. This allows for more effective reduction or prevention of unwanted waves outside the band.

In the portion of the curve region W where the excitation angle θC__prop is about 0°, the duty ratio is constant. However, this is not limited to this.

Regardless of whether the elastic wave device has the first configuration or the second configuration, in the curve region, the shape of each electrode finger as viewed in plan is a curved shape. Therefore, in the curved region, the excitation angle θC__prop is not uniform. Even when the elastic wave device has the second configuration, it is preferable that the resonance frequency or anti-resonance frequency is the same or approximately the same throughout the curved region, as when the elastic wave device has the first configuration. It is more preferable that the resonance frequency or anti-resonance frequency is the same or approximately the same throughout the entire or substantially the entire cross-sectional region. This allows for the dispersion of unwanted waves outside the band, such as Rayleigh waves, for example. Thus, unwanted waves outside the band can be effectively reduced or prevented.

Even when the elastic wave device has the second configuration, the curved region may be provided in the same or substantially the same manner as in the first to fourteenth example embodiments and each modification, as well as the examples shown in the descriptions thereof. For example, when the elastic wave device has the second configuration, the resonance frequency or anti-resonance frequency in the curved region may be the same or substantially the same as in the case where the elastic wave device has a first configuration. This example is shown below.

When the elastic wave device has the second configuration, the duty ratio may be constant in the portion located in the curved region where the excitation angle θC__prop of the IDT electrodes is the same or substantially the same. In at least a portion of the curved region, the duty ratio in the portion where the excitation angle θC_prop of the IDT electrodes is the same or substantially the same may vary depending on the absolute value of the excitation angle |θC__prop|, such that the resonance frequency or anti-resonance frequency is equal or approximately equal. Specifically, the duty ratio of the IDT electrodes where the excitation angle θC__prop is the same or substantially the same may increase or decrease as the absolute value of the excitation angle |θC__prop| increases.

The portion located in the curved region where the excitation angle θC__prop of the IDT electrode is the same or substantially the same may have an electrode finger pitch and at least one of the thicknesses of the plurality of first electrode fingers and the plurality of second electrode fingers being constant. In this case, when the electrode finger pitch is constant in the region where the excitation angle θC_prop is the same or substantially the same, the electrode finger pitch may vary as follows. Specifically, in at least a portion of the curved region, the electrode finger pitch in the portion of the IDT electrode where the excitation angle θC_prop is the same or substantially the same may vary in accordance with the absolute value of the excitation angle |θC_prop| such that the resonance frequency or anti-resonance frequency is equal or approximately equal. Specifically, the electrode finger pitch in the portion of the IDT electrode where the excitation angle θC_prop is the same or substantially the same may become wider or narrower as the absolute value of the excitation angle |θC_prop∥ increases.

On the other hand, when the thickness of multiple electrode fingers is constant in regions where the excitation angle θC_prop is the same or substantially the same, the thickness of the plurality of electrode fingers may vary as follows. That is, in at least a portion of the curved region, the thickness of the plurality of electrode fingers in the region where the excitation angle θC_prop is the same or substantially the same may vary depending on the absolute value of the excitation angle |θC_prop|, such that the resonance frequency or anti-resonance frequency is the same or approximately the same. Specifically, the thickness of the plurality of first electrode fingers and the plurality of second electrode fingers in the region where the excitation angle θC__prop is the same or substantially the same may increase or decrease as the absolute value of the excitation angle |θC_prop| increases.

Furthermore, even when the elastic wave device has the second configuration, a dielectric film may be provided in the same or similar manner as in the fourth or fifth modified examples of the first example embodiment shown in FIG. 11 to 13.

In this case, the thickness of the portion of the dielectric film covering the curved region may be constant in the portion where the excitation angle θC_prop is the same or substantially the same. In at least a portion of the curved region, the thickness of the dielectric film portion located on the portion of the curved region where the excitation angle θC_prop is the same or substantially the same may vary depending on the excitation angle θC_prop so that the resonance frequency or anti-resonance frequency is the same or approximately the same. Specifically, the thickness of the portion located on the portion where the excitation angle θC_prop is the same or substantially the same in the dielectric film may be thicker or thinner as the absolute value of the excitation angle |θC_prop| increases.

When the elastic wave device has the second configuration, the electrode finger pitch in the portion where the excitation angle θC_prop is the same or substantially the same may not be constant, as shown in the seventh example embodiment in FIGS. 31 and 32. For example, the electrode finger pitch in the region where the excitation angle θC__prop is the same or substantially the same may become wider as the distance from the center in the direction along which the propagation axis extends of the IDT electrode increases. In this case, the curvature of the electrode fingers can be increased as they move away from the center, thus increasing the variation in curvature between the electrode fingers. This allows the variation in the frequencies at which unwanted waves outside the bandwidth occur to be further increased, thus further reducing or preventing unwanted waves outside the bandwidth.

On the other hand, for example, the electrode finger pitch in regions where the excitation angle θC__prop is the same or substantially the same may become narrower as the distance from the center in the direction of propagation of the IDT electrode increases. In this case as well, unwanted waves outside the band can be effectively reduced or prevented.

As shown in FIG. 50, the inter-sectional region D in the present example embodiment includes a curved region W and a first straight region T1 and a second straight region T2 that sandwich the curved region W and face each other. It is preferable that, for example, about 50% or more of the intersection region D is the curved region W. This allows unwanted waves to be reduced or prevented more reliably and effectively.

Furthermore, the cross-sectional area D may also include a pair of curved regions W and curved regions facing each other and sandwiched between them. In this case, the first cross line B1 is the boundary between the curved region W and one of the pair of curved regions. The second cross line B2 is the boundary between the curved region W and the other of the pair of curved regions. In this case as well, the elastic wave device 151 may have the second configuration.

When the second intersection line B2 defines and functions as a boundary between a curved region W and another curved region, for example, the plurality of first electrode fingers and the plurality of second electrode fingers may include the above-described inflection points. The second intersection line B2 may pass through the inflection points of each electrode finger. In this case, in the curved region W and the other curved region, the directions in which the plurality of first electrode fingers and the plurality of second electrode fingers bend, as viewed in plan, are different from each other. The first intersection line B1 may pass through the inflection points of each electrode finger.

As shown in FIG. 50, in the IDT electrode 158 of the present example embodiment, the direction in which the first envelope line E1 extends and the direction in which the second envelope line E2 extends are parallel or substantially parallel. Therefore, the direction in which the first cross line B1 extends and the direction in which the second cross line B2 extends are parallel or substantially parallel. Furthermore, the direction in which the first envelope line E1 extends, the direction in which the second envelope line E2 extends, the direction in which the first intersection line B1 extends, and the direction in which the second intersection line B2 extends are parallel or substantially parallel to the direction in which the propagation axis extends.

However, as in the thirteenth example embodiment, for example, the direction in which the first envelope line E1 extends and the direction in which the second envelope line E2 extends may intersect. Similarly, the direction in which the first intersection line B1 extends and the direction in which the second intersection line B2 extends may intersect. For example, the first envelope line E1 and the first crossing line B1 may extend at an angle to the direction in which the propagation axis extends. Similarly, the second envelope line E2 and the second crossing line B2 may extend at an angle to the direction in which the propagation axis extends.

Alternatively, even when the elastic wave device 151 has the second configuration, as in the second example embodiment shown in FIG. 15, the first envelope may include at least one bend. In this case, the first intersection line includes at least one bend so that it extends parallel or substantially parallel to the first envelope. The second envelope may include at least one bend. In this case, the second intersection line includes at least one bend so that it extends parallel or substantially parallel to the second envelope.

As shown in FIG. 50, the first edge region H1 and the second edge region H2 each include a mass-added film 59A provided in the same or similar manner as in the fourteenth example embodiment. As a result, low-velocity regions are provided in the first edge region H1 and the second edge region H2, respectively. Thus, in the present example embodiment as well, the transverse mode can be reduced or prevented, and leakage of elastic wave energy can be reduced or prevented.

The first busbar 44 and the second busbar 45 include a plurality of openings, similar to the fourteenth example embodiment. The first busbar 44 and the second busbar 45 do not necessarily include a plurality of openings.

Even when the elastic wave device 151 has the second configuration, the IDT electrode 158 may include the plurality of first offset electrodes as described above, as in the first example embodiment. The IDT electrode 158 may include the plurality of second offset electrodes described above. Alternatively, the elastic wave device 151 may have a configuration in which the IDT electrode 158 includes a plurality of first offset electrodes and a plurality of openings 45d are provided in the second bus bar 45.

In the present example embodiment, as described above, the shape of each reflector corresponds to the shape of the IDT electrode 158. In each reflector, the shape of the plurality of reflector electrode fingers as viewed in plan includes a curved shape. In each reflector, a pair of reflector bus bars extends parallel or substantially parallel to the direction in which the propagation axis extends. The direction in which each reflector bus bar extends is not limited to the above.

The piezoelectric substrate of the elastic wave device 151 is configured similarly to the piezoelectric substrate 2 shown in FIG. 2 and FIG. 48 in the first example embodiment and the fourteenth example embodiment. Even when the elastic wave device 151 has the second configuration, the piezoelectric substrate may be configured similarly to the piezoelectric substrate shown in FIGS. 35 to 37, which is the ninth example embodiment or its first or second modified example. Alternatively, the piezoelectric substrate of the elastic wave device 151 may solely include a piezoelectric layer.

In the filter device 120 according to the twelfth example embodiment shown in FIG. 43, an elastic wave device according to an example embodiment of the present invention is used. As described above, at least one of the plurality of elastic wave resonators of the filter device 120 may be an elastic wave device according to an example embodiment of the present invention. Furthermore, the elastic wave device according to an example embodiment of the present invention may have the first configuration or the second configuration. For example, when an elastic wave device having the second configuration is used as an elastic wave resonator of the filter device, unnecessary waves can be effectively reduced or prevented in the elastic wave resonator, similar to the twelfth example embodiment. Therefore, the filter characteristics of the filter device can be improved.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device, comprising:
a piezoelectric substrate including a piezoelectric layer; and
an IDT electrode on the piezoelectric layer and including a pair of busbars and a plurality of electrode fingers; wherein
the pair of busbars include a first busbar and a second busbar facing each other;
the plurality of electrode fingers include a plurality of first electrode fingers and a plurality of second electrode fingers;
one end of each of the plurality of first electrode fingers is connected to the first busbar;
one end of each of the plurality of second electrode fingers is connected to the second busbar;
the plurality of first electrode fingers and the plurality of second electrode fingers are interdigitated with each other;
a region between a first envelope and a second envelope in the IDT electrode is defined as an overlap region where the first envelope is a virtual line connecting tips of distal end portions of the plurality of second electrode fingers and the second envelope is a virtual line connecting tips of distal end portions of the plurality of first electrode fingers;
an intersection region includes a first edge region including the first envelope line, a second edge region including the second envelope line, and a central region between the first edge region and the second edge region;
the intersection region includes at least one curved portion where shapes of the plurality of first electrode fingers and the plurality of second electrode fingers, as viewed in plan view, are each curved;
the intersection region includes a portion located on the first envelope line of the first electrode finger, and a portion adjacent to the tip of any of the plurality of second electrode fingers is an adjacent portion of the first electrode finger;
the intersection region includes a portion located on the second envelope line of the second electrode finger, and a portion adjacent to the tip of any of the plurality of first electrode fingers is an adjacent portion of the second electrode finger;
when a virtual line extending parallel or substantially parallel to the first envelope line or the second envelope line and passing through the central region in the intersection region is drawn as the intersection line, a portion intersecting the intersection line in each of the plurality of first electrode fingers is a first intersection portion, and a portion intersecting the intersection line in each of the plurality of second electrode fingers is a second intersection portion;
the acoustic wave device includes:
a first configuration where at least one curved-line region includes one edge corresponding to the first envelope, in the curved-line region, each of the plurality of first electrode fingers and the plurality of second electrode fingers has a non-constant curvature, and on the first envelope side in at least one pair of electrode fingers among the plurality of first electrode fingers and the plurality of second electrode fingers, the distal end portions, the adjacent portions, or the distal end portion and the adjacent portions have different curvatures from each other; or
a second configuration where the at least one curved region includes a curved region including one end edge defined by the intersection line, and in the curved region, the curvature is not constant at each of the plurality of first electrode fingers and the plurality of second electrode fingers, and the curvature is different from each other between the first intersection portions, between the second intersection portions, or between the first intersection portions, or the second intersection portions, of at least one pair of the plurality of first electrode fingers and the plurality of second electrode fingers.

2. The acoustic wave device according to claim 1, wherein the acoustic wave device includes the first configuration;
in the curved-line region, the plurality of first electrode fingers and the plurality of second electrode fingers each have a plan-view shape to be approximated by a circular arc, an elliptical arc, a parabola, or one branch of a hyperbola; and
the curvature of the distal end portion or the adjacent portion of any one of the plurality of first electrode fingers or any one of the plurality of second electrode fingers that is located on an outer side is greater than curvature of the distal end portion or the adjacent portion of any one of the plurality of first electrode fingers or any one of the plurality of second electrode fingers that is located on an inner side where:
when the plan-view shape of each of the plurality of first electrode fingers and the plurality of second electrode fingers is approximated by a circular arc, an elliptical arc, or a parabola, the inner side is closer to a center of a circle including the circular arc, a centroid of foci of an ellipse including the elliptical arc, or a focus of the parabola while the outer side is farther from the same; or
when the plan-view shape of each of the plurality of first electrode fingers and the plurality of second electrode fingers is approximated by one branch of a hyperbola, the outer side is closer to a centroid of foci of the hyperbola while the inner side is farther from the same.

3. The acoustic wave device according to claim 1, wherein
the acoustic wave device includes the first configuration;
in the curved-line region, the plurality of first electrode fingers and the plurality of second electrode fingers each have a plan-view shape to be approximated by a circular arc, an elliptical arc, a parabola, or one branch of a hyperbola; and
the curvature of the distal end portion or the adjacent portion of any one of the plurality of first electrode fingers or any one of the plurality of second electrode fingers that is located on an outer side is smaller than the curvature of the distal end portion or the adjacent portion of any one of the plurality of first electrode fingers or any one of the plurality of second electrode fingers that is located on an inner side where:
when the plan-view shape of each of the plurality of first electrode fingers and the plurality of second electrode fingers is approximated by a circular arc, an elliptical arc, or a parabola, the inner side is closer to the center of the circle including the circular arc, the centroid of the foci of the ellipse including the elliptical arc, or the focus of the parabola while the outer side is farther from the same; or
when the plan-view shape of each of the plurality of first electrode fingers and the plurality of second electrode fingers is approximated by one branch of a hyperbola, the outer side is closer to the centroid of the foci of the hyperbola while the inner side is farther from the same.

4. The acoustic wave device according to claim 1, wherein
the overlap region includes at least two of the curved-line regions; and
in the plan-view shapes of the plurality of first electrode fingers and the plurality of second electrode fingers, the plurality of first electrode fingers and the plurality of second electrode fingers are bent in different directions in one of the at least two curved-line regions and another of the at least two curved-line regions.

5. An acoustic wave device, comprising:
a piezoelectric substrate including a piezoelectric layer; and
an IDT electrode on the piezoelectric layer and including a pair of busbars and a plurality of electrode fingers; wherein
the pair of busbars include a first busbar and a second busbar facing each other;
the plurality of electrode fingers include a plurality of first electrode fingers and a plurality of second electrode fingers;
one end of each of the plurality of first electrode fingers is connected to the first busbar;
one end of each of the plurality of second electrode fingers is connected to the second busbar;
the plurality of first electrode fingers and the plurality of second electrode fingers are interdigitated with each other;
a region between a first envelope and a second envelope in the IDT electrode is defined as an overlap region where the first envelope is a virtual line connecting distal end portions of the plurality of second electrode fingers and the second envelope is a virtual line connecting distal end portions of the plurality of first electrode fingers;
a portion that includes a portion of each of the plurality of first electrode fingers located on the first envelope and is adjacent to the distal end portion of any one of the plurality of second electrode fingers is referred to as an adjacent portion of the first electrode finger;
a portion that includes a portion of each of the plurality of second electrode fingers located on the second envelope and is adjacent to the distal end portion of any one of the plurality of first electrode fingers is referred to as an adjacent portion of the second electrode finger;
the overlap region includes at least one curved-line region, in which the plurality of first electrode fingers and the plurality of second electrode fingers each have a curved plan-view shape;
the at least one curved-line region includes a curved-line region in which each of the plurality of first electrode fingers and the plurality of second electrode fingers has a curved plan-view shape that is not a circular or elliptical arc and is to be approximated by a circular or elliptical arc; and
in the curved-line region, when the plan-view shapes of at least one pair of electrode fingers among the plurality of first electrode fingers and the plurality of second electrode fingers are approximated by circular or elliptical arcs, centers of circles including the respective circular arcs or centroids of foci of ellipses including the respective elliptical arcs are located at different positions.

6. The acoustic wave device according to claim 5, wherein
a first intersection area includes a portion located on the first envelope line of the first electrode finger, and a portion adjacent to a tip of any of the plurality of second electrode fingers is the adjacent portion of the first electrode finger;
a second intersection area includes a portion located on the second envelope line of the second electrode finger, and a portion adjacent to a tip of any of the first electrode fingers is the adjacent portion of the second electrode finger;
in the curved-line region, each of the plurality of first electrode fingers and the plurality of second electrode fingers has a non-constant curvature; and
on the first envelope side in at least one pair of electrode fingers among the plurality of first electrode fingers and the plurality of second electrode fingers, the distal end portions, the adjacent portions, or the distal end portions and the adjacent portions have different curvatures from each other.

7. The acoustic wave device according to claim 1, wherein
the piezoelectric layer includes a propagation axis; and
in the curved-line region, a duty ratio in a direction parallel or substantially parallel to a direction in which the propagation axis extends is constant.

8. The acoustic wave device according to claim 1, wherein
the piezoelectric layer includes a propagation axis;
in the curved-line region, an excitation direction of an acoustic wave at any given portion of any given electrode finger among the plurality of first electrode fingers and the plurality of second electrode fingers is any one of first to third directions;
the first direction is perpendicular or substantially perpendicular to a direction in which the given electrode finger extends;
the second direction is a direction of a shortest line connecting the given electrode finger to the first or second electrode finger adjacent to the given electrode finger;
the third direction is a direction of an electric field vector between the given electrode finger and the first or second electrode finger adjacent to the given electrode finger; and
when an angle between an excitation direction and a direction in which the propagation axis extends is referred to as an excitation angle, in the curved-line region, in portions of the IDT electrode where an excitation angle is uniform, an electrode finger pitch increases with increasing distance from a center of the IDT electrode in the direction in which the propagation axis extends.

9. The acoustic wave device according to claim 8, wherein
the acoustic wave device includes the first configuration;
in the IDT electrode, the curvatures of the distal end portions and the adjacent portions of the plurality of first electrode fingers and the distal end portions and the adjacent portions of the plurality of second electrode fingers increase with increasing distance from the center of the IDT electrode in the direction in which the propagation axis extends.

10. The acoustic wave device according to claim 1, wherein
the piezoelectric layer includes a propagation axis;
in the curved-line region, an excitation direction of an acoustic wave at any given portion of any given electrode finger among the plurality of first electrode fingers and the plurality of second electrode fingers is any one of first to third directions;
the first direction is perpendicular or substantially perpendicular to a direction in which the given electrode finger extends;
the second direction is a direction of a shortest line connecting the given electrode finger to the first or second electrode finger adjacent to the given electrode finger;
the third direction is a direction of an electric field vector between the given electrode finger and the first or second electrode finger adjacent to the given electrode finger; and
when an angle between an excitation direction and a direction in which the propagation axis extends is referred to as an excitation angle, in the curved-line region, in portions of the IDT electrode where the excitation angle is uniform, an electrode finger pitch decreases with increasing distance from a center of the IDT electrode in the direction in which the propagation axis extends.

11. The acoustic wave device according to claim 1, wherein
the piezoelectric layer includes a propagation axis;
in the curved-line region, an excitation direction of an acoustic wave at any given portion of any given electrode finger among the plurality of first electrode fingers and the plurality of second electrode fingers is any one of first to third directions;
the first direction is perpendicular or substantially perpendicular to a direction in which the given electrode finger extends;
the second direction is a direction of a shortest line connecting the given electrode finger to the first or second electrode finger adjacent to the given electrode finger;
the third direction is a direction of an electric field vector between the given electrode finger and the first or second electrode finger adjacent to the given electrode finger; and
when an angle between an excitation direction and a direction in which the propagation axis extends is referred to as an excitation angle, a duty ratio is constant in portions of the IDT electrode which are located in the curved-line region and where the excitation angle is uniform.

12. The acoustic wave device according to claim 11, wherein, among the portions of the IDT electrode where the excitation angle is uniform, as an absolute value of the excitation angle increases, the duty ratio increases or decreases such that resonant frequencies or anti-resonant frequencies are the same or substantially the same in at least a portion of the curved-line region.

13. The acoustic wave device according to claim 1, wherein
the piezoelectric layer includes a propagation axis;
in the curved-line region, an excitation direction of an acoustic wave at any given portion of any given electrode finger among the plurality of first electrode fingers and the plurality of second electrode fingers is any one of first to third directions;
the first direction is perpendicular or substantially perpendicular to a direction in which the given electrode finger extends;
the second direction is a direction of a shortest line connecting the given electrode finger to the first or second electrode finger adjacent to the given electrode finger;
the third direction is a direction of an electric field vector between the given electrode finger and the first or second electrode finger adjacent to the given electrode finger; and
when an angle between an excitation direction and a direction in which the propagation axis extends is referred to as an excitation angle, in the portions of the IDT electrode which are located in the curved-line region and where an excitation angle is uniform, at least one of an electrode finger pitch and a thickness of the plurality of first electrode fingers and the plurality of second electrode fingers is constant.

14. The acoustic wave device according to claim 13, wherein
the electrode finger pitch is constant in the portions of the IDT electrode which is located in the curved-line region and where the excitation angle is uniform; and
among the portions of the IDT electrode where the excitation angle is uniform, as an absolute value of the excitation angle increases, the electrode finger pitch increases or decreases such that resonant frequencies or anti-resonant frequencies are the same or substantially the same in at least a portion of the curved-line region.

15. The acoustic wave device according to claim 13, wherein
the thickness of the plurality of first electrode fingers and the plurality of second electrode fingers is constant in the portions of the IDT electrode which is located in the curved-line region and where the excitation angle is uniform; and
among the portions of the IDT electrode where the excitation angle is uniform, as an absolute value of the excitation angle increases, the thickness of the plurality of first electrode fingers and the plurality of second electrode fingers increases or decreases such that resonant frequencies or anti-resonant frequencies are the same or substantially the same in at least a portion of the curved-line region.

16. The acoustic wave device according to claim 1, further comprising:
a dielectric film on the piezoelectric layer and covering the IDT electrode; wherein
the piezoelectric layer includes a propagation axis;
in the curved-line region, an excitation direction of an acoustic wave at any given portion of any given electrode finger among the plurality of first electrode fingers and the plurality of second electrode fingers is any one of first to third directions;
the first direction is perpendicular or substantially perpendicular to a direction in which the given electrode finger extends;
the second direction is a direction of a shortest line connecting the given electrode finger to the first or second electrode finger adjacent to the given electrode finger;
the third direction is a direction of an electric field vector between the given electrode finger and the first or second electrode finger adjacent to the given electrode finger; and
when an angle between an excitation direction and a direction in which the propagation axis extends is referred to as an excitation angle, in a portion of the dielectric film that covers the curved-line region, a thickness of the dielectric film is constant on the portions where the excitation angle is uniform.

17. The acoustic wave device according to claim 16, wherein, in the curved-line region, as an absolute value of the excitation angle increases, in the curved-line region, the thickness of the dielectric film increases or decreases on the portions where the excitation angle is uniform such that resonant frequencies or anti-resonant frequencies are the same or substantially the same in at least a portion of the curved-line region.

18. The acoustic wave device according to claim 1, wherein resonant frequencies or anti-resonant frequencies are the same or substantially the same throughout an entirety or substantially an entirety of the overlap region.

19. The acoustic wave device according to claim 1, wherein
the acoustic wave device includes the first configuration;
an entirety or substantially an entirety of the overlap region includes the at least one curved-line region.

20. The acoustic wave device according to claim 1, wherein the overlap region includes a straight-line region in which the plurality of first electrode fingers and the plurality of second electrode fingers each have a linear plan-view shape.

21. The acoustic wave device according to claim 20, wherein the curved-line region includes at least about 50% of the overlap region.

22. The acoustic wave device according to claim 1, wherein
the piezoelectric layer includes a propagation axis;
in the curved-line region, an excitation direction of an acoustic wave at any given portion of any given electrode finger among the plurality of first electrode fingers and the plurality of second electrode fingers is any one of first to third directions;
the first direction is perpendicular or substantially perpendicular to a direction in which the given electrode finger extends;
the second direction is a direction of a shortest line connecting the given electrode finger to the first or second electrode finger adjacent to the given electrode finger;
the third direction is a direction of an electric field vector between the given electrode finger and the first or second electrode finger adjacent to the given electrode finger; and
when an angle between an excitation direction and a direction in which the propagation axis extends is referred to as an excitation angle, a maximum absolute value of an excitation angle is at least about 5° in each of the plurality of first electrode fingers and the plurality of second electrode fingers.

23. The acoustic wave device according to claim 1, wherein
the intersection region includes the portion located on the first envelope line of the first electrode finger, and the portion adjacent to the tip of any of the second electrode fingers is the portion adjacent to the tip of any of the first electrode fingers; and
the intersection region includes the portion located on the second envelope line of the second electrode finger, and the portion adjacent to the tip of any of the first electrode fingers is an adjacent portion of the second electrode finger; and
the at least one curved-line region includes a curved-line region including one end defining the first envelope line, and in the curved-line region, the curvature of the first electrode fingers and the second electrode fingers is not constant;
the at least one curved-line region includes the first configuration in which at least one pair of electrode fingers, among the plurality of first electrode fingers and the plurality of second electrode fingers, has different curvatures between the tip portions located on the first envelope line side, between the adjacent portions, or between the tip portions and the adjacent portions;
on the first envelope side in all of the plurality of first electrode fingers and the plurality of second electrode fingers, the distal end portions, the adjacent portions, or the distal end portions and the adjacent portions have different curvatures from each other.

24. The acoustic wave device according to claim 1, wherein
the piezoelectric layer includes a propagation axis; and
the first envelope extends at an angle with respect to the propagation axis.

25. The acoustic wave device according to claim 24, wherein
the intersection region includes the portion located on the first envelope line of the first electrode finger, and the portion adjacent to the tip of any of the second electrode fingers is the adjacent portion of the first electrode finger;
the intersection region includes a portion located on the second envelope line of the second electrode finger, and the portion adjacent to the tip of any of the first electrode fingers is the adjacent portion of the second electrode finger;
the second envelope extends parallel or substantially parallel to a direction in which the propagation axis extends;
the distal end portions of the plurality of first electrode fingers and the adjacent portions of the plurality of second electrode fingers are linear and are perpendicular or substantially perpendicular to the propagation axis; and
the distal end portions of the plurality of second electrode fingers and the adjacent portions of the plurality of first electrode fingers extend at an angle with respect to the direction in which the propagation axis extends and a normal direction to the propagation axis.

26. The acoustic wave device according to claim 1, wherein the first envelope includes at least one bent portion at which the first envelope changes direction.

27. The acoustic wave device according to claim 1, wherein
the piezoelectric layer includes a propagation axis; and
the first envelope and the second envelope both extend parallel or substantially parallel to a direction in which the propagation axis extends.

28. The acoustic wave device according to claim 1, wherein
the first busbar includes:
a first inside busbar portion and a first outside busbar portion facing each other; and
a plurality of first connecting portions connecting the first inside busbar portion and the first outside busbar portion;
the first inside busbar portion is located on an overlap region side relative to the first outside busbar portion;
the first inside busbar portion extends parallel or substantially parallel to the first envelope; and
the first busbar includes a plurality of openings bounded by the first inside busbar portion, the first outside busbar portion, and the plurality of first connecting portions.

29. The acoustic wave device according to claim 1, wherein
the IDT electrode includes a plurality of first offset electrodes each including one end connected to the first busbar; and
the plurality of first offset electrodes face the plurality of second electrode fingers across gaps.

30. The acoustic wave device according to claim 29, wherein
the plurality of first offset electrodes each have a curved plan-view shape;
each of the plurality of first offset electrodes has a non-constant curvature; and
distal end portions of at least one pair of first offset electrodes among the plurality of first offset electrodes have different curvatures from each other.

31. The acoustic wave device according to claim 29, wherein the plurality of first offset electrodes each have a linear plan-view shape.

32. The acoustic wave device according to claim 29, wherein
the IDT electrode includes a plurality of second offset electrodes each including one end connected to the second busbar; and
the plurality of second offset electrodes face the plurality of first electrode fingers across gaps.

33. The acoustic wave device according to claim 28, wherein
the second busbar includes:
a second inside busbar portion and a second outside busbar portion facing each other; and
a plurality of second connecting portions connecting the second inside busbar portion and the second outside busbar portion;
the second inside busbar portion is located on an overlap region side relative to the second outside busbar portion;
the second inside busbar portion extends parallel or substantially parallel to the second envelope; and
the second busbar includes a plurality of openings bounded by the second inside busbar portion, the second outside busbar portion, and the plurality of second connecting portions.

34. The acoustic wave device according to claim 1, wherein
the overlap region includes a first edge region including the first envelope, a second edge region including the second envelope, and a central region between the first edge region and the second edge region; and
a low velocity region where the acoustic velocity is lower than in the central region is provided in at least one of the first edge region and the second edge region.

35. The acoustic wave device according to claim 34, wherein the low velocity region is provided in both of the first edge region and the second edge region.

36. The acoustic wave device according to claim 34, wherein
the IDT electrode includes a plurality of first offset electrodes each including one end connected to the first busbar; and
the plurality of first offset electrodes face the plurality of second electrode fingers across gaps.

37. The acoustic wave device according to claim 36, wherein
the IDT electrode includes a plurality of second offset electrodes each including one end connected to the second busbar; and
the plurality of second offset electrodes face the plurality of first electrode fingers across gaps.

38. The acoustic wave device according to claim 36, wherein
the second busbar includes:
a second inside busbar portion and a second outside busbar portion facing each other; and
a plurality of second connecting portions connecting the second inside busbar portion and the second outside busbar portion; and
the second busbar includes a plurality of openings bounded by the second inside busbar portion, the second outside busbar portion, and the plurality of second connecting portions.

39. The acoustic wave device according to claim 1, further comprising:
a pair of reflectors on the piezoelectric layer, facing each other across the IDT electrode, and each including a plurality of reflector electrode fingers; wherein
the plurality of reflector electrode fingers each have a curved plan-view shape.

40. The acoustic wave device according to claim 39, wherein
the piezoelectric layer includes a propagation axis;
the first envelope extends at an angle with respect to the propagation axis;
each of the pair of reflectors includes a pair of reflector busbars facing each other;
one end of each of the plurality of reflector electrode fingers is connected to one of the pair of reflector busbars while another end of each of the plurality of reflector electrode fingers is connected to another of the pair of reflector busbars; and
in each of the pair of reflectors, the pair of reflector busbars extend parallel or substantially parallel to the direction in which the propagation axis extends.

41. The acoustic wave device according to claim 1, wherein
the piezoelectric substrate includes a support substrate; and
the piezoelectric layer is on the support substrate.

42. The acoustic wave device according to claim 41, wherein the piezoelectric substrate includes an intermediate layer between the support substrate and the piezoelectric layer.

43. The acoustic wave device according to claim 41, wherein
the piezoelectric substrate includes a hollow portion; and
a portion of the support substrate and a portion of the piezoelectric layer face each other across the hollow portion.

44. The acoustic wave device according to claim 1, wherein
the piezoelectric substrate includes only the piezoelectric layer.

45. A filter device, comprising:
a plurality of acoustic wave resonators; wherein
at least one of the plurality of acoustic wave resonators includes the acoustic wave device according to claim 1.
